(19) United States
(12) Patent Application Publication
(10) Pub. No.: US 2024/0065011 A1
(43) Pub. Date: Feb. 22, 2024

(54) IMAGING ELEMENT, STACKED IMAGING ELEMENT, AND IMAGING DEVICE

(71) Applicants: SONY GROUP CORPORATION, TOKYO (JP); SONY SEMICONDUCTOR SOLUTIONS CORPORATION, KANAGAWA (JP)

(72) Inventors: MAMORU TANABE, TOKYO (JP); MIKI KIMIJIMA, TOKYO (JP); OSAMU ENOKI, KANAGAWA (JP); CHIKA OHASHI, KANAGAWA (JP); MASAKAZU MUROYAMA, KANAGAWA (JP)

(21) Appl. No.: 18/255,663

(22) PCT Filed: Nov. 2, 2021
(86) PCT No.: PCT/JP2021/040450

§ 371 Date: Jun. 2, 2023

(30) Foreign Application Priority Data
Dec. 10, 2020 (JP) 2020-204687

(51) Int. Cl. H10K 39/32; H10K 39/00; H10K 30/85; H10K 30/86; H10K 39/38

(52) U.S. Cl. CPC H10K 39/32; H10K 39/501; H10K 30/85; H10K 30/86; H10K 39/38

(57) ABSTRACT

An imaging element according to an embodiment of the present disclosure includes a photoelectric conversion layer including an organic photoelectric conversion material, a hole transporting material, and an electron transporting material, in which the electron transporting material includes a fullerene compound monomer and a fullerene compound dimer.

### TECHNICAL FIELD

The present disclosure relates to an imaging element, a stacked imaging element and an imaging device.

### BACKGROUND ART

In recent years, an imaging element that includes a photoelectric conversion layer (light receiving layer) including an organic photoelectric conversion material is drawing attention as an imaging element included in an image sensor or the like. The imaging element generally has a structure in which the photoelectric conversion layer (light receiving layer) is sandwiched between two electrodes, and the imaging element having received light irradiation generates signal electric charge in the photoelectric conversion layer on the basis of photoelectric conversion. Accordingly, in the photoelectric conversion layer, high light resistance is demanded. An imaging element that satisfies such a demand is known from, for example, Japanese Unexamined Patent Application Publication No. 2011-199253. That is, a photoelectric conversion element disclosed in this patent application publication includes a photoelectric conversion layer including a mixture of an organic photoelectric conversion dye, a fullerene or a fullerene derivative, and a fullerene polymer between a first electrode and a second electrode.

### CITATION LIST

### Patent Literature

PTL 1: Japanese Unexamined Patent Application Publication No. 2011-199253

### SUMMARY OF THE INVENTION

However, a photoelectric conversion element disclosed in the patent application publication described above actually has an issue that characteristics change with time depending on light irradiation time.

It is therefore desirable to provide an imaging element in which change in characteristics with time is small, and a stacked imaging element and an imaging device that include the imaging element.

An imaging element according to an embodiment of the present disclosure includes a photoelectric conversion layer including an organic photoelectric conversion material, a hole transporting material, and an electron transporting material, in which the electron transporting material includes a fullerene compound monomer and a fullerene compound dimer.

A stacked imaging element according to an embodiment of the present disclosure includes at least one imaging element according to the embodiment of the present disclosure stacked.

A first imaging device according to an embodiment of the present disclosure includes a plurality of imaging elements according to the embodiment of the present disclosure. In addition, a second imaging device according to an embodiment of the present disclosure includes a plurality of stacked imaging elements according to the embodiment of the present disclosure.

### BRIEF DESCRIPTION OF DRAWINGS

FIG. 1 is a conceptual diagram of an imaging element of Example 1.

FIG. 2A is a graph illustrating a result of examining a relationship between light irradiation time and change in ratio of (a C60 dimer/a C60 monomer) in a photoelectric conversion layer in the imaging element of Example 1, and FIG. 2B is a chart of an example in which a monomer and a dimer of C60 in an electron transporting material are quantitatively determined on the basis of a high performance liquid chromatography method (HPLC method).

FIG. 3A is a conceptual diagram for describing a mechanism of suppressing generation of a fullerene compound multimer by presence of a hole transporting material, and FIG. 3B is a conceptual diagram for describing a mechanism of generating a fullerene compound multimer by absence of the hole transporting material for comparison.

FIG. 4A and FIG. 4B are graphs illustrating a result of determining an external quantum efficiency variation rate in Example 1A.

FIG. 5A and FIG. 5B are graphs illustrating a result of determining an external quantum efficiency variation rate in Comparative Example 1A.

FIG. 6A and FIG. 6B are conceptual diagrams of a stacked imaging element of Example 2.

FIG. 7 is a schematic partial cross-sectional view of a modification example of the stacked imaging element of Example 2.

FIG. 8 is a schematic partial cross-sectional view of an imaging element of Example 3.

FIG. 9 is an equivalent circuit diagram of the imaging element of Example 3.

FIG. 10 is an equivalent circuit diagram of the imaging element of Example 3.

FIG. 11 is a schematic layout diagram of a first electrode and an electric charge accumulation electrode, and transistors included in a control section that are included in the imaging element of Example 3.

FIG. 12 is a diagram schematically illustrating a state of potential at each part during operation of the imaging element of Example 3.

FIGS. 13A, FIG. 13B, and FIG. 13C are equivalent circuit diagrams of imaging elements of Example 3, Example 6, and Example 8 for describing respective parts of FIG. 12 (Example 3), FIG. 27 and FIG. 28 (Example 6), and FIG. 36 and FIG. 37 (Example 8).

FIG. 14 is a conceptual diagram of the imaging device of Example 3.

FIG. 15 is an equivalent circuit diagram of a modification example of the imaging element of Example 3.

FIG. 16 is a schematic layout diagram of the first electrode and the electric charge accumulation electrode, and the transistors included in the control section that are included in the modification example of the imaging element of Example 3 illustrated in FIG. 15.

FIG. 17 is a schematic partial cross-sectional view of another modification example of the imaging element of Example 3.

FIG. 18 is a schematic partial cross-sectional view of an imaging element of Example 4.

FIG. 19 is a schematic partial cross-sectional view of an imaging element of Example 5.

FIG. 20 is a schematic partial cross-sectional view of Modification Example-1 of the imaging element of Example 5.

FIG. 21 is a schematic partial cross-sectional view of Modification Example-2 of the imaging element of Example 5.

FIG. 22 is a schematic partial cross-sectional view of Modification Example-3 of the imaging element of Example 5.

FIG. 23 is a schematic partial cross-sectional view of the imaging element of Example 6.

FIG. 24 is an equivalent circuit diagram of the imaging element of Example 6.

FIG. 25 is an equivalent circuit diagram of the imaging element of Example 6.

FIG. 26 is a schematic layout diagram of a first electrode, a transfer control electrode, and an electric charge accumulation electrode, and transistors included in a control section that are included in the imaging element of Example 6.

FIG. 27 is a diagram schematically illustrating a state of potential at each part during operation of the imaging element of Example 6.

FIG. 28 is a diagram schematically illustrating a state of potential at each part during another operation of the imaging element of Example 6.

FIG. 29 is a schematic layout diagram of the first electrode, the transfer control electrode, and the electric charge accumulation electrode, and the transistors included in the control section that are included in a modification example of the imaging element of Example 6.

FIG. 30 is a schematic partial cross-sectional view of an imaging element of Example 7.

FIG. 31 is a schematic layout diagram of a first electrode, an electric charge accumulation electrode, and an electric charge drain electrode included in the imaging element of Example 7.

FIG. 32 is a schematic partial cross-sectional view of the imaging element of Example 8.

FIG. 33 is an equivalent circuit diagram of the imaging element of Example 8.

FIG. 34 is an equivalent circuit diagram of the imaging element of Example 8.

FIG. 35 is a schematic layout diagram of a first electrode and an electric charge accumulation electrode, and transistors included in a control section that are included in the imaging element of Example 8.

FIG. 36 is a diagram schematically illustrating a state of potential at each part during operation of the imaging element of Example 8.

FIG. 37 is a diagram schematically illustrating a state of potential at each part during another operation (during transfer) of the imaging element of Example 8.

FIG. 38 is a schematic layout diagram of the first electrode and the electric charge accumulation electrode included in the imaging element of Example 8.

FIG. 39 is a schematic layout diagram of the first electrode and the electric charge accumulation electrode included in a modification example of the imaging element of Example 8.

FIG. 40 is a schematic cross-sectional view of a portion of an imaging element of Example 9 (two imaging elements arranged side by side).

FIG. 41 is a schematic layout diagram of a first electrode, an electric charge accumulation electrode, and the like, and transistors included in a control section that are included in the imaging element of Example 9.

FIG. 42 is a schematic layout diagram of the first electrode, the electric charge accumulation electrode, and the like included in the imaging element of Example 9.

FIG. 43 is a schematic layout diagram of a modification example of the first electrode, the electric charge accumulation electrode, and the like included in the imaging element of Example 9.

FIG. 44 is a schematic layout diagram of a modification example of the first electrode, the electric charge accumulation electrode, and the like included in the imaging element of Example 9.

FIG. 45A and FIG. 45B are schematic layout diagrams of a modification example of the first electrode, the electric charge accumulation electrode, and the like included in the imaging element of Example 9.

FIG. 46 is a schematic cross-sectional view of a portion of an imaging element of Example 10 (two imaging elements arranged side by side).

FIG. 47 is a schematic plan view of a portion of the imaging element of Example 10 (2×2 imaging elements arranged side by side).

FIG. 48 is a schematic plan view of a portion of a modification example of the imaging element of Example 10 (2×2 imaging elements arranged side by side).

FIG. 49A and FIG. 49B are schematic cross-sectional views of a portion of a modification example of the imaging element of Example 10 (two imaging elements arranged side by side).

FIG. 50A and FIG. 50B are schematic cross-sectional views of a portion of a modification example of the imaging element of Example 10 (two imaging elements arranged side by side).

FIG. 51A and FIG. 51B are schematic plan views of a portion of a modification example of the imaging element of Example 10.

FIG. 52A and FIG. 52B are schematic plan views of a portion of a modification example of the imaging element of Example 10.

FIG. 53 is a schematic plan view of first electrodes and electric charge accumulation electrode segments in an imaging device of Example 11.

FIG. 54 is a schematic plan view of the first electrodes and the electric charge accumulation electrode segments in a first modification example of the imaging device of Example 11.

FIG. 55 is a schematic plan view of the first electrodes and the electric charge accumulation electrode segments in a second modification example of the imaging device of Example 11.

FIG. 56 is a schematic plan view of the first electrodes and the electric charge accumulation electrode segments in a third modification example of the imaging device of Example 11.

FIG. 57 is a schematic plan view of the first electrodes and the electric charge accumulation electrode segments in a fourth modification example of the imaging device of Example 11.

FIG. 58 is a schematic plan view of the first electrodes and the electric charge accumulation electrode segments in a fifth modification example of the imaging device of Example 11.

FIG. 59 is a schematic plan view of the first electrodes and the electric charge accumulation electrode segments in a sixth modification example of the imaging device of Example 11.

FIG. 60 is a schematic plan view of the first electrodes and the electric charge accumulation electrode segments in a seventh modification example of the imaging device of Example 11.

FIG. 61A, FIG. 61B, and FIG. 61C are charts illustrating examples of reading and driving in an imaging element block of Example 11.

FIG. 62 a schematic partial cross-sectional view of still another modification example of the imaging element and a stacked imaging element of Example 3.

FIG. 63 is a schematic partial cross-sectional view of still another modification example of the imaging element and the stacked imaging element of Example 3.

FIG. 64 is a schematic partial cross-sectional view of still another modification example of the imaging element and the stacked imaging element of Example 3.

FIG. 65 is a schematic partial cross-sectional view of another modification example of the imaging element and the stacked imaging element of Example 3.

FIG. 66 is a schematic partial cross-sectional view of still another modification example of the imaging element of Example 6.

FIG. 67 is a conceptual diagram of an example in which an imaging device including an imaging element and a stacked imaging element of the present disclosure is used in an electronic apparatus (camera).

FIG. 68 is a schematic partial cross-sectional view of a modification example of the imaging element of the present disclosure.

FIG. 69 is a diagram schematically illustrating an example of a planar configuration of the imaging element illustrated in FIG. 68.

FIG. 70 is a diagram schematically illustrating a cross-sectional configuration of another modification example of the imaging element of the present disclosure.

FIG. 71 is a diagram schematically illustrating an example of a planar configuration of the imaging element illustrated in FIG. 70.

FIG. 72 is a block diagram depicting an example of schematic configuration of a vehicle control system.

FIG. 73 is a diagram of assistance in explaining an example of installation positions of an outside-vehicle information detecting section and an imaging section.

FIG. 74 is a view depicting an example of a schematic configuration of an endoscopic surgery system.

FIG. 75 is a block diagram depicting an example of a functional configuration of a camera head and a camera control unit (CCU).

### MODES FOR CARRYING OUT THE INVENTION

In the following, description is given of the present disclosure on the basis of Examples with reference to the drawings. However, the present disclosure is not limited to Examples, and various numerical values and materials in Examples are illustrative. It is to be noted that the description is given in the following order.
1. General Description of Imaging Element of Present Disclosure, Stacked Imaging Element of Present Disclosure, and Imaging Devices According to First and Second Aspects of Present Disclosure
2. Example 1 (Imaging Element of Present Disclosure)
3. Example 2 (Modification of Example 1)
4. Example 3 (Modification of Examples 1 and 2, Imaging Element Including Electric Charge Accumulation Electrode of Present Disclosure)
5. Example 4 (Modification of Example 3)
6. Example 5 (Modification of Examples 3 and 4)
7. Example 6 (Modification of Examples 3 to 5, Imaging Element Including Transfer Control Electrode)
8. Example 7 (Modification of Examples 3 to 6, Imaging Element Including Electric Charge Drain Electrode)
9. Example 8 (Modification of Examples 3 to 7, Imaging Element Including a Plurality of Electric Charge Accumulation Electrode Segments)
10. Example 9 (Modification of Examples 3 to 8, Imaging Element Including Electric Charge Movement Control Electrode)
11. Example 10 (Modification of Example 9)
12. Example 11 (Modification of Examples 3 to 10, First Electrode Sharing Imaging Device)
13. Others

### General Description of Imaging Element of Present Disclosure, Stacked Imaging Element of Present Disclosure, and Imaging Devices According to First and Second Aspects of Present Disclosure

In the following, an imaging element of the present disclosure, an imaging element included in a stacked imaging element of the present disclosure, and an imaging element included in an imaging device according to any of a first aspect and a second aspect of the present disclosure may be collectively referred to as an “imaging element or the like of the present disclosure” in some cases. In addition, the following expression holds true:

α=M_{Mono-0}+M_{Di-0}+M_{Multi-0}
where M_{Mono-0}: mass % of a fullerene compound monomer in a photoelectric conversion layer,
MDi-0: mass % of a fullerene compound dimer in the photoelectric conversion layer,
MMulti-0: mass % of a fullerene compound trimer or a higher-order fullerene compound multimer in the photoelectric conversion layer, and
α: mass % of an electron transporting material or an electron transporting material precursor in the photoelectric conversion layer.

In the imaging element or the like of the present disclosure, a mode may be adopted in which mass % of (the fullerene compound monomer+the fullerene compound dimer) in the photoelectric conversion layer is greater than or equal to 13 mass % and less than or equal to 33 mass % (preferably less than or equal to 32 mass %). That is, it is desirable to satisfy:

β≤(M_{Mono-0}+M_{Di-0})≤33.

In addition, in such a mode, it is desirable to adopt a configuration in which a mass ratio of the electron transporting material, and the fullerene compound dimer per unit mass is greater than 0 and less than or equal to 0.4, preferably greater than or equal to 0.08 and less than 0.30. That is, it is desirable to adopt a configuration in which the following expression is satisfied:

0<M_{Di-0}≤0.4α,

and preferably

0.08α≤M_{Di-0}<0.30α.

Alternatively, in such a mode, it is desirable to adopt a configuration in which a mass ratio of the electron transporting material, and the fullerene compound trimer or the higher-order fullerene compound multimer per unit mass is less than or equal to 0.12. That is, it is desirable to adopt a configuration in which the following expression is satisfied:

M_{Multi-o0}≤0.12α,

or in some cases,

0.03α≤M_{Multi-0}≤0.12α.

In the preferred modes described above including various preferred configurations described above, a mode may be adopted in which M_{Di-1} satisfies:

M_{Di-1}/M_{Di-0}≤100,

and preferably

2≤M_{Di-1}/M_{Di-0}≤30,
where M_{Di-0} denotes mass % of the fullerene compound dimer in the photoelectric conversion layer, and M_{Di-1} denotes mass % of the fullerene compound dimer in the photoelectric conversion layer after the photoelectric conversion layer is irradiated with light of a wavelength of 560 nm having an energy of 3.2 mW/cm² for 24 hours. Alternatively, a mode may be adopted in which M_{Di-1} satisfies:

M_{Di-1}/M_{Di-0}≤100,

and preferably

2≤M_{Di-1}/M_{Di-0}≤30,
where M_{Di-1} denotes mass % of the fullerene compound dimer in the photoelectric conversion layer after the photoelectric conversion layer is irradiated with light of a wavelength of 400 nm to 1000 nm having 2×10⁵ lux for three hours.

In the imaging element or the like of the present disclosure including various preferred modes and configurations described above, a mode may be adopted in which mass % of a hole transporting material in the photoelectric conversion layer is greater than or equal to 15 mass % and less than or equal to 50 mass %. It is to be noted that the hole transporting material exhibits a behavior as a p-type organic semiconductor.

Furthermore, in the imaging element or the like of the present disclosure including various preferred modes and configurations described above, the fullerene compound monomer includes at least one kind of material selected from a group including a C60 monomer, a C60 monomer oxide, a C60 monomer derivative, a C60 monomer derivative oxide, a C70 monomer, a C70 monomer oxide, a C70 monomer derivative, a C70 monomer derivative oxide, a C74 monomer, a C74 monomer oxide, a C74 monomer derivative, and a C74 monomer derivative oxide, and the fullerene compound dimer includes at least one kind of material selected from a group including a C60 dimer, a C60 dimer oxide, a C60 dimer derivative, a C60 dimer derivative oxide, a C70 dimer, a C70 dimer oxide, a C70 dimer derivative, a C70 dimer derivative oxide, a C74 dimer, a C74 dimer oxide, a C74 dimer derivative, and a C74 dimer derivative oxide; however, a mode is preferred in which the fullerene compound monomer includes the C60 monomer, and the fullerene compound dimer includes the C60 dimer. It is to be noted that these materials exhibit a behavior as an n-type organic semiconductor.

It is to be noted that examples of a fullerene derivative include a fullerene fluoride and a PCBM fullerene compound. Alternatively, examples of groups and the like included in the fullerene derivative include: halogen atoms; a straight-chain, branched, or cyclic alkyl group or phenyl group; a group including a straight-chain or condensed aromatic compound; a group including halide; a partial fluoroalkyl group; a perfluoroalkyl group; a silylalkyl group; a silylalkoxy group; an arylsilyl group; an arylsulfanyl group; an alkylsulfanyl group; an arylsulfonyl group; an alkylsulfonyl group; an arylsulfide group; an alkylsulfide group; an amino group; an alkylamino group; an arylamino group; a hydroxy group; an alkoxy group; an acylamino group; an acyloxy group; a carbonyl group; a carboxy group; a carboxamide group; a carboalkoxy group; an acyl group; a sulfonyl group; a cyano group; a nitro group; a group including chalcogenide; a phosphine group; a phosphon group; and derivatives thereof.

Organic semiconductors are often classified into p-type and n-type. The p-type means that holes are easily transportable, and the n-type means that electrons are easily transportable. The organic semiconductor is not limited to the interpretation that it has holes or electrons as majority carriers of thermal excitation, as in inorganic semiconductors.

Furthermore, in the imaging element or the like of the present disclosure including various preferred modes and configurations described above, a mode may be adopted in which a first electrode, and a second electrode where light enters are further included, and the photoelectric conversion layer is sandwiched between the first electrode and the second electrode.

A first carrier blocking layer may be provided between the photoelectric conversion layer and the first electrode, and a second carrier blocking layer may be provided between the photoelectric conversion layer and the second electrode. In addition, a first electric charge injection layer may be provided between the first carrier blocking layer and the first electrode, and a second electric charge injection layer may be provided between the second carrier blocking layer and the second electrode. For example, examples of a material included in an electron injection layer include alkali metal, including lithium (Li), sodium (Na), and potassium (K), fluorides or oxides thereof, alkaline earth metal, including magnesium (Mg) and calcium (Ca), and fluorides or oxides thereof.

In the imaging element or the like of the present disclosure, it is preferred to adopt a mode in which the photoelectric conversion layer has a bulk hetero structure including a mixture of the hole transporting material and the electron transporting material.

The thickness of the photoelectric conversion layer may be, for example, but not limited to, 1×10⁻⁸ m to 5×10⁻⁷ m, preferably, 2.5×10⁻⁸ m to 3×10⁻⁷ m, more preferably, 2.5×10⁻⁸ m to 2×10⁻⁷ m, still more preferably, 1×10⁻⁷ m to 1.8×10⁻⁷ m.

Examples of the hole transporting material include a naphthalene derivative, an anthracene derivative, a phenanthrene derivative, a pyrene derivative, a perylene derivative, a tetracene derivative, a pentacene derivative, a quinacridone derivative, a thiophene derivative, a thienothiophene derivative, a benzothiophene derivative, a benzothienobenzothiophene derivative, a triallylamine derivative, a carbazole derivative, a perylene derivative, a picene derivative, a chrysene derivative, a fluoranthene derivative, a phthalocyanine derivative, a subphthalocyanine derivative, a subporphyrazine derivative, a metal complex including heterocyclic compounds as ligands, a polythiophene derivative, a polybenzothiadiazole derivative, a polyfluorene derivative, and the like. Alternatively, examples of the hole transporting material include a polymer or a derivative including a framework such as phenylenevinylene, fluorene, carbazole, indole, pyrene, pyrrole, or thiophene.

Examples of an organic photoelectric conversion material for performing photoelectric conversion of green light include a rhodamine-based dye, a merocyanine-based dye, a quinacridone derivative, apentacene derivative, aphthalocyanine-based dye, a subphthalocyanine-based dye (subphthalocyanine and a derivative thereof), and the like. In addition, examples of a material included in an organic photoelectric conversion material for performing photoelectric conversion of blue light include a coumaric acid dye, tris-8-hydroxyquinoline aluminum (Alq3), a merocyanine-based dye, and the like. Furthermore, examples of a material included in an organic photoelectric conversion material for performing photoelectric conversion of red light include a phthalocyanine-based dye, a subphthalocyanine-based dye (subphthalocyanine and a derivative thereof), and the like. Alternatively, examples of a material included in the organic photoelectric conversion material include a donor-7r-acceptor compound, a ruthenium dye, a squarylium dye, a perylene-based material (perylene bisimide), a porphyrin derivative, and a pyrrole-based dye.

In some cases, examples of an inorganic material included in the photoelectric conversion layer include crystalline silicon, amorphous silicon, microcrystalline silicone, crystalline selenium, amorphous selenium, chalcopyrite compounds, such as CIGS (CuInGaSe), CIS (CuInSe₂), CuInS₂, CuAlS₂, CuAlSe₂, CuGaS₂, CuGaSe₂, AgAlS₂, AgAlSe₂, AgInS₂, and AgInSe₂, or group III-V compounds, such as GaAs, InP, AlGaAs, InGaP, AlGaInP, and InGaAsP, and furthermore, compound semiconductors of CdSe, CdS, In₂Se₃, In₂S₃, Bi₂Se₃, Bi₂S₃, ZnSe, ZnS, PbSe, PbS, and the like. In addition, quantum dots including these materials are also usable for the photoelectric conversion layer. It is to be noted that in a case where the photoelectric conversion layer includes an inorganic material, a “photoelectric conversion layer including an organic photoelectric conversion material, a hole transporting material, and an electron transporting material” may be replaced with a “photoelectric conversion layer including a photoelectric conversion material, a hole transporting material, and an electron transporting material” or a “photoelectric conversion layer including an inorganic photoelectric conversion material, a hole transporting material, and an electron transporting material”.

In the imaging element or the like of the present disclosure including various preferred modes described above, photoelectric conversion is caused in the photoelectric conversion layer irradiated with light, and holes and electrons are subjected to carrier separation. In addition, an electrode from which the holes are extracted is an anode, and an electrode from which the electrons are extracted is a cathode. In general, the first electrode constitutes the cathode, and the second electrode constitutes the anode. A mode may be adopted in which light enters the photoelectric conversion layer via the second electrode. In addition, a mode may be adopted in which electric charge generated in the photoelectric conversion layer moves to the first electrode. In this case, a mode may be adopted in which the electric charge is an electron.

A configuration may be adopted in which the first electrode and the second electrode, or the first electrode and the like to be described later include transparent electrically-conductive materials. Alternatively, a configuration may be adopted in which the second electrode includes a transparent electrically-conductive material and the first electrode includes a metal material. In this case, specifically, a configuration may be adopted in which the second electrode positioned on light incident side includes a transparent electrically-conductive material and the first electrode includes, for example, Al—Nd (alloy of aluminum and neodymium) or ASC (alloy of aluminum, samarium, and copper). An electrode including a transparent electrically-conductive material is referred to as a “transparent electrode” in some cases. Examples of the transparent electrically-conductive material included in the transparent electrode include electrically-conductive metal oxides. Specific examples thereof include aluminum oxide, aluminum-tin oxide, aluminum-zinc oxide (AZO) in which aluminum is added as a dopant to zinc oxide, aluminum-gallium oxide in which aluminum is added as a dopant to gallium oxide, aluminum-gallium-zinc oxide in which aluminum and gallium are added as dopants to zinc oxide, aluminum-tin-zinc oxide in which aluminum and tin are added as dopants to zinc oxide, gallium-zinc oxide (GZO) in which gallium is added to zinc oxide, IFO (F-doped In₂O₃), tin oxide (SnO₂), ATO (Sb-doped SnO₂), FTO (F-doped SnO₂), zinc oxide (including ZnO doped with another element), titanium oxide (TiO₂), niobium-titanium oxide (TNO) in which niobium is added as a dopant to titanium oxide, antimony oxide, CuI, InSbO₄, ZnMgO, CuInO₂, MgIn₂O₄, CdO, ZnSnO₃, spinel oxide, and an oxide having YbFe₂O₄ structure. Alternatively, the transparent electrode may include gallium oxide, titanium oxide, niobium oxide, nickel oxide, or the like as a mother layer. An example of the thickness of the transparent electrode may be 2×10⁻⁸ m to 2×10⁻⁷ m, and preferably 3×10⁻⁸ m to 1×10⁻⁷ m.

Alternatively, in a case where transparency is not necessary, it is preferred to use an electrically-conductive material with a low work function (e.g., ϕ=3.5 eV to 4.5 eV) as an electrically-conductive material included in the cathode that functions as an electrode for extracting electrons. Specific examples of such an electrically-conductive material include alkali metal (e.g., Li, Na, K, and the like) and fluorides or oxides thereof, alkaline earth metal (e.g., Mg, Ca, and the like) and fluorides or oxides thereof, aluminum (Al), zinc (Zn), tin (Sn), thallium (Tl), a sodium-potassium alloy, an aluminum-lithium alloy, a magnesium-silver alloy, indium, rare earth metal such as ytterbium, and alloys thereof. Alternatively, examples of the material included in the cathode include electrically-conductive materials, including metal such as platinum (Pt), gold (Au), palladium (Pd), chromium (Cr), nickel (Ni), silver (Ag), tantalum (Ta), tungsten (W), copper (Cu), titanium (Ti), iron (Fe), cobalt (Co), or molybdenum (Mo), alloys including these metal elements, electrically-conductive particles including these metals, electrically-conductive particles of alloys including these metals, polysilicon including impurities, carbon materials, oxide semiconductor materials, carbon nanotubes, graphene, and the like, and stacked structures of layers including these elements. Further examples of the material included in the cathode include organic materials (electrically-conductive polymers) such as poly(3,4-ethylenedioxythiophene)/polystyrenesulfonic acid [PEDOT/PSS]. In addition, these electrically-conductive materials may be mixed with a binder (polymer) into a paste or an ink, and the paste or the ink may be cured and used as an electrode.

A dry method or a wet method is usable as a film-formation method for the first electrode and the second electrode (the cathode and the anode). Examples of the dry method include a physical vapor deposition method (PVD method) and a chemical vapor deposition method (CVD method). Examples of the film-formation method using the principle of the PVD method include a vacuum deposition method using resistance heating or high frequency heating, an EB (electron beam) deposition method, various sputtering methods (a magnetron sputtering method, an RF-DC coupled bias sputtering method, an ECR sputtering method, a facing-target sputtering method, and a high frequency sputtering method), an ion plating method, a laser ablation method, a molecular beam epitaxy method, and a laser transfer method. In addition, examples of the CVD method include a plasma CVD method, a thermal CVD method, an organic metal (MO) CVD method, and an optical CVD method. Meanwhile, examples of the wet method include an electrolytic plating method and an electroless plating method, a spin coating method, an ink jet method, a spray coating method, a stamping method, a micro contact printing method, a flexographic printing method, an offset printing method, a gravure printing method, a dipping method, and the like. Examples of patterning methods include chemical etching, including shadow mask, laser transfer, photolithography, and the like, and physical etching by ultraviolet light, laser, or the like. As a planarization technique for the first electrode and the second electrode, a laser planarization method, a reflow method, a CMP (Chemical Mechanical Polishing) method, or the like is usable.

Examples of a film-formation method for various organic layers include a dry film-forming method and a wet film-forming method. Examples of the dry film-forming method include a vacuum deposition method using resistance heating, high frequency heating, or electron beam heating, a flash deposition method, a plasma deposition method, an EB deposition method, various sputtering methods (a bipolar sputtering method, a direct current sputtering method, a direct current magnetron sputtering method, a high frequency sputtering method, a magnetron sputtering method, an RF-DC coupled bias sputtering method, an ECR sputtering method, a facing-target sputtering method, a high frequency sputtering method, and an ion beam sputtering method), a DC (Direct Current) method, an RF method, a multi-cathode method, an activation reaction method, an electric field deposition method, various ion plating methods including a high-frequency ion plating method and a reactive ion plating method, a laser ablation method, a molecular beam epitaxy method, a laser transfer method, and a molecular beam epitaxy (MBE) method. In addition, examples of the CVD methods include a plasma CVD method, a thermal CVD method, an MOCVD method, and a photo CVD method. Meanwhile, specific examples of the wet method include a spin coating method; a dipping method; a casting method; a micro contact printing method; a drop casting method; various printing methods including a screen printing method, an ink jet printing method, an offset printing method, a gravure printing method, and a flexographic printing method; a stamping method; a spray method; various coating methods including an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Examples of a solvent in the coating method include nonpolar or low polar organic solvents including toluene, chloroform, hexane, and ethanol. Examples of patterning methods include chemical etching including shadow mask, laser transfer, photolithography, and the like, and physical etching by ultraviolet light, laser, or the like. As a planarization technique for various organic layers, a laser planarization method, a reflow method, or the like is usable.

In the imaging element or the like of the present disclosure, an on-chip microlens and a light-blocking layer may be provided as necessary. In addition, in the imaging element or the like of the present disclosure, a drive circuit and wiring lines for driving the imaging element are provided. Furthermore, a mode may be adopted in which the imaging element or the like further includes a semiconductor substrate, and a photoelectric conversion section in which the first electrode, the photoelectric conversion layer, and the second electrode are stacked is disposed above the semiconductor substrate. It is to be noted that the first electrode and the second electrode, or various electrodes are coupled to a drive circuit to be described later. A shutter for controlling incidence of light on the imaging element may be disposed as necessary, and an optical cut filter may be provided according to the purpose of an imaging device including a plurality of imaging elements.

Examples of the imaging element or the like of the present disclosure including various preferred modes and configurations described above may include a CCD element, a CMOS image sensor, a CIS (Contact Image Sensor), and a signal amplification image sensor of a CMD (Charge Modulation Device) type. The imaging element of the present disclosure, and the imaging devices according to the first and second aspects of the present disclosure including the imaging element of the present disclosure or the stacked imaging element of the present disclosure are able to be included in, for example, a digital still camera, a video camera, a camcorder, a monitoring camera, an on-vehicle camera, a smartphone camera, a user interface camera for games, and a biometric authentication camera. In addition, the imaging device may also be included in a modular form to be mounted on an electronic apparatus, i.e., a camera module.

### Example 1

Example 1 relates to the imaging element of the present disclosure. An imaging element (photoelectric conversion element) of Example 1 includes a photoelectric conversion layer 23 including an organic photoelectric conversion material, a hole transporting material, and an electron transporting material, and the electron transporting material includes a fullerene compound monomer and a fullerene compound dimer.

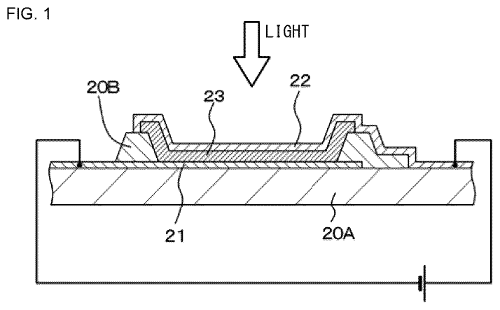

As illustrated in a conceptual diagram in FIG. 1, the imaging element of Example 1 includes at least a first electrode 21, the photoelectric conversion layer 23, and a second electrode 22 that are stacked in order. It is to be noted that such a stacked structure may be referred to as a “photoelectric conversion section” in some cases. In addition, the first electrode 21 is formed on a substrate 20A, and a frame-shaped insulating film 20B is formed on the first electrode 21. The photoelectric conversion layer 23 and the second electrode 22 are stacked in order on the insulating film 20B.

Here, in Example 1, for example, as the organic photoelectric conversion material, a subphthalocyanine derivative (F6-SubPC-OPh26F2) was used, and as the hole transporting material, a benzothiophene-based material was used. In addition, the electron transporting material includes a C60 monomer and a C60 dimer.

Then, the first electrode 21 including ITO and having a thickness of 0.1 m was formed on a quartz substrate or a glass substrate, and a p-buffer material layer (not illustrated) having a thickness of 10 nm was formed as a base on the first electrode 21. The organic photoelectric conversion material, the hole transporting material, and an electron transporting material precursor were co-deposited on the p-buffer material layer to have a mass ratio of (the organic photoelectric conversion material: the hole transporting material: the electron transporting material precursor) of (40:40:20). Thus, a co-deposited layer was obtained. It is to be noted that the electron transporting material precursor includes a C60 monomer. Next, an n-buffer material layer (not illustrated) having a thickness of 10 nm was formed on the co-deposited layer, and the second electrode 22 including ITO and having a thickness of 50 nm was formed on the n-buffer material layer. Thereafter, irradiation with light of a wavelength of 560 nm (3.2 mW/cm²) was performed for 3.5 hours in an atmosphere of a nitrogen gas or an argon gas at a temperature of 160° C., thus making it possible to obtain the photoelectric conversion layer 23 sandwiched between the first electrode 21 and the second electrode 22. That is, the imaging element of Example 1 further includes the first electrode 21, and the second electrode 22 where light enters, and the photoelectric conversion layer 23 is sandwiched between the first electrode 21 and the second electrode 22.

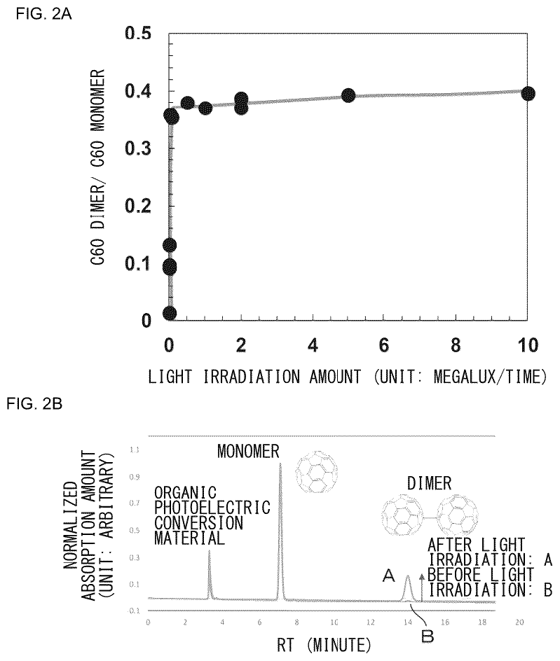

FIG. 2A illustrates a result of examining a relationship between light irradiation time and change in ratio of (a C60 dimer/a C60 monomer) in the photoelectric conversion layer. After start of irradiation with light, the C60 dimer is immediately generated, and after that, the ratio of (the C60 dimer/the C60 monomer) hardly changes. It is to be noted that a horizontal axis in FIG. 2A is a light irradiation amount (unit: megalux/time).

In the co-deposited layer, the C60 dimer and a fullerene compound trimer or higher-order fullerene compound multimer are generated from a portion of the C60 monomer that is the electron transporting material precursor by light irradiation processing. This makes it possible to obtain the photoelectric conversion layer 23 including the fullerene compound monomer (specifically, the C60 monomer), the fullerene compound dimer (specifically, the C60 dimer), and the fullerene compound trimer or higher-order fullerene compound multimer.

In analysis of components of the electron transporting material, a result illustrated in the following Table 1 was obtained. That is, when the content of the electron transporting material precursor in the photoelectric conversion layer was 20 mass % (=α), a portion of 20 mass % of the electron transporting material precursor was changed into the C60 dimer and the fullerene compound multimer (specifically, a C60 trimer). It is to be noted that, as illustrated in an example in FIG. 2B, it is possible to quantitatively determine a monomer and a dimer of C60 in the electron transporting material on the basis of a high performance liquid chromatography method (HPLC method), and it is also possible to quantitatively determine a multimer of C60 on the basis of the HPLC method. It is to be noted that in FIG. 2B, “A” indicates a peak of the C60 dimer after irradiation with light, and “B” indicates a peak of the C60 dimer before irradiation with light.

TABLE 1

| | |
|---|---|
| C60 Monomer | 18.0 mass % |
| C60 Dimer | 1.53 mass % |
| C60 Trimer | 0.47 mass % |
| <Total of Electron Transporting Material = α> | 20.0 mass % |

Various samples were prototyped, and a test was performed. When the photoelectric conversion layer included 15 mass % to 33 mass % (15≤a≤33) of the electron transporting material precursor, the obtained photoelectric conversion layer exhibited superior characteristics.

Furthermore, when various samples were prototyped, and a test was performed, 0.1α mass % to 0.5α mass % of the electron transporting material precursor was changed into the C60 dimer and the fullerene compound multimer.

Here, the following expression holds true:

α=M_{Mono-0}+M_{Di-0}+M_{Multi-0}.

Then, change in composition of the electron transporting material at that time is as illustrated in the following Table 2.

TABLE 2

<Maximum> <Minimum>
C60 Monomer 0.90α mass % to 0.50α mass %
<Maximum> <Minimum>
C60 Dimer 0.075α mass % to 0.38α mass %
C60 Trimer 0.025α mass % to 0.12α mass %

In addition, a formation mass ratio of the C60 dimer and the C60 trimer was (3:1) in the example described above; however, when various samples were prototyped, and a test was performed, the formation mass ratio of the C60 dimer and the C60 trimer was within a range from (3:0.75) to (3:1.25).

From the above result, when a minimum of 15 mass % of the electron transporting material precursor is included (that is, α=15), the photoelectric conversion layer includes:
C60 monomer (maximum): 15 (mass %)×0.9=13.5 mass %,
C60 dimer (minimum): 15 (mass %)×0.075=1.1 mass %, and
C60 trimer (minimum): 15 (mass %)×0.025=0.4 mass %.

In addition, from the above result, when a minimum of 15 mass % of the electron transporting material precursor is included, the photoelectric conversion layer includes:
C60 monomer (minimum): 15 (mass %)×0.5=7.5 mass %,
C60 dimer (maximum): 15 (mass %)×0.38=5.7 mass %, and
C60 trimer (maximum): 15 (mass %)×0.12=1.8 mass %.

Meanwhile, when a maximum of 33 mass % of the electron transporting material precursor is included (that is, α=33), the photoelectric conversion layer includes:
C60 monomer (maximum): 33 (mass %)×0.9=29.7 mass %,
C60 dimer (minimum): 33 (mass %)×0.075=2.5 mass %, and
C60 trimer (minimum): 33 (mass %)×0.025=0.8 mass %.

In addition, from the above result, when a minimum of 33 mass % of the electron transporting material precursor is included, the photoelectric conversion layer includes:
C60 monomer (minimum): 33 (mass %)×0.5=16.5 mass %,
C60 dimer (maximum): 33 (mass %)×0.38=12.5 mass %, and
C60 trimer (maximum): 33 (mass %)×0.12=4.0 mass %.

Accordingly, when mass % of (the fullerene compound monomer+the fullerene compound dimer) in the photoelectric conversion layer was greater than or equal to 13 mass % and 32 mass % (preferably less than or equal to 33 mass % in consideration of variations), the obtained photoelectric conversion layer exhibited superior characteristics. It is to be noted that “greater than or equal to 13 mass %” is specified based on “15(%)×0.5+15(%)×0.38”, and “less than or equal to 32 mass %” is specified based on “33(%)×0.9+33(%)×0.075”.

In addition, as illustrated in Table 2 described above, the photoelectric conversion layer included 0.38a mass % or less of the C60 dimer, the obtained photoelectric conversion layer exhibited superior characteristics. That is, it is appreciated that it is desirable that the mass ratio of the electron transporting material, and the fullerene compound dimer per unit mass be greater than 0 and less than or equal to 0.4, preferably greater than or equal to 0.08 and less than 0.3. That is, it is appreciated that it is desirable to satisfy:

0<M_{Di-0}≤0.4α,

and preferably

0.08α≤M_{Di-0}≤0.30α.

Furthermore, as illustrated in Table 2 described above, when the photoelectric conversion layer included 12a mass % or less of the C60 trimer, the obtained photoelectric conversion layer exhibited superior characteristics. That is, is, it is appreciated that it is desirable that the mass ratio of the electron transporting material, and the fullerene compound trimer or the higher-order fullerene compound multimer per unit mass be less than or equal to 0.12, and preferably greater than or equal to 0.03 and less than or equal to 0.12. That is, it is appreciated that it is desirable to satisfy:

M_{Multi-0}≤0.12α,

and preferably

0.03α≤M_{Multi-0}≤0.12α.

In addition, various samples were prototyped, and a test was performed. When mass % of the hole transporting material in the photoelectric conversion layer was greater than or equal to 15 mass % and less than or equal to 50 mass %, the obtained photoelectric conversion layer exhibited superior characteristics.

Then, it is appreciated that in a case where the hole transporting material is present in the photoelectric conversion layer, formation of the fullerene compound multimer is suppressed. This is new findings.

Specifically, the organic photoelectric conversion material, the hole transporting material, and the electron transporting material precursor were co-deposited to have a mass ratio of (the organic photoelectric conversion material: the hole transporting material: the electron transporting material precursor) of (1:1:1), thereby obtaining a co-deposited layer. It is to be noted that the electron transporting material precursor includes a C60 monomer. Then, an imaging element of Example 1A was obtained from the organic photoelectric conversion material, the hole transporting material, and the electron transporting material precursor in a manner similar to that described above.

Meanwhile, the organic photoelectric conversion material and the electron transporting material precursor were co-deposited without using the hole transporting material to have a mass ratio of (the organic photoelectric conversion material: the hole transporting material: the electron transporting material precursor) of (2:0:1), thereby obtaining a co-deposited layer. It is to be noted that the electron transporting material precursor includes a C60 monomer. Then, an imaging element of Comparative Example 1A was obtained from the organic photoelectric conversion material and the electron transporting material precursor in a manner similar to that described above.

The following Table 3 illustrates results of determining M_{Mono-0}, M_{Di-0}, and M_{Multi-0} in Example 1A and Comparative Example 1A, and it is appreciated that formation of a fullerene compound multimer is relatively suppressed by presence of the hole transporting material.

TABLE 3

| | Example 1A | Comparative Example 1A |
|---|---|---|
| α | 33 | 66 |
| M_{Mono-0} | 16.2 | 21.8 |
| M_{Di-0} | 7.6 | 15.8 (2.1 times larger than Example 1A) |
| M_{Multi-0} | 8.3 | 28.4 (3.4 times larger than Example 1A) |

A mechanism of suppressing formation of the fullerene compound multimer by presence of the hole transporting material is described below.

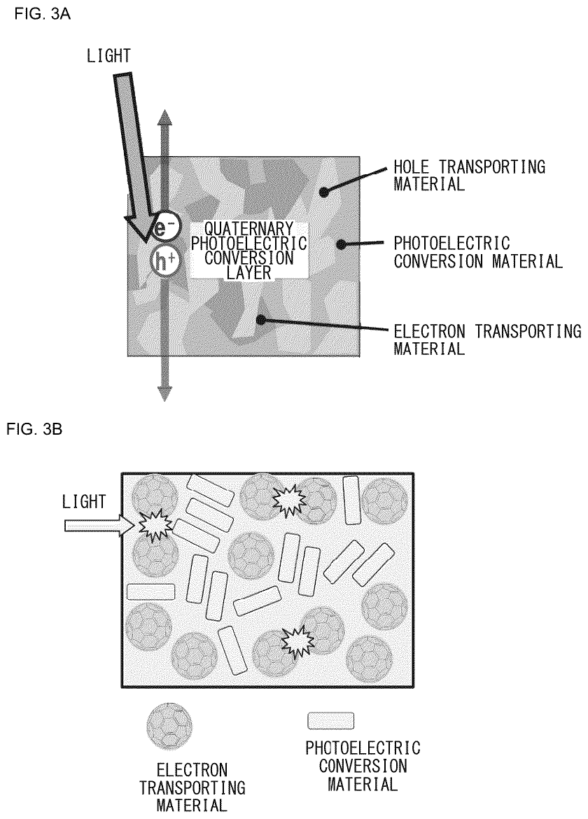

As illustrated in a conceptual diagram in FIG. 3B, the organic photoelectric conversion material and the C60 monomer (electron transporting material) are present in the photoelectric conversion layer. However, in a case where the hole transporting material is not present, a possibility (probability) that the C60 monomers come into contact with each other or come close to each other. As a result, irradiation with light causes formation of the C60 dimer and the C60 multimer. Furthermore, formation of the C60 dimer and the C60 multimer continues over time, and degradation in characteristics of the photoelectric conversion layer occurs. Specifically, degradation in EQE (external quantum efficiency) of the photoelectric conversion layer occurs. It is conceivable that, as compared with the C60 dimer, the 60 multimer inhibits exciton dissociation, and also inhibits carrier transport.

In contrast, as illustrated in a conceptual diagram in FIG. 3A, in a case where the hole transporting material is present, the hole transporting material has a function of causing phase separation, and in general, the hole transporting material has relatively high crystallinity, and the hole transporting material easily gets in between the organic photoelectric conversion material and the electron transporting material, which decreases a possibility (probability) that the C60 monomers come into contact with each other or come close to each other. In addition, the hole transporting material and the electron transporting material include many πelectron systems; therefore, the hole transporting material and the electron transporting material interact relatively easily and come close to each other easily, which prevents aggregation of dimers or higher-order multimers. Then, as a result, it is possible to suppress formation of a large amount of the C60 dimer and the C60 multimer and suppress continuation of formation of the C60 dimer and the C60 multimer over time even by irradiation with light; therefore, degradation in characteristics of the photoelectric conversion layer does not easily occur. Specifically, degradation in EQE of the photoelectric conversion layer does not easily occur.

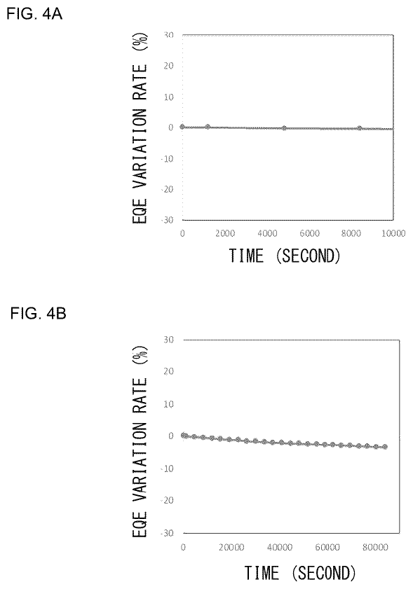

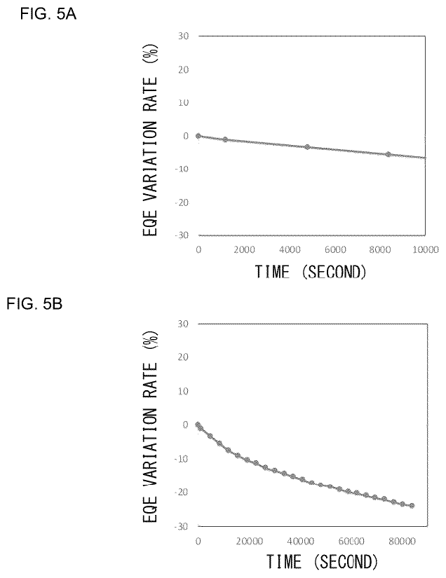

FIGS. 4A and 4B illustrate a result of determining an EQE variation rate in Example 1A, and FIGS. 5A and 5B illustrate a result of determining an EQE variation rate in Comparative Example 1A. Here, FIG. 4A and FIG. 5A each illustrate an EQE variation rate until the lapse of 10000 seconds, and FIG. 4B and FIG. 5B each illustrate an EQE variation rate after the lapse of 10000 seconds. It is to be noted that in a test for determining the EQE variation rates, a voltage of 2.6 volts was applied between the first electrode and the second electrode, and irradiation with light having light intensity (3.2 mW/cm²) of 2000 times higher than that of standard light (1.62 μW/cm²) of a wavelength of 560 nm was performed for a predetermined time in a test atmosphere at a temperature of 95° C. The EQE variation rates (%) after the lapse of 1×104 seconds and after the lapse of 8.4×104 seconds are as illustrated in the following Table 4.

TABLE 4
EQE Variation Rate (%)

| | After lapse of | After lapse of |
|---|---|---|
| | 1 × 104 seconds | 8.4 × 104 seconds |
| Example 1A | −0.8% or less | −4% or less |
| Comparative | About −10% | About −20% |
| Example 1A | | |

To summarize the above results, it is appreciated that M_{Di-1} satisfies:

M_{Di-1}/M_{Di-0}≤100,

and preferably

2≤M_{Di-1}/M_{Di-0}≤30,
where M_{Di-0} denotes mass % of the fullerene compound dimer in the photoelectric conversion layer, and M_{Di-1} denotes mass % of the fullerene compound dimer in the photoelectric conversion layer after the photoelectric conversion layer is irradiated with light of a wavelength of 560 nm having an energy of 3.2 mW/cm² for 24 hours. Alternatively, it is appreciated that M_{Di-1} satisfies:

M_{Di-1}/M_{Di-0}≤100,

and preferably

2≤M_{Di-1}/M_{Di-0}≤30,
where M_{Di-1} denotes mass % of the fullerene compound dimer in the photoelectric conversion layer after the photoelectric conversion layer is irradiated with light of a wavelength of 400 nm to 1000 nm having 2×10⁵ lux for three hours.

It is to be noted that as the hole transporting material, specifically, it is possible to use, for example, a benzothienobenzothiophene derivative (DPh-BTBT) in the following expression (1), BP-ChDT in the following expression (2), and BP-rBDT in the following expression (3), but the hole transporting material is not limited thereto.

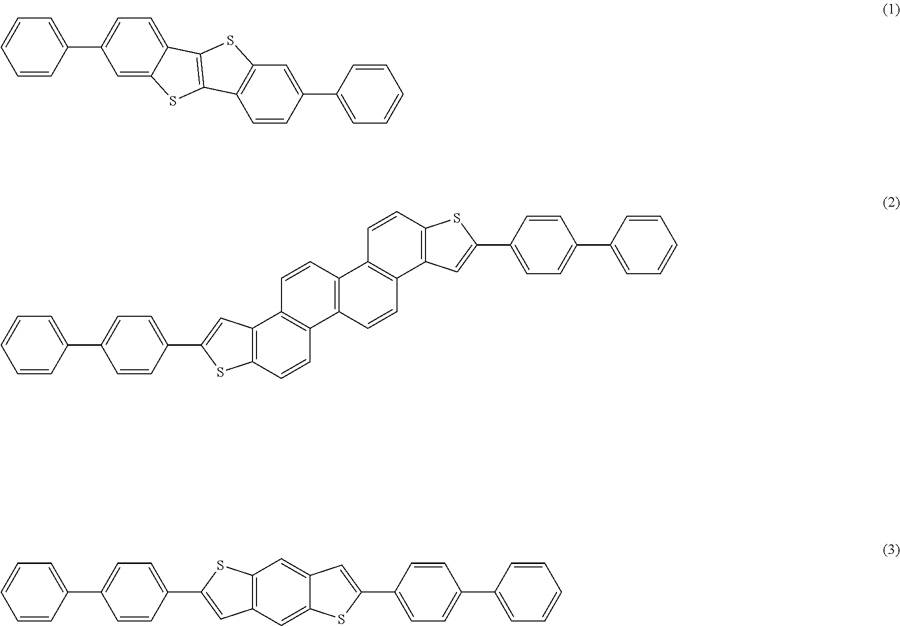 [SMILES: c1ccc(-c2ccc3c(c2)sc2c4ccc(-c5ccccc5)cc4sc32)cc1 ; c1ccc(-c2ccc(-c3cc4c(ccc5c4ccc4c6ccc7sc(-c8ccc(-c9ccccc9)cc8)cc7c6ccc54)s3)cc2)cc1 ; c1ccc(-c2ccc(-c3cc4cc5sc(-c6ccc(-c7ccccc7)cc6)cc5cc4s3)cc2)cc1]

### Example 2

Example 2 is a modification of the imaging element of Example 1, and relates to the stacked imaging element of the present disclosure and the imaging device (stacked imaging device) according to the second aspect of the present disclosure.

Incidentally, an imaging element in which an organic semiconductor material is used for a photoelectric conversion layer is able to perform photoelectric conversion of a specific color (wavelength band). Having such a characteristic, in a case where the imaging element is used as an imaging element, makes it possible to obtain a structure including stacked subpixels (stacked imaging element) that is not possible to obtain with an existing imaging device. In the structure, a combination of an on-chip color filter layer (OCCF) and an imaging element constitutes a subpixel, and the subpixels are arranged in a two-dimensional pattern. Furthermore, because a demosaic treatment is unnecessary, the imaging element has an advantage of not generating false colors. In the following description, an imaging element including a photoelectric conversion section provided on or above a semiconductor substrate is referred to as an “imaging element of a first type” for the sake of convenience, and the photoelectric conversion section included in the imaging element of the first type is referred to as a “photoelectric conversion section of the first type” for the sake of convenience. In addition, in some cases, an imaging element provided in the semiconductor substrate may be referred to as an “imaging element of a second type” for the sake of convenience, and a photoelectric conversion section included in the imaging element of the second type may be referred to as a “photoelectric conversion section of the second type” for the sake of convenience.

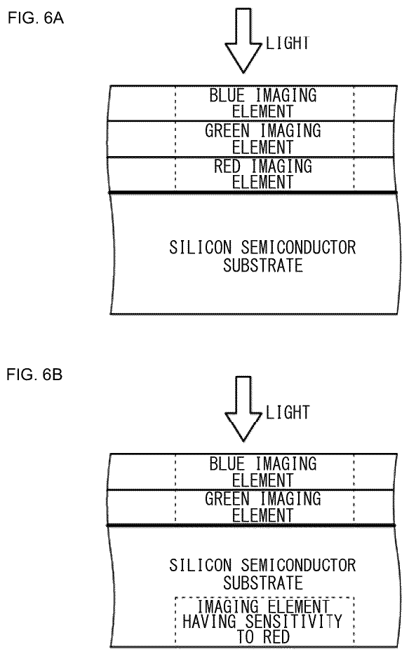

A stacked imaging element (longitudinal spectral imaging element) of Example 2 includes at least one stacked imaging element described in Example 1. In addition, a stacked imaging device of Example 2 includes a plurality of such stacked imaging elements. Specifically, as illustrated in a conceptual diagram in FIG. 6A, the stacked imaging element of Example 2 has a configuration in which three imaging elements (three subpixels) including a blue light imaging element, a green light imaging element, and a red light imaging element described in Example 1 are stacked in a vertical direction. That is, it is possible to obtain a stacked imaging element having a structure in which subpixels are stacked to constitute one pixel. The blue light imaging element is positioned in the highest layer; the green light imaging element is positioned in an intermediate layer; and the red light imaging element is positioned in the lowest layer. However, the stacking order is not limited thereto.

Alternatively, as illustrated in a conceptual diagram in FIG. 6B, the imaging elements described in Example 1 (the blue light imaging element and the green light imaging element in the illustrated example) are provided on a silicon semiconductor substrate, and one or a plurality of photoelectric conversion regions (which are imaging elements, and photoelectric conversion regions having sensitivity to red in the illustrated example) is provided in the silicon semiconductor substrate positioned below these imaging elements, which makes it possible to obtain a stacked imaging element having a structure in which the imaging elements are stacked, that is, a structure in which subpixels are stacked to constitute one pixel.

Alternatively, the imaging element described in Example 1 (e.g., one imaging element of the blue light imaging element and the green light imaging element) is provided on the silicon semiconductor substrate, and a plurality of (e.g., two) photoelectric conversion regions (imaging elements) is provided in the silicon semiconductor substrate positioned below that imaging element, which makes it possible to obtain a stacked imaging element having a structure in which the imaging elements are stacked, that is, a structure in which subpixels are stacked to constitute one pixel.

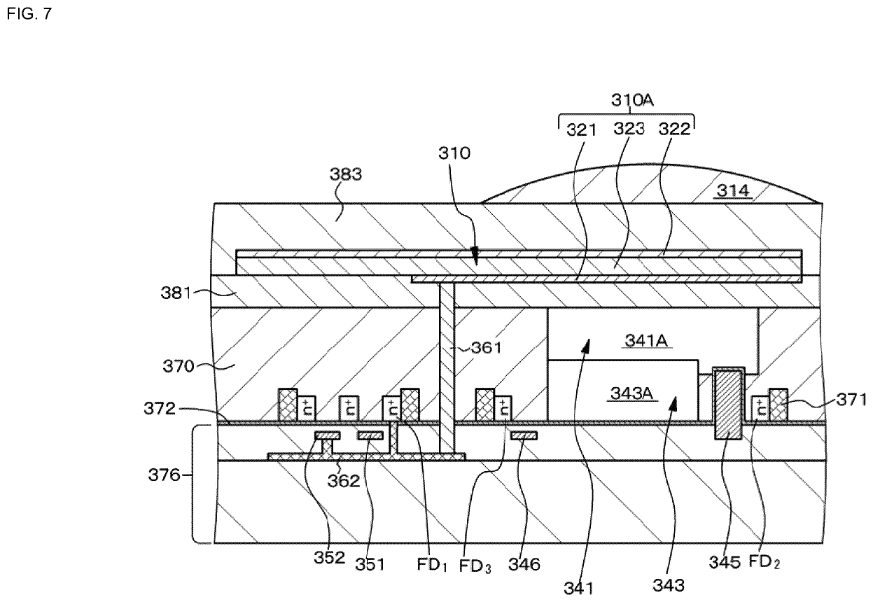

FIG. 7 illustrates one configuration example of such a stacked imaging element of Example 2. In an example illustrated in FIG. 7, a third photoelectric conversion section 343A and a second photoelectric conversion section 341A are stacked and formed in a semiconductor substrate 370. The third photoelectric conversion section 343A and the second photoelectric conversion section 341A are photoelectric conversion sections of the second type, and constitute a third imaging element 343 and a second imaging element 341 that are imaging elements of the second type. In addition, a first photoelectric conversion section 310A, which is a photoelectric conversion section of the first type, is disposed above the semiconductor substrate 370 (specifically, above the second imaging element 341). Here, the first photoelectric conversion section 310A includes the photoelectric conversion section described in Example 1 (specifically, includes a first electrode 321, a photoelectric conversion layer 323 including an organic material, and a second electrode 322). The first photoelectric conversion section 310A is included in a first imaging element 310 that is an imaging element of the first type. The second photoelectric conversion section 341A and the third photoelectric conversion section 343A photoelectrically convert, for example, blue light and red light, respectively, owing to a difference in absorption coefficient. In addition, the first photoelectric conversion section 310A photoelectrically converts, for example, green light.

Electric charge generated by the photoelectric conversion in the second photoelectric conversion section 341A and the third photoelectric conversion section 343A is temporarily accumulated in the second photoelectric conversion section 341A and the third photoelectric conversion section 343A. Thereafter, a vertical transistor (a gate section 345 is illustrated) and a transfer transistor (a gate section 346 is illustrated) transfer the electric charge to a second floating diffusion layer (Floating Diffusion) FD₂ and a third floating diffusion layer FD₃, respectively, and the electric charge is further outputted to an external readout circuit (not illustrated). The transistors and the floating diffusion layers FD₂ and FD₃ are also formed in the semiconductor substrate 370.

Electric charge generated by the photoelectric conversion in the first photoelectric conversion section 310A is accumulated in a first floating diffusion layer FD₁ formed in the semiconductor substrate 370 through a contact hole section 361 and a wiring layer 362. In addition, the first photoelectric conversion section 310A is also coupled to a gate section 352 of an amplification transistor that converts the electric charge amount into voltage through the contact hole section 361 and the wiring layer 362. In addition, the first floating diffusion layer FD₁ constitutes a portion of a reset transistor (a gate section 351 is illustrated). Reference numeral 371 denotes an element separation region. Reference numeral 372 denotes an oxide film formed on a surface of the semiconductor substrate 370. Reference numerals 376 and 381 denote interlayer insulating layers. Reference numeral 383 denotes a protection material layer. Reference numeral 314 denotes an on-chip microlens.

In the imaging element of Example 2 illustrated in FIG. 7, the electric charge generated by the photoelectric conversion in the second photoelectric conversion section 341A and the third photoelectric conversion section 343A is once accumulated in the second photoelectric conversion section 341A and the third photoelectric conversion section 343A, and is thereafter transferred to the second floating diffusion layer FD₂ and the third floating diffusion layer FD₃. It is therefore possible to completely deplete the second photoelectric conversion section 341A and the third photoelectric conversion section 343A. However, the electric charge generated by photoelectric conversion in the first photoelectric conversion section 310A is accumulated directly in the first floating diffusion layer FD₁. It is therefore difficult to completely deplete the first photoelectric conversion section 310A in some cases. Then, as a result, kTC noise becomes greater and random noise deteriorates, which may possibly cause reduction in quality of captured images. In such a case, it is desirable to use a stacked imaging element including an electric charge accumulation electrode that is to be described in Example 3 described below or a subsequent example.

The photoelectric conversion regions (imaging elements) formed in the silicon semiconductor substrate are preferably of a back illuminated type, but may be of a front illuminated type. In place of providing the photoelectric conversion region in the silicon semiconductor substrate, it is possible to form a photoelectric conversion region on a semiconductor substrate by an epitaxial growth method, or it is possible to form a photoelectric conversion region in a silicon layer in a so-called SOI structure.

In the stacked imaging element of Example 2, in order not to interfere with light reception by an imaging element positioned below, in an imaging element positioned above, the first electrode includes, for example, a transparent electrically-conductive material such as ITO, and the second electrode also includes, for example, a transparent electrically-conductive material such as ITO.

In the stacked imaging device of Example 2 including the stacked imaging element, the imaging elements having sensitivity to light of a plurality of types of wavelengths are stacked in a direction in which light enters within the same pixel without using a color filter layer for performing blue, green, or red spectral separation, which makes it possible to achieve improvement of sensitivity and improvement of pixel density per unit volume. In addition, organic materials are high in absorption coefficient, and thus make it possible to reduce the thickness of the photoelectric conversion layer compared with an existing Si-based photoelectric conversion layer. This reduces leakage of light from adjacent pixels and eases restrictions on a light incident angle. Further, while existing Si-based imaging elements suffer from generation of false colors because an interpolation process is performed for pixels of three colors to create color signals, the generation of the false colors is suppressed in the stacked imaging device of Example 2 including the stacked imaging element.

### Example 3

Example 3 is a modification of Example 1 and Example 2.

Incidentally, an imaging element preferably has a structure for accumulating and transferring signal electric charge generated in a photoelectric conversion layer on the basis of photoelectric conversion in an organic photoelectric conversion material. In an imaging element of Example 3 (including both the imaging element of the present disclosure and the stacked imaging element of the present disclosure, and in the following description, these imaging elements may be collectively referred to as a “stacked imaging element or the like” in some cases), a photoelectric conversion section including a first electrode, the photoelectric conversion layer described in Example 1, and a second electrode that are stacked further includes an insulating layer and an electric charge accumulation electrode that is disposed at a distance from the first electrode and disposed to be opposed to the photoelectric conversion layer with the insulating layer interposed therebetween. It is to be noted that, for the sake of convenience, such an imaging element of Example 3 may be referred to as an “imaging element including the electric charge accumulation electrode of the present disclosure” in some cases.

In the stacked imaging element or the like of the present disclosure, as described above, as long as the electric charge accumulation electrode is provided that is disposed at a distance from the first electrode and disposed to be opposed to the photoelectric conversion layer with the insulating layer interposed therebetween, it is possible to accumulate electric charge in the photoelectric conversion layer when the photoelectric conversion section is irradiated with light and photoelectric conversion occurs in the photoelectric conversion section. It is therefore possible to completely deplete a portion in which electric charge is accumulated (the photoelectric conversion section and an electric charge accumulation section) and eliminate the electric charge when exposure is started. As a result, it is possible to suppress the occurrence of the phenomenon that the kTC noise becomes greater and the random noise deteriorates to cause reduction in quality of captured images.

In the following, an overall description is given of the imaging element and the imaging device of Example 3, and thereafter, a detailed description is given of the imaging element and the imaging device of Example 3. Symbols representing potentials to be applied to various electrodes described below are listed in the following Table 5.

TABLE 5

| | Electric Charge | Electric Charge |
|---|---|---|
| | Accumulation | Transfer |
| | Period | Period |
| First Electrode | V₁₁ | V₁₂ |
| Second Electrode | V₂₁ | V₂₂ |
| Electric Charge Accumulation | V₃₁ | V₃₂ |
| Electrode | | |
| Electric Charge Movement | V₄₁ | V₄₂ |
| Control Electrode | | |
| Transfer Control Electrode | V₅₁ | V₅₂ |
| Electric Charge Drain Electrode | V₆₁ | V₆₂ |

In the imaging element including the electric charge accumulation electrode of the present disclosure, a mode may be adopted in which the photoelectric conversion layer includes an inorganic oxide semiconductor material layer directly therebelow. The inorganic oxide semiconductor material layer may have a single-layer configuration, or a multilayer configuration. In addition, an inorganic oxide semiconductor material positioned above the electric charge accumulation electrode and an inorganic oxide semiconductor material positioned above the first electrode may be different from each other. It is preferred that the inorganic oxide semiconductor material layer have a light transmittance of 65% or more for light of a wavelength of 400 nm to 660 nm. In addition, it is preferred that the electric charge accumulation electrode also have a light transmittance of 65% or more for light of a wavelength of 400 nm to 660 nm. It is preferred that the electric charge accumulation electrode have a sheet resistance of 3×10Ω/□ to 1×10³Ω/□. It is desirable that the inorganic oxide semiconductor material layer have a thickness of 1×10⁻⁸ m to 1.5×10⁻⁷ m, preferably 2×10⁻⁸ m to 1.0×10⁻⁷ m, and more preferably 3×10⁻⁸ m to 1.0×10⁻⁷ m.

It is preferable to use, as a semiconductor material included in the inorganic oxide semiconductor material layer, a material having a large band gap value (e.g., a band gap value of 3.0 eV or more) and having higher mobility than that of a material included in the photoelectric conversion layer. Specific examples of the material include an oxide semiconductor material such as IGZO; transition metal dichalcogenide; silicon carbide; diamond; graphene; carbon nanotubes; a semiconductor material such as Si, Ge, and GaAs; and an organic semiconductor material such as a condensed polycyclic hydrocarbon compound and a condensed heterocyclic compound. The impurity concentration in the semiconductor material included in the inorganic oxide semiconductor material layer is preferably 1×10¹⁸ cm⁻³ or less. The inorganic oxide semiconductor material layer may have a single-layer configuration or a multilayer configuration.

It is possible to form the inorganic oxide semiconductor material layer on the basis of, for example, a physical vapor deposition method (PVD method), specifically, a sputtering method. More specifically, examples of the sputtering method include one using a parallel flat plate sputtering device, a DC magnetron sputtering device or an RF sputtering device as a sputtering device, an argon (Ar) gas as a process gas, and a desired sintered body as a target. However, it is also possible to form the inorganic oxide semiconductor material layer on the basis of a coating method or the like, not being limited only to the PVD method such as the sputtering method or a vapor deposition method.

In the stacked imaging element or the like, the second electrode positioned on light incident side may be shared by a plurality of stacked imaging elements or the like. That is, the second electrode may be a so-called solid electrode except for stacked imaging elements or the like including an upper electric charge movement control electrode of the present disclosure to be described later. The photoelectric conversion layer may be shared by a plurality of stacked imaging elements or the like, i.e., one photoelectric conversion layer may be formed for a plurality of stacked imaging elements or the like, or may be provided for each stacked imaging element.

In the imaging element including the electric charge accumulation electrode of the present disclosure, a mode may be adopted in which the photoelectric conversion layer extends in an opening provided in the insulating layer and is coupled to the first electrode.

In the imaging element including the electric charge accumulation electrode of the present disclosure including various preferred modes described above, a configuration may be adopted in which:
the imaging element further includes a control section provided in the semiconductor substrate and including a drive circuit,
the first electrode and the electric charge accumulation electrode are coupled to the drive circuit,
during an electric charge accumulation period, from the drive circuit, a potential V₁₁ is applied to the first electrode, a potential V₃₁ is applied to the electric charge accumulation electrode, and electric charge is accumulated in the photoelectric conversion layer, and
during an electric charge transfer period, from the drive circuit, a potential V₁₂ is applied to the first electrode, a potential V₃₂ is applied to the electric charge accumulation electrode, and the electric charge accumulated in the photoelectric conversion layer is read out to the control section via the first electrode. Note that the potential of the first electrode is higher than the potential of the second electrode, and V₃₁≥V₁₁ and V₃₂<V₁₂ hold true.

Furthermore, in the imaging element including the electric charge accumulation electrode of the present disclosure including various preferred modes described above, a mode may be adopted in which the electric charge movement control electrode is formed in a region opposed to, with the insulating layer interposed therebetween, a region of the photoelectric conversion layer positioned between adjacent imaging elements. It is to be noted that such a mode may be referred to as an “imaging element including a lower electric charge movement control electrode of the present disclosure” for the sake of convenience in some cases. Alternatively, a mode may be adopted in which the electric charge movement control electrode is formed, instead of the second electrode, on the region of the photoelectric conversion layer positioned between adjacent imaging elements. It is to be noted that such a mode may be referred to as an “imaging element including an upper electric charge movement control electrode of the present disclosure” for the sake of convenience in some cases.

In the following description, the “region of the photoelectric conversion layer positioned between adjacent imaging elements” is referred to as a “region-A of the photoelectric conversion layer” for the sake of convenience, and a “region of the insulating layer positioned between adjacent imaging elements” is referred to as a “region-A of the insulating layer” for the sake of convenience. The region-A of the photoelectric conversion layer corresponds to the region-A of the insulating layer. Further, a “region between adjacent imaging elements” is referred to as a “region-a” for the sake of convenience.

In the imaging element including the lower electric charge movement control electrode (lower side/electric charge movement control electrode, an electric charge movement control electrode positioned on side opposite to the light incident side with respect to the photoelectric conversion layer) of the present disclosure, the lower electric charge movement control electrode is formed in a region opposed to the region-A of the photoelectric conversion layer with the insulating layer interposed therebetween. In other words, the lower electric charge movement control electrode is formed below a portion of the insulating layer (region-A of the insulating layer) in a region (region-a) sandwiched between an electric charge accumulation electrode and an electric charge accumulation electrode that are included in respective adjacent imaging elements. The lower electric charge movement control electrode is provided at a distance from the electric charge accumulation electrode. Or in other words, the lower electric charge movement control electrode surrounds the electric charge accumulation electrode and is provided at a distance from the electric charge accumulation electrode. The lower electric charge movement control electrode is disposed to be opposed to the region-A of the photoelectric conversion layer with the insulating layer interposed therebetween.

Then, a mode may be adopted in which:
the imaging element including the lower electric charge movement control electrode of the present disclosure further includes a control section provided in the semiconductor substrate and including a drive circuit,
the first electrode, the second electrode, the electric charge accumulation electrode, and the lower electric charge movement control electrode are coupled to the drive circuit,
during an electric charge accumulation period, from the drive circuit, a potential V₁₁ is applied to the first electrode, a potential V₃₁ is applied to the electric charge accumulation electrode, a potential V₄₁ is applied to the lower electric charge movement control electrode, and electric charge is accumulated in the photoelectric conversion layer, and
during an electric charge transfer period, from the drive circuit, a potential V₁₂ is applied to the first electrode, a potential V₃₂ is applied to the electric charge accumulation electrode, a potential V₄₂ is applied to the lower electric charge movement control electrode, and the electric charge accumulated in the photoelectric conversion layer is read out to the control section via the first electrode. Note that:
V₃₁≥V₁₁, V₃₁>V₄₁ and V₁₂>V₃₂>V₄₂
hold true. The lower electric charge movement control electrode may be formed at a level the same as or different from that of the first electrode or the electric charge accumulation electrode.

In the imaging element including the upper electric charge movement control electrode (upper side/electric charge movement control electrode, an electric charge movement control electrode positioned on the light incident side with respect to the photoelectric conversion layer) of the present disclosure, the upper electric charge movement control electrode is formed on the region of the photoelectric conversion layer positioned between adjacent imaging elements, instead of the second electrode. The upper electric charge movement control electrode is provided at a distance from the second electrode. In other words:
[A] a mode may be adopted in which: the second electrode is provided for each imaging element; and the upper electric charge movement control electrode surrounds at least a portion of the second electrode and is provided, at a distance from the second electrode, on the region-A of the photoelectric conversion layer. Alternatively,
[B] a mode may be adopted in which: the second electrode is provided for each imaging element; the upper electric charge movement control electrode surrounds at least a portion of the second electrode and is provided at a distance from the second electrode; and a portion of the electric charge accumulation electrode is present below the upper electric charge movement control electrode. Alternatively,
[C] a mode may be adopted in which: the second electrode is provided for each imaging element; the upper electric charge movement control electrode surrounds at least a portion of the second electrode and is provided at a distance from the second electrode; a portion of the electric charge accumulation electrode is present below the upper electric charge movement control electrode; and furthermore, the lower electric charge movement control electrode is formed below the upper electric charge movement control electrode. In some cases, a potential generated by coupling between the upper electric charge movement control electrode and the second electrode may be applied to a region of the photoelectric conversion layer positioned below a region between the upper electric charge movement control electrode and the second electrode.

In addition, a mode may be adopted in which:
the imaging element including the upper electric charge movement control electrode of the present disclosure further includes a control section provided in the semiconductor substrate and including a drive circuit,
the first electrode, the second electrode, the electric charge accumulation electrode, and the upper electric charge movement control electrode are coupled to the drive circuit,
during an electric charge accumulation period, from the drive circuit, a potential V₂₁ is applied to the second electrode, a potential V₄₁ is applied to the upper electric charge movement control electrode, and electric charge is accumulated in the photoelectric conversion layer, and
during an electric charge transfer period, from the drive circuit, a potential V₂₂ is applied to the second electrode, a potential V₄₂ is applied to the upper electric charge movement control electrode, and the electric charge accumulated in the photoelectric conversion layer is read out to the control section via the first electrode. Note that: V₂₁≥V₄₁ and V₂₂≥V₄₂
hold true. The upper electric charge movement control electrode is formed at a level the same as that of the second electrode.

Furthermore, in the imaging element including the electric charge accumulation electrode of the present disclosure including various preferred modes described above, a mode may be adopted in which the imaging element further includes, between the first electrode and the electric charge accumulation electrode, a transfer control electrode (electric charge transfer electrode) disposed at a distance from the first electrode and the electric charge accumulation electrode and disposed to be opposed to the photoelectric conversion layer with the insulating layer interposed therebetween. The imaging element including the electric charge accumulation electrode of the present disclosure in such a mode is referred to as an “imaging element including the transfer control electrode of the present disclosure” for the sake of convenience.

Then, in the imaging element including the transfer control electrode of the present disclosure, a mode may be adopted in which:
the imaging element further includes a control section provided in the semiconductor substrate and including a drive circuit,
the first electrode, the electric charge accumulation electrode, and the transfer control electrode are coupled to the drive circuit,
during an electric charge accumulation period, from the drive circuit, a potential V₁₁ is applied to the first electrode, a potential V₃₁ is applied to the electric charge accumulation electrode, a potential V₅₁ is applied to the transfer control electrode, and electric charge is accumulated in the photoelectric conversion layer, and
during an electric charge transfer period, from the drive circuit, a potential V₁₂ is applied to the first electrode, a potential V₃₂ is applied to the electric charge accumulation electrode, a potential V₅₂ is applied to the transfer control electrode, and the electric charge accumulated in the photoelectric conversion layer is read out to the control section via the first electrode. Note that the potential of the first electrode is higher than the potential of the second electrode, and
V₃₁>V₅₁ and V₃₂≤V₅₂≤V₁₂
hold true.

Further, in the imaging element including the transfer control electrode of the present disclosure including the various preferred modes described above, a mode may be adopted in which the imaging element further includes an electric charge drain electrode coupled to the photoelectric conversion layer and disposed at a distance from the first electrode and the electric charge accumulation electrode. The imaging element including the transfer control electrode of the present disclosure in such a mode is referred to as an “imaging element including the electric charge drain electrode of the present disclosure” for the sake of convenience. Then, in the imaging element including the electric charge drain electrode of the present disclosure, a mode may be adopted in which the electric charge drain electrode is disposed to surround the first electrode and the electric charge accumulation electrode (i.e., in a picture frame form). The electric charge drain electrode may be shared by (common to) a plurality of imaging elements.

Further, in the imaging element including the electric charge drain electrode of the present disclosure, a mode may be adopted in which:
the imaging element further includes a control section provided in the semiconductor substrate and including a drive circuit,
the first electrode, the electric charge accumulation electrode, and the electric charge drain electrode are coupled to the drive circuit,
during an electric charge accumulation period, from the drive circuit, a potential V₁₁ is applied to the first electrode, a potential V₃₁ is applied to the electric charge accumulation electrode, a potential V₆₁ is applied to the electric charge drain electrode, and electric charge is accumulated in the photoelectric conversion layer, and
during an electric charge transfer period, from the drive circuit, a potential V₁₂ is applied to the first electrode, a potential V₃₂ is applied to the electric charge accumulation electrode, a potential V₆₂ is applied to the electric charge drain electrode, and the electric charge accumulated in the photoelectric conversion layer is read out to the control section via the first electrode. Note that the potential of the first electrode is higher than the potential of the second electrode, and
V₆₁>V₁₁ and V₆₂<V₁₂
hold true.

Further, in the above-described various preferred modes of the imaging element including the transfer control electrode of the present disclosure, a mode may be adopted in which the electric charge accumulation electrode includes a plurality of electric charge accumulation electrode segments. The imaging element including the transfer control electrode of the present disclosure in such a mode is referred to as an “imaging element including a plurality of electric charge accumulation electrode segments of the present disclosure” for the sake of convenience. It is sufficient that the number of the electric charge accumulation electrode segments is two or more. In the imaging element including a plurality of electric charge accumulation electrode segments of the present disclosure, in a case where different potentials are applied to N electric charge accumulation electrode segments, a mode may be adopted in which:
in a case where the potential of the first electrode is higher than the potential of the second electrode, during the electric charge transfer period, the potential to be applied to an electric charge accumulation electrode segment (a first electric charge accumulation electrode segment) positioned closest to the first electrode is higher than the potential to be applied to an electric charge accumulation electrode segment (an N-th electric charge accumulation electrode segment) positioned farthest from the first electrode, and in a case where the potential of the first electrode is lower than the potential of the second electrode, during the electric charge transfer period, the potential to be applied to the electric charge accumulation electrode segment (the first electric charge accumulation electrode segment) positioned closest to the first electrode is lower than the potential to be applied to the electric charge accumulation electrode segment (the N-th electric charge accumulation electrode segment) positioned farthest from the first electrode.

In the imaging element including the electric charge accumulation electrode of the present disclosure including various preferred modes described above, a configuration may be adopted in which:
at least a floating diffusion layer and an amplification transistor included in the control section are provided in the semiconductor substrate, and
the first electrode is coupled to the floating diffusion layer and a gate section of the amplification transistor. Then, in this case, furthermore, a configuration may be adopted in which:
a reset transistor and a selection transistor included in the control section are further provided in the semiconductor substrate,
the floating diffusion layer is coupled to one of source/drain regions of the reset transistor, and
one of source/drain regions of the amplification transistor is coupled to one of source/drain regions of the selection transistor, and another one of the source/drain regions of the selection transistor is coupled to a signal line.

Furthermore, in the imaging element including the electric charge accumulation electrode of the present disclosure including various preferred modes described above, a mode may be adopted in which the electric charge accumulation electrode is larger in size than the first electrode. Although not limited,

4≤s₁′/s₁
is preferably satisfied, where s₁′ denotes the area of the electric charge accumulation electrode, and s₁ denotes the area of the first electrode.

As a modification example of the imaging devices according to the first and second aspects of the present disclosure, an imaging device may have a configuration in which
the imaging device includes a plurality of the stacked imaging elements or the like,
the plurality of stacked imaging elements constitutes an imaging element block, and
the first electrode is shared by the plurality of stacked imaging elements or the like constituting the imaging element block. The imaging device having such a configuration is referred to as a “first electrode sharing imaging device” for the sake of convenience. By allowing the first electrode to be shared by the plurality of stacked imaging elements or the like constituting the imaging element block as described above, it is possible to simplify and miniaturize the configuration and structure of a pixel region in which a plurality of stacked imaging elements or the like is arranged.

In the first electrode sharing imaging device, one floating diffusion layer is provided for a plurality of stacked imaging elements or the like (one imaging element block). Then, appropriately controlling the timing of the electric charge transfer period allows for sharing of one floating diffusion layer among the plurality of stacked imaging elements or the like. The plurality of stacked imaging elements or the like is caused to operate together and is coupled as an imaging element block to a drive circuit. That is, the plurality of stacked imaging elements or the like constituting the imaging element block is coupled to one drive circuit. However, control of the electric charge accumulation electrode is performed for each imaging element. In addition, it is possible for the plurality of stacked imaging elements or the like to share one contact hole section. The arrangement relationship between the first electrode shared by the plurality of stacked imaging elements or the like and the electric charge accumulation electrode of each stacked imaging element or the like may be such that, in some cases, the first electrode is disposed to be adjacent to the electric charge accumulation electrode of each imaging element. Alternatively, the first electrode may be disposed to be adjacent to the electric charge accumulation electrodes of some of the plurality of stacked imaging elements or the like and not disposed to be adjacent to the electric charge accumulation electrodes of the rest of the plurality of stacked imaging elements. In this case, the movement of electric charge from the rest of the plurality of imaging elements to the first electrode is movement via some of the plurality of imaging elements. In order to ensure movement of electric charge from each imaging element to the first electrode, it is preferred that a distance between an electric charge accumulation electrode included in an imaging element and an electric charge accumulation electrode included in an imaging element (referred to as a “distance A” for the sake of convenience) be longer than a distance between the first electrode and the electric charge accumulation electrode in an imaging element adjacent to the first electrode (referred to as a “distance B” for the sake of convenience). In addition, it is preferred that the value of the distance A be larger in the imaging element positioned farther away from the first electrode.

Furthermore, in the imaging element including the electric charge accumulation electrode of the present disclosure including various preferred modes described above, a mode may be adopted in which light enters from side of the second electrode, and a light-blocking layer is formed on the light incident side closer to the second electrode. Alternatively, a mode may be adopted in which light enters from the side of the second electrode, and no light enters the first electrode (depending on the case, light enters neither of the first electrode and the transfer control electrode). Then, in this case, a configuration may be adopted in which the light-blocking layer is formed on the light incident side closer to the second electrode and above the first electrode (depending on the case, the first electrode and the transfer control electrode). Alternatively, a configuration may be adopted in which an on-chip microlens is provided above the electric charge accumulation electrode and the second electrode, and the light entering the on-chip microlens is condensed onto the electric charge accumulation electrode. Here, the light-blocking layer may be disposed above a surface of the second electrode on the light incident side, or may be disposed on the surface of the second electrode on the light incident side. The light-blocking layer may be formed in the second electrode depending on the case. Examples of a material included in the light-blocking layer include chromium (Cr), copper (Cu), aluminum (Al), tungsten (W), and non-light-transmitting resins (e.g., polyimide resin).

Specific examples of the imaging element including the electric charge accumulation electrode of the present disclosure include: an imaging element (referred to as a “blue light imaging element of a first type” for the sake of convenience) that has sensitivity to blue light and includes a photoelectric conversion layer or a photoelectric conversion section (referred to as a “blue light photoelectric conversion layer of a first type” or a “blue light photoelectric conversion section of a first type” for the sake of convenience) that absorbs blue light (light of 425 nm to 495 nm); an imaging element (referred to as a “green light imaging element of a first type” for the sake of convenience) that has sensitivity to green light and includes a photoelectric conversion layer or a photoelectric conversion section (referred to as a “green light photoelectric conversion layer of a first type” or a “green light photoelectric conversion section of a first type” for the sake of convenience) that absorbs green light (light of 495 nm to 570 nm); and an imaging element (referred to as a “red light imaging element of a first type” for the sake convenience) that has sensitivity to red light and includes a photoelectric conversion layer or a photoelectric conversion section (referred to as a “red light photoelectric conversion layer of a first type” or a “red light photoelectric conversion section of a first type” for the sake of convenience) that absorbs red light (light of 620 nm to 750 nm). In addition, an imaging element that does not include the electric charge accumulation electrode and that has sensitivity to blue light is referred to as a “blue light imaging element of a second type” for the sake convenience. An imaging element that does not include the electric charge accumulation electrode and that has sensitivity to green light is referred to as a “green light imaging element of a second type” for the sake of convenience. An imaging element that does not include the electric charge accumulation electrode and that has sensitivity to red light is referred to as a “red light imaging element of a second type” for the sake of convenience. A photoelectric conversion layer or a photoelectric conversion section included in the blue light imaging element of the second type is referred to as a “blue light photoelectric conversion layer of a second type” or a “blue light photoelectric conversion section of a second type” for the sake of convenience. A photoelectric conversion layer or a photoelectric conversion section included in the green light imaging element of the second type is referred to as a “green light photoelectric conversion layer of a second type” or a “green light photoelectric conversion section of a second type” for the sake of convenience. A photoelectric conversion layer or a photoelectric conversion section included in the red light imaging element of the second type is referred to as a “red light photoelectric conversion layer of a second type” or a “red light photoelectric conversion section of a second type” for the sake of convenience.

In the stacked imaging element of the present disclosure, a mode may adopted in which the stacked imaging element includes at least one imaging element (photoelectric conversion element) including the electric charge accumulation electrode of the present disclosure, and specific examples of the configuration and structure of the stacked imaging element include:
[A] a configuration and a structure in which the blue light photoelectric conversion section of the first type, the green light photoelectric conversion section of the first type, and the red light photoelectric conversion section of the first type are stacked in a vertical direction, and
   the control sections of the blue light imaging element of the first type, the green light imaging element of the first type, and the red light imaging element of the first type are each provided in the semiconductor substrate;
[B] a configuration and a structure in which the blue light photoelectric conversion section of the first type and the green light photoelectric conversion section of the first type are stacked in the vertical direction,
   the red light photoelectric conversion section of the second type is disposed below these two layers of photoelectric conversion sections of the first type, and
   the control sections of the blue light imaging element of the first type, the green light imaging element of the first type, and the red light imaging element of the second type are each provided in the semiconductor substrate;
[C] a configuration and a structure in which the blue light photoelectric conversion section of the second type and the red light photoelectric conversion section of the second type are disposed below the green light photoelectric conversion section of the first type, and
   the control sections of the green light imaging element of the first type, the blue light imaging element of the second type, and the red light imaging element of the second type are each provided in the semiconductor substrate; and
[D] a configuration and a structure in which the green light photoelectric conversion section of the second type and the red light photoelectric conversion section of the second type are disposed below the blue light photoelectric conversion section of the first type, and
   the control sections of the blue light imaging element of the first type, the green light imaging element of the second type, and the red light imaging element of the second type are each provided in the semiconductor substrate. It is preferred that the arrangement order of the photoelectric conversion sections of these imaging elements in the vertical direction be the order of the blue light photoelectric conversion section, the green light photoelectric conversion section, and the red light photoelectric conversion section from a light incident direction, or the order of the green light photoelectric conversion section, the blue light photoelectric conversion section, and the red light photoelectric conversion section from the light incident direction. One reason for this is that the light of a shorter wavelength is efficiently absorbed on incident surface side. Red has the longest wavelength among the three colors, and it is therefore preferred that the red light photoelectric conversion section be positioned in the lowest layer as viewed from light incident surface. One pixel is configured by the stacked structure of these imaging elements. In addition, a near-infrared photoelectric conversion section (alternatively, an infrared photoelectric conversion section) of a first type may be provided. Here, it is preferred that the photoelectric conversion layer of the infrared photoelectric conversion section of the first type include, for example, an organic material and be disposed in the lowest layer of the stacked structure of the imaging elements of the first type and above the imaging elements of the second type. Alternatively, a near-infrared photoelectric conversion section (alternatively, an infrared photoelectric conversion section) of a second type may be provided below the photoelectric conversion sections of the first type.

In the imaging elements of the first type, the first electrode is formed on, for example, an interlayer insulating layer provided on the semiconductor substrate. The imaging element formed on the semiconductor substrate may be of a back illuminated type or a front illuminated type.

The imaging devices according to the first and second aspects of the present disclosure are able to configure single-plate color imaging devices.

In the imaging device (stacked imaging device) according to the second aspect of the present disclosure including the stacked imaging element, the imaging elements having sensitivity to light of a plurality of types of wavelengths are stacked in the direction in which light enters within the same pixel to constitute one pixel, unlike in an imaging device including imaging elements in Bayer arrangement (i.e., not using a color filter layer for performing blue, green, or red spectral separation). It is therefore possible to achieve improvement of sensitivity and improvement of pixel density per unit volume.

Meanwhile, in the imaging device according to the first aspect of the present disclosure, employing the color filter layer makes it possible to ease requirements on the spectral characteristics of blue, green, and red, and provides high mass productivity. Examples of arrangement of the imaging elements in the imaging device according to the first aspect of the present disclosure include an interline arrangement, a G stripe RB checkered arrangement, a G stripe RB full checkered arrangement, a checkered complementary color arrangement, a stripe arrangement, a diagonal stripe arrangement, a primary color difference arrangement, a field color difference sequential arrangement, a frame color difference sequential arrangement, a MOS arrangement, an improved MOS arrangement, a frame interleave arrangement, and a field interleave arrangement, as well as the Bayer arrangement. Here, one imaging element constitutes one pixel (or subpixel).

Examples of the color filter layers (wavelength selection means) include filter layers that transmit not only red, green, and blue, but also specific wavelengths, such as cyan, magenta, and yellow, depending on the case. It is possible for the color filter layer to be configured not only by an organic material-based color filter layer using an organic compound such as a pigment or a dye, but also by a thin film including an inorganic material such as a photonic crystal, a wavelength selection element based on application of plasmon (color filter layer having a conductor lattice structure with a lattice-like hole structure in a conductive thin film; see, for example, Japanese Unexamined Patent Application Publication No. 2008-177191), or amorphous silicon.

The pixel region in which a plurality of stacked imaging elements or the like is arranged includes a plurality of pixels systematically arranged in a two-dimensional array. The pixel region typically includes: an effective pixel region in which light is actually received to generate signal electric charge through photoelectric conversion, and the signal electric charge is amplified and read out to the drive circuit; and a black reference pixel region (also called an optical black pixel region (OPB)) for outputting optical black serving as a black level reference. The black reference pixel region is typically disposed on the outer periphery of the effective pixel region.

A configuration may be adopted in which the first electrode, the electric charge accumulation electrode, the transfer control electrode, the electric charge movement control electrode, the electric charge drain electrode, and the second electrode include transparent electrically-conductive materials. The first electrode, the electric charge accumulation electrode, the transfer control electrode, and the electric charge drain electrode are collectively referred to as a “first electrode or the like” in some cases. The material included in the first electrode or the like is as described above.

Examples of the material included in the insulating layer include not only inorganic insulating materials exemplified by metal oxide high dielectric insulating materials including: silicon oxide materials; silicon nitride (SiN_{Y}); and aluminum oxide (Al₂O₃), but also organic insulating materials (organic polymers) exemplified by polymethyl methacrylate (PMMA); polyvinyl phenol (PVP); polyvinyl alcohol (PVA); polyimide; polycarbonate (PC); polyethylene terephthalate (PET); polystyrene; silanol derivatives (silane coupling agents) including N-2 (aminoethyl) 3-aminopropyltrimethoxysilane (AEAPTMS), 3-mercaptopropyltrimethoxysilane (MPTMS), octadecyltrichlorosilane (OTS), and the like; novolac-type phenolic resins; fluoro resins; straight-chain hydrocarbons having a functional group being able to bond to the control electrode at one end, including octadecanethiol, dodecyl isocyanate, and the like, and combinations thereof. Examples of the silicon oxide-based materials include silicon oxide (SiOₓ), BPSG, PSG, BSG, AsSG, PbSG, silicon oxynitride (SiON), SOG (spin-on-glass), and low dielectric constant insulating materials (e.g., polyaryl ether, cycloperfluorocarbon polymers and benzocyclobutene, cyclic fluoro resins, polytetrafluoroethylene, fluorinated aryl ether, fluorinated polyimide, amorphous carbon, and organic SOG). The insulating layer may have a single-layer configuration, or a configuration including a plurality of layers (e.g., two layers) stacked. In the latter case, an insulating layer/lower layer may be formed at least over the electric charge accumulation electrode and in a region between the electric charge accumulation electrode and the first electrode. A planarization process may be performed on the insulating layer/lower layer to allow the insulating layer/lower layer to remain at least in the region between the electric charge accumulation electrode and the first electrode. It is sufficient that an insulating layer/upper layer is formed over the remaining insulating layer/lower layer and the electric charge accumulation electrode. In this way, it is possible to planarize the insulating layer with reliability. It is sufficient that materials forming the protection material layer, various interlayer insulating layers, and insulating material films are appropriately selected from these materials.

The configurations and structures of the floating diffusion layer, the amplification transistor, the reset transistor, and the selection transistor included in the control section may be similar to the configurations and structures of existing floating diffusion layers, amplification transistors, reset transistors, and selection transistors. The drive circuit may also have a well-known configuration and structure.

While the first electrode is coupled to the floating diffusion layer and a gate section of the amplification transistor, it is sufficient that a contact hole section is formed for the coupling of the first electrode to the floating diffusion layer and the gate section of the amplification transistor. Examples of a material for forming the contact hole section include polysilicon doped with impurities, a high melting point metal such as tungsten, Ti, Pt, Pd, Cu, TiW, TiN, TiNW, WSi₂, or MoSi₂, a metal silicide, and a stacked structure of layers including these materials (e.g., Ti/TiN/W).

For example, in a case of stacking the imaging device and a readout integrated circuit (ROIC), the stacking may be performed by laying a driving substrate having the readout integrated circuit and a connection section including copper (Cu) formed thereon and a stacked imaging element or the like having a connection section formed thereon over each other such that their respective connection sections come into contact with each other, and joining the connection sections. The connection sections may be joined to each other using a solder bump or the like.

Further, a driving method for driving the imaging devices according to the first and second aspects of the present disclosure may be a driving method of the imaging device repeating the steps of:
draining electric charge in the first electrodes out of the system all at once while accumulating electric charge in the photoelectric conversion layers in all of the stacked imaging elements or the like; and thereafter,
transferring the electric charge accumulated in the photoelectric conversion layers all at once to the first electrodes in all of the stacked imaging elements or the like, and after completion of the transferring, sequentially reading out the electric charge transferred to the first electrodes in the respective stacked imaging elements or the like.

In such a driving method of the imaging device, each stacked imaging element or the like has a structure in which light having entered from side of the second electrode does not enter the first electrode and, in all of the stacked imaging elements, electric charge in the first electrodes is drained out of the systems all at once while accumulating electric charge in the photoelectric conversion layers. This makes it possible to perform resetting of the first electrodes with reliability in all of the stacked imaging elements or the like simultaneously. Thereafter, in all of the stacked imaging elements or the like, the electric charge accumulated in the photoelectric conversion layer is transferred all at once to the first electrodes, and after completion of the transferring, the electric charge transferred to the first electrodes is sequentially read out in the respective stacked imaging elements or the like. It is therefore possible to achieve a so-called global shutter function easily.

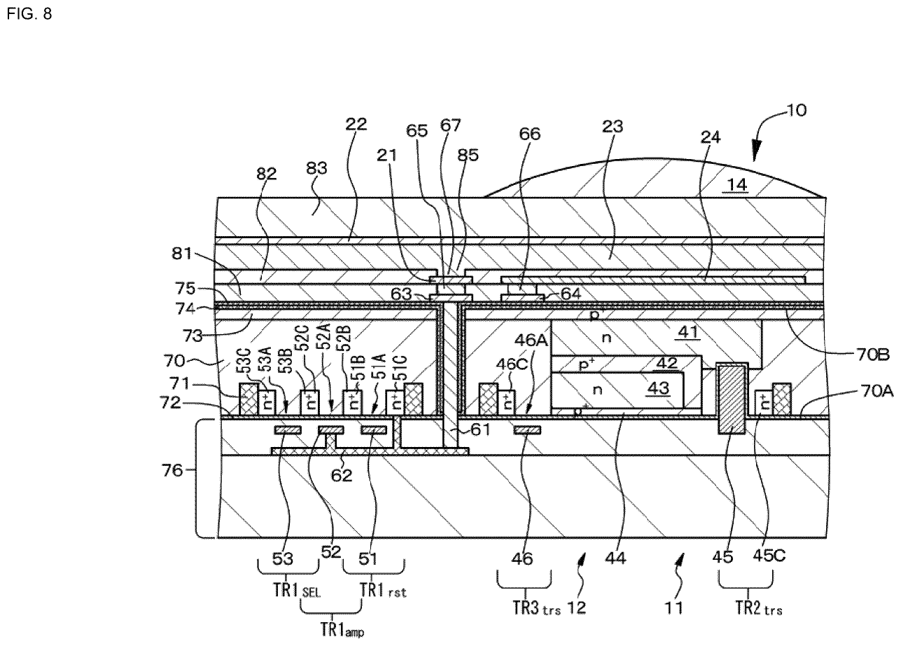

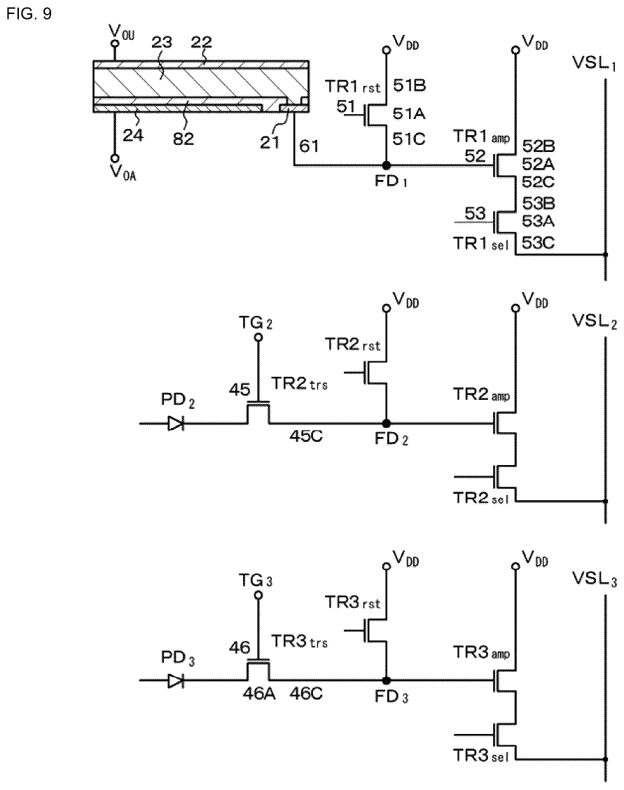

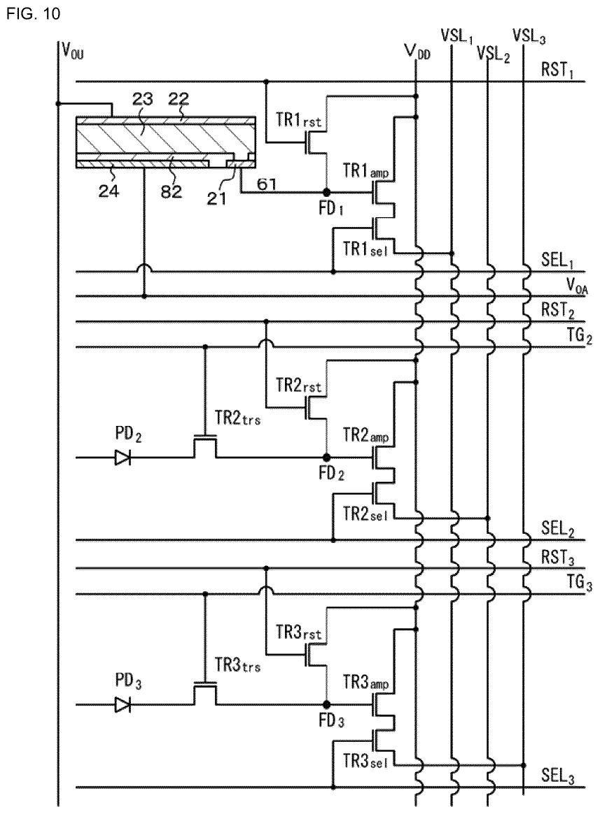

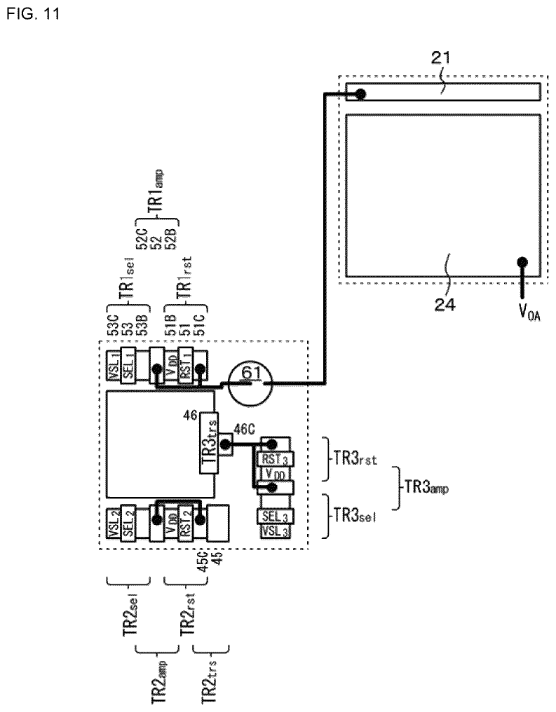

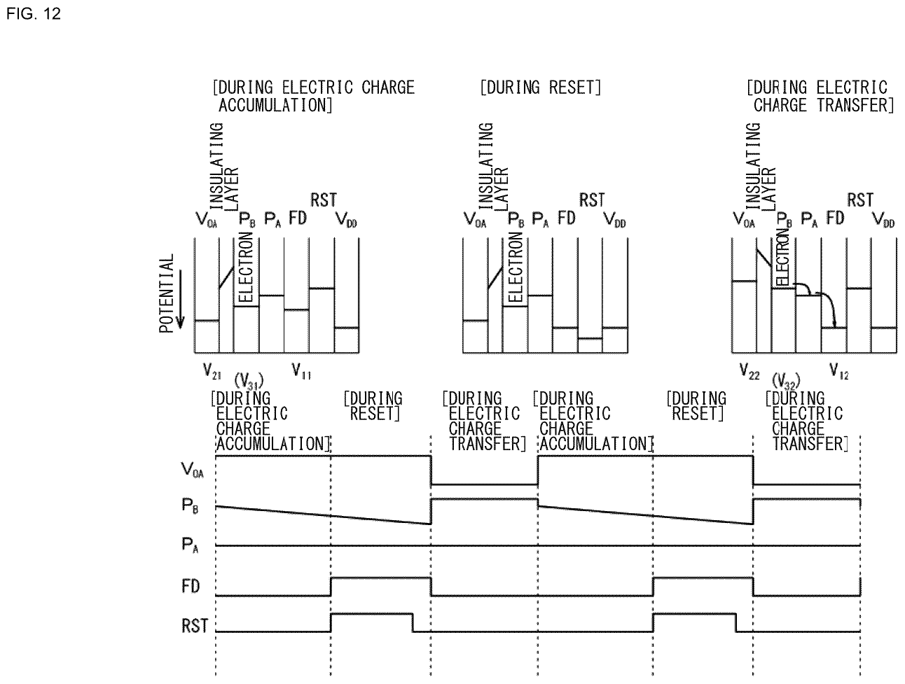

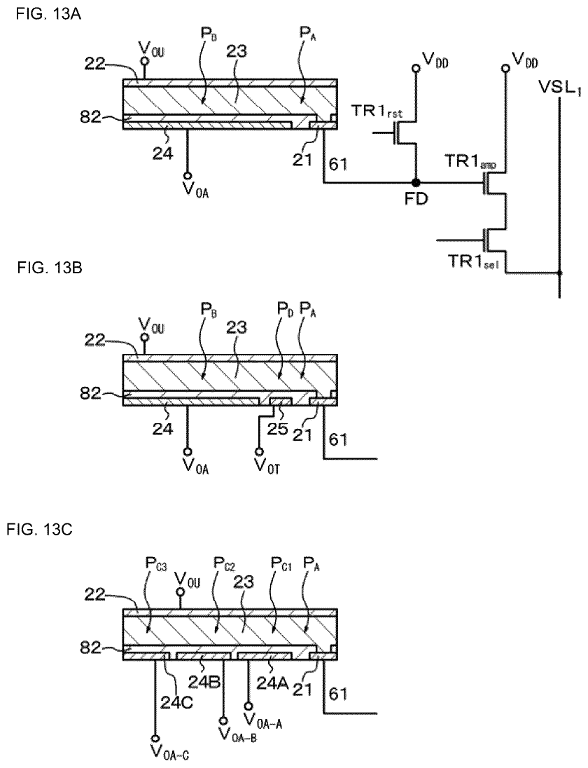

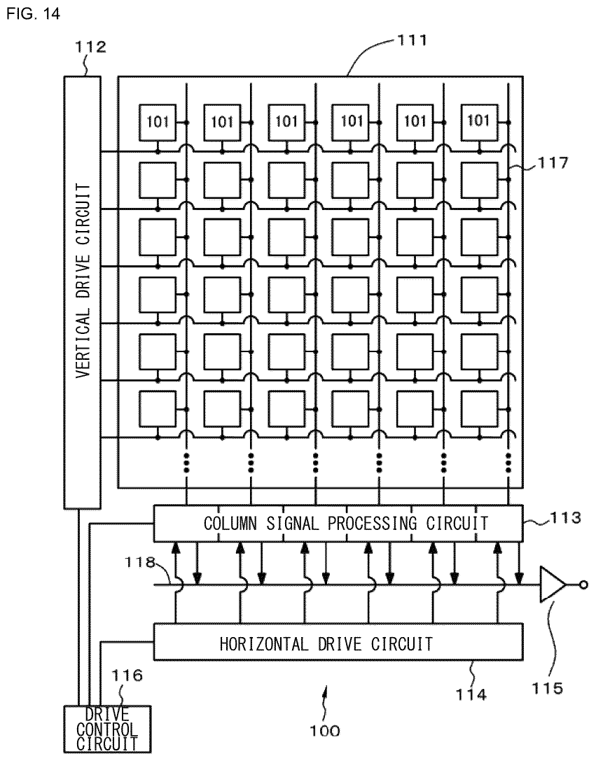

A detailed description is given below of the imaging element of Example 3, specifically, the stacked imaging element and the imaging device (stacked imaging device) according to the second aspect of the present disclosure. FIG. 8 illustrates a schematic partial cross-sectional view of the imaging element and the imaging device of Example 3. FIG. 9 and FIG. 10 illustrate equivalent circuit diagrams of the imaging element of Example 3. FIG. 11 illustrates a schematic layout diagram of the first electrode and the electric charge accumulation electrode included in the photoelectric conversion section, and transistors included in the control section that are included in the imaging element of Example 3. FIG. 12 schematically illustrating a state of potential at each part during operation of the imaging element of Example 3. FIG. 13A is an equivalent circuit diagram for describing each part of the imaging element of Example 1. Furthermore, FIG. 14 illustrates a conceptual diagram of the imaging device of Example 3.

The imaging element 10 of Example 3 further includes a semiconductor substrate (more specifically, a silicon semiconductor layer) 70, and the photoelectric conversion section is disposed above the semiconductor substrate 70. In addition, the imaging element 10 further includes the control section provided in the semiconductor substrate 70 and including the drive circuit to which the first electrode 21 and the second electrode 22 are coupled. Here, a light incident surface of the semiconductor substrate 70 is defined as above, and opposite side of the semiconductor substrate 70 is defined as below. A wiring layer 62 including a plurality of wiring lines is provided below the semiconductor substrate 70.

At least a floating diffusion layer FD₁ and an amplification transistor TR1ₐₘₚ included in the control section are provided in the semiconductor substrate 70, and the first electrode 21 is coupled to the floating diffusion layer FD₁ and a gate section of the amplification transistor TR1ₐₘₚ. A reset transistor TR1ᵣₛₜ and a selection transistor TR1ₛₑₗ included in the control section are further provided in the semiconductor substrate 70. The floating diffusion layer FD₁ is coupled to one of source/drain regions of the reset transistor TR1ₛᵣₜ. Another one of source/drain regions of the amplification transistor TR1ₐₘₚ is coupled to one of source/drain regions of the selection transistor TR1ₛₑₗ. Another one of the source/drain regions of the selection transistor TR1ₛₑₗ is coupled to a signal line VSL₁. The amplification transistor TR1ₐₘₚ, the reset transistor TR1ᵣₛₜ, and the selection transistor TR1ₛₑₗ constitute the drive circuit.

Specifically, the imaging element and the stacked imaging element of Example 3 are an imaging element and a stacked imaging element of the back illuminated type, and have a structure in which three imaging elements are stacked, the three imaging elements being: a green light imaging element of Example 3 of a first type (hereinafter referred to as a “first imaging element”) having sensitivity to green light and including the green light photoelectric conversion layer of the first type for absorbing green light; an existing blue light imaging element of the second type (hereinafter referred to as a “second imaging element”) having sensitivity to blue light and including the blue light photoelectric conversion layer of the second type for absorbing blue light; and an existing red light imaging element of the second type (hereinafter referred to as a “third imaging element”) having sensitivity to red light and including the red light photoelectric conversion layer of the second type for absorbing red light. Here, the red light imaging element (third imaging element) 12 and the blue light imaging element (second imaging element) 11 are provided in the semiconductor substrate 70, and the second imaging element 11 is positioned closer to the light incident side than the third imaging element 12. In addition, the green light imaging element (first imaging element 10) is provided above the blue light imaging element (second imaging element 11). The stacked structure of the first imaging element 10, the second imaging element 11, and the third imaging element 12 constitutes one pixel. No color filter layer is provided.

In the first imaging element 10, the first electrode 21 and an electric charge accumulation electrode 24 are formed at a distance from each other on an interlayer insulating layer 81. The interlayer insulating layer 81 and the electric charge accumulation electrode 24 are covered with an insulating layer 82. The photoelectric conversion layer 23 is formed on the insulating layer 82, and the second electrode 22 is formed on the photoelectric conversion layer 23. A protection material layer 83 is formed over the entire surface inclusive of the second electrode 22, and an on-chip microlens 14 is provided on the protection material layer 83. No color filter layer is provided. The first electrode 21, the electric charge accumulation electrode 24, and the second electrode 22 are configured by transparent electrodes including, for example, ITO (work function: about 4.4 eV). The photoelectric conversion layer 23 has the configuration and structure described in Example 1, and includes a layer including a known organic photoelectric conversion material (e.g., an organic material such as rhodamine-based dye, merocyanine-based dye, or quinacridone) having sensitivity to at least green light. The interlayer insulating layer 81, the insulating layer 82, and the protection material layer 83 include a known insulating material (e.g., SiO₂ or SiN). The photoelectric conversion layer 23 and the first electrode 21 are coupled to each other by a connection section 67 provided at the insulating layer 82. The photoelectric conversion layer 23 extends in the connection section 67. That is, the photoelectric conversion layer 23 extends in an opening 84 provided in the insulating layer 82, and is coupled to the first electrode 21.

The electric charge accumulation electrode 24 is coupled to the drive circuit. Specifically, the electric charge accumulation electrode 24 is coupled to a vertical drive circuit 112 included in the drive circuit, via a connection hole 66, a pad section 64, and a wiring line VOA provided in the interlayer insulating layer 81.

The electric charge accumulation electrode 24 is larger in size than the first electrode 21. Although not limited, it is preferred to satisfy:

4≤s₁′/s₁
where s₁′ denotes the area of the electric charge accumulation electrode 24, and s₁ denotes the area of the first electrode 21. For example, in Example 3,

s₁′/s₁=8
holds true, although not limited thereto.

Element separation regions 71 are formed on side of a first surface (front surface) 70A of the semiconductor substrate 70, and an oxide film 72 is formed over the first surface 70A of the semiconductor substrate 70. Further, on side of the first surface of the semiconductor substrate 70, the reset transistor TR1ᵣₛₜ, the amplification transistor TR1ₐₘₚ, and the selection transistor TR1ₛₑₗ included in the control section of the first imaging element 10 are provided, and further, the first floating diffusion layer FD₁ is provided.

The reset transistor TR1ᵣₛₜ includes a gate section 51, a channel formation region 51A, and source/drain regions 51B and 51C. The gate section 51 of the reset transistor TR1ₛᵣₜ is coupled to a reset line RST₁, the one source/drain region 51C of the reset transistor TR1ₛᵣₜ also serves as the first floating diffusion layer FD₁, and another source/drain region 51B is coupled to a power supply V_{DD}.

The first electrode 21 is coupled to the one source/drain region 51C (first floating diffusion layer FD₁) of the reset transistor TR1ᵣₛₜ, via a connection hole 65 and a pad section 63 provided in the interlayer insulating layer 81, and a contact hole section 61 formed in the semiconductor substrate 70 and an interlayer insulating layer 76, and the wiring layer 62 formed in the interlayer insulating layer 76.

The amplification transistor TR1ₐₘₚ includes a gate section 52, a channel formation region 52A, and source/drain regions 52B and 52C. The gate section 52 is coupled to the first electrode 21 and the one source/drain region 51C (first floating diffusion layer FD₁) of the reset transistor TR1ₛᵣₜ via the wiring layer 62. In addition, the one source/drain region 52B is coupled to the power supply V_{DD}.

The selection transistor TR1ₛₑₗ includes a gate section 53, a channel formation region 53A, and source/drain regions 53B and 53C. The gate section 53 is coupled to a selection line SEL₁. In addition, the one source/drain region 53B shares a region with another source/drain region 52C included in the amplification transistor TR1ₐₘₚ, and another source/drain region 53C is coupled to a signal line (data output line) VSL₁ (117).

The second imaging element 11 includes an n-type semiconductor region 41 provided in the semiconductor substrate 70, as a photoelectric conversion layer. A gate section 45 of a transfer transistor TR2tᵣs including a vertical transistor extends to the n-type semiconductor region 41, and is coupled to a transfer gate line TG₂. In addition, a second floating diffusion layer FD₂ is provided in a region 45C of the semiconductor substrate 70 in the vicinity of the gate section 45 of the transfer transistor TR2ₜᵣₛ. Electric charge accumulated in the n-type semiconductor region 41 is read out to the second floating diffusion layer FD₂ via a transfer channel formed along the gate section 45.

In the second imaging element 11, further, a reset transistor TR2ᵣₛₜ, an amplification transistor TR2ₐₘₚ, and a selection transistor TR2ₛₑₗ included in the control section of the second imaging element 11 are provided on the side of the first surface of the semiconductor substrate 70.

The reset transistor TR2ᵣₛₜ includes a gate section, a channel formation region, and source/drain regions. The gate section of the reset transistor TR2ᵣₛₜ is coupled to a reset line RST₂, one of the source/drain regions of the reset transistor TR2ᵣₛₜ is coupled to the power supply V_{DD}, and another one of the source/drain regions also serves as the second floating diffusion layer FD₂.

The amplification transistor TR2ₐₘₚ includes a gate section, a channel formation region, and source/drain regions. The gate section is coupled to another one (second floating diffusion layer FD₂) of the source/drain regions of the reset transistor TR2ᵣₛₜ. In addition, one of the source/drain regions is coupled to the power supply V_{DD}.

The selection transistor TR2ₛₑₗ includes a gate section, a channel formation region, and source/drain regions. The gate section is coupled to a selection line SEL₂. In addition, one of the source/drain regions shares a region with another one of the source/drain regions included in the amplification transistor TR2ₐₘₚ, and another one of the source/drain regions is coupled to a signal line (data output line) VSL₂.

The third imaging element 12 includes an n-type semiconductor region 43 provided in the semiconductor substrate 70, as a photoelectric conversion layer. A gate section 46 of a transfer transistor TR3ₜᵣₛ is coupled to a transfer gate line TG₃. In addition, a third floating diffusion layer FD₃ is provided in a region 46C of the semiconductor substrate 70 in the vicinity of the gate section 46 of the transfer transistor TR3ₜᵣₛ. Electric charge accumulated in the n-type semiconductor region 43 is read out to the third floating diffusion layer FD₃ via a transfer channel 46A formed along the gate section 46.

In the third imaging element 12, further, a reset transistor TR3ᵣₛₜ, an amplification transistor TR3ₐₘₚ, and a selection transistor TR3ₛₑₗ included in the control section of the third imaging element 12 are provided on the side of the first surface of the semiconductor substrate 70.

The reset transistor TR3ᵣₛₜ includes a gate section, a channel formation region, and source/drain regions. The gate section of the reset transistor TR3ᵣₛₜ is coupled to a reset line RST₃, one of the source/drain regions of the reset transistor TR3ᵣₛₜ is coupled to the power supply V_{DD}, and another one of the source/drain regions also serves as the third floating diffusion layer FD₃.

The amplification transistor TR3ₐₘₚ includes a gate section, a channel formation region, and source/drain regions. The gate section is coupled to the other one (third floating diffusion layer FD₃) of the source/drain regions of the reset transistor TR3ᵣₛₜ. In addition, one of the source/drain regions is coupled to the power supply V_{DD}.

The selection transistor TR3ₛₑₗ includes a gate section, a channel formation region, and source/drain regions. The gate section is coupled to a selection line SEL₃. In addition, one of the source/drain regions shares a region with another one of the source/drain regions included in the amplification transistor TR3ₐₘₚ, and another one of the source/drain regions is coupled to a signal line (data output line) VSL₃.

The reset lines RST₁, RST₂, and RST₃, the selection lines SEL₁, SEL₂, and SEL₃, and the transfer gate lines TG₂ and TG₃ are coupled to the vertical drive circuit 112 included in the drive circuit. The signal lines (data output lines) VSL₁, VSL₂, and VSL₃ are coupled to a column signal processing circuit 113 included in the drive circuit.

A p+ layer 44 is provided between the n-type semiconductor region 43 and the front surface 70A of the semiconductor substrate 70, and suppresses generation of a dark current. A p+ layer 42 is formed between the n-type semiconductor region 41 and the n-type semiconductor region 43, and further, a portion of a side surface of the n-type semiconductor region 43 is surrounded by the p+ layer 42. A p+ layer 73 is formed on side of a back surface 70B of the semiconductor substrate 70, and an HfO₂ film 74 and an insulating material film 75 are formed in a region extending from the p+ layer 73 to a part inside of the semiconductor substrate 70 where the contact hole section 61 is to be formed. While wiring lines are formed across a plurality of layers in the interlayer insulating layer 76, illustrations thereof are omitted.

The HfO₂ film 74 is a film having a negative fixed charge. By providing such a film, it is possible to suppress generation of a dark current. The HfO₂ film may be replaced with an aluminum oxide (Al₂O₃) film, a zirconium oxide (ZrO₂) film, a tantalum oxide (Ta₂O₅) film, a titanium oxide (TiO₂) film, a lanthanum oxide (La₂O₃) film, a praseodymium oxide (Pr₂O₃) film, a cerium oxide (CeO₂) film, a neodymium oxide (Nd₂O₃) film, a promethium oxide (Pm₂O₃) film, a samarium oxide (Sm₂O₃) film, an europium oxide (Eu₂O₃) film, a gadolinium oxide ((Gd₂O₃) film, a terbium oxide (Tb₂O₃) film, a dysprosium oxide (Dy₂O₃) film, a holmium oxide (Ho₂O₃) film, a thulium oxide (Tm₂O₃) film, a ytterbium oxide (Yb₂O₃) film, a lutetium oxide (Lu₂O₃) film, a yttrium oxide (Y₂O₃) film, a hafnium nitride film, an aluminum nitride film, a hafnium oxynitride film, or an aluminum oxynitride film. Examples of the film-forming method for these films include a CVD method, a PVD method, and an ALD method.

In the following, description is given of an operation of the stacked imaging element (first imaging element 10) including the electric charge accumulation electrode of Example 3 with reference to FIGS. 12 and 13A. The imaging element of Example 3 further includes a control section provided in the semiconductor substrate 70 and including a drive circuit. The first electrode 21, the second electrode 22, and the electric charge accumulation electrode 24 are coupled to the drive circuit. Here, the potential of the first electrode 21 is made higher than the potential of the second electrode 22. That is, for example, the first electrode 21 is set to a positive potential and the second electrode 22 is set to a negative potential. Then, electrons generated by photoelectric conversion in the photoelectric conversion layer 23 are read out to the floating diffusion layer. The same applies also to other examples.

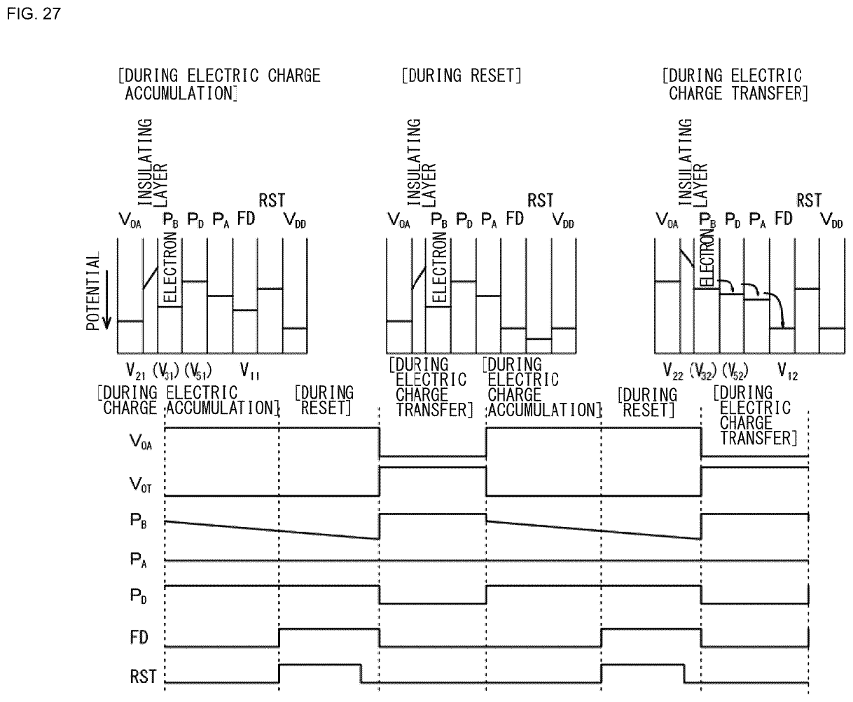

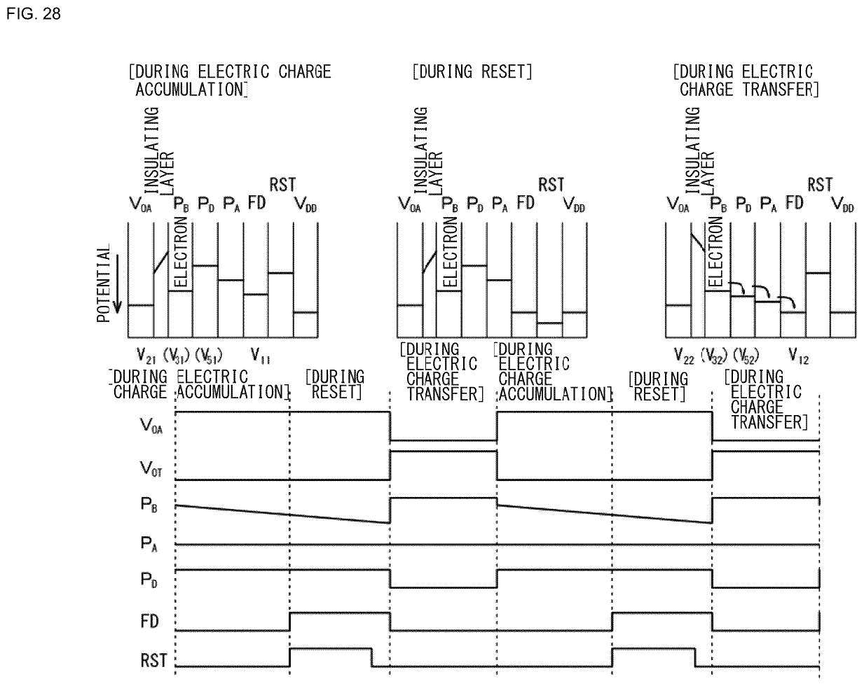

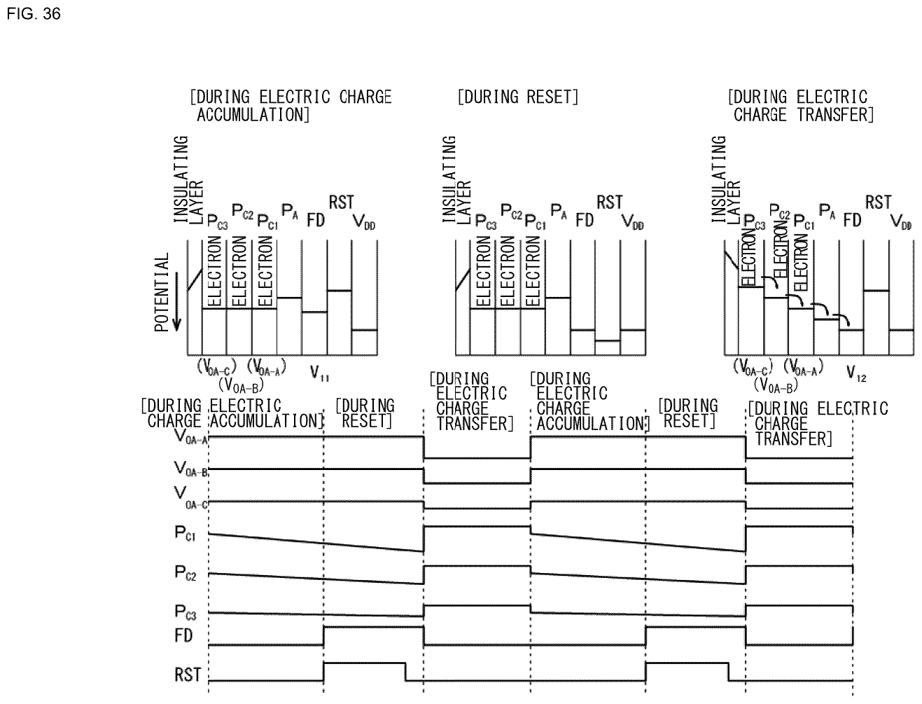

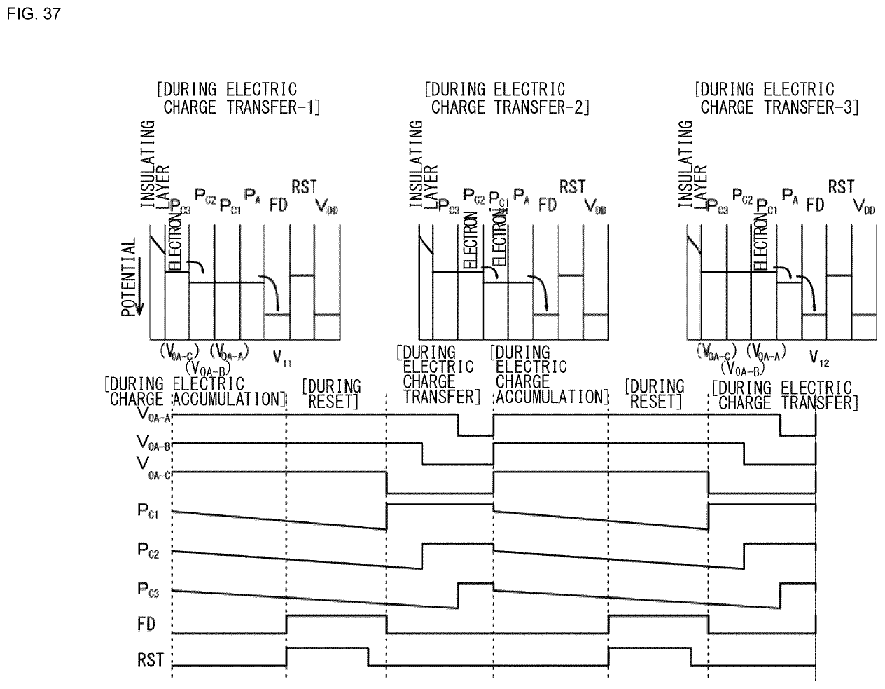

Reference numerals used in FIG. 12; FIGS. 27 and 28 in Example 4 to be described later; and FIGS. 36 and 37 in Example 6 are as follows.

P_{A}: Potential at point P_{A} in a region of the photoelectric conversion layer 23 opposed to a region positioned intermediate between the electric charge accumulation electrode 24 or a transfer control electrode (electric charge transfer electrode) 25 and the first electrode 21
P_{B}: Potential at point P_{B} in a region of the photoelectric conversion layer 23 opposed to the electric charge accumulation electrode 24
P_{C1}: Potential at point P_{C1} in a region of the photoelectric conversion layer 23 opposed to an electric charge accumulation electrode segment 24A
P_{C2}: Potential at point P_{C2} in a region of the photoelectric conversion layer 23 opposed to an electric charge accumulation electrode segment 24B
P_{C3}: Potential at point P_{C3} in a region of the photoelectric conversion layer 23 opposed to an electric charge accumulation electrode segment 24C
P_{D}: Potential at point P_{D} in a region of the photoelectric conversion layer 23 opposed to the transfer control electrode (electric charge transfer electrode) 25
FD: Potential at the first floating diffusion layer FD₁
V_{OA}: Potential at the electric charge accumulation electrode 24
V_{OA_A}: Potential at the electric charge accumulation electrode segment 24A
V_{OA-B}: Potential at the electric charge accumulation electrode segment 24B
V_{OA-C}: Potential at the electric charge accumulation electrode segment 24C
V_{OT}: Potential at the transfer control electrode (electric charge transfer electrode) 25
RST: Potential at the gate section 51 of the reset transistor TR1ᵣₛₜ
V_{DD}: Potential of the power supply
VSL₁: Signal line (data output line)
TR1ᵣₛₜ: Reset transistor
TR1ₐₘₚ: Amplification transistor
TR1ₛₑₗ: Selection transistor

During an electric charge accumulation period, from the drive circuit, the potential V₁₁ is applied to the first electrode 21 and the potential V₃₁ is applied to the electric charge accumulation electrode 24. Light having entered the photoelectric conversion layer 23 causes photoelectric conversion in the photoelectric conversion layer 23. Holes generated by the photoelectric conversion are sent from the second electrode 22 to the drive circuit via a wiring line. Meanwhile, because the potential of the first electrode 21 is higher than the potential of the second electrode 22, i.e., because a positive potential is to be applied to the first electrode 21 and a negative potential is to be applied to the second electrode 22, V₃₁>V₁₁ holds true, and preferably, V₃₁>V₁₁ holds true. This causes electrons generated by the photoelectric conversion to be attracted to the electric charge accumulation electrode 24, and to remain in a region of the photoelectric conversion layer 23 opposed to the electric charge accumulation electrode 24. That is, electric charge is accumulated in the photoelectric conversion layer 23. Because V₃₁>V₁₁ holds true, the electrons generated inside of the photoelectric conversion layer 23 would not move toward the first electrode 21. With the passage of time of photoelectric conversion, the potential in the region of the photoelectric conversion layer 23 opposed to the electric charge accumulation electrode 24 has a more negative value.

A reset operation is performed later in the electric charge accumulation period. This resets the potential of the first floating diffusion layer FD₁, and the potential of the first floating diffusion layer FD₁ shifts to the potential V_{DD} of the power supply.

After completion of the reset operation, the electric charge is read out. That is, during an electric charge transfer period, from the drive circuit, the potential V₁₂ is applied to the first electrode 21 and the potential V₃₂ is applied to the electric charge accumulation electrode 24. Here, V₃₂<V₁₂ holds true. This causes the electrons remaining in the region of the photoelectric conversion layer 23 opposed to the electric charge accumulation electrode 24 to be read out to the first electrode 21, and further to the first floating diffusion layer FD₁. That is, the electric charge accumulated in the photoelectric conversion layer 23 is read out to the control section.

This completes the series of operations including the electric charge accumulation, the reset operation, and the electric charge transfer.

The operations of the amplification transistor TR1ₐₘₚ and the selection transistor TR1ₛₑₗ after the electrons are read out to the first floating diffusion layer FD₁ are the same as the operations of existing ones of these transistors. In addition, the series of operations including the electric charge accumulation, the reset operation, and the electric charge transfer of the second imaging element 11 and the third imaging element 12 are similar to the series of operations including the electric charge accumulation, the reset operation, and the electric charge transfer according to existing techniques. In addition, reset noise of the first floating diffusion layer FD₁ is removable through a correlated double sampling (CDS, Correlated Double Sampling) process in a similar manner to the existing techniques.

As has been described, in Example 3, the electric charge accumulation electrode is provided that is disposed at a distance from the first electrode and disposed to be opposed to the photoelectric conversion layer with the insulating layer interposed therebetween. Thus, when the photoelectric conversion layer is irradiated with light and photoelectric conversion occurs in the photoelectric conversion layer, a kind of capacitor is formed by the photoelectric conversion layer, the insulating layer, and the electric charge accumulation electrode, making it possible to accumulate electric charge in the photoelectric conversion layer. For this reason, it is possible to completely deplete a portion in which electric charge is accumulated and eliminate the electric charge when exposure is started. As a result, it is possible to suppress the occurrence of the phenomenon that kTC noise becomes greater and random noise deteriorates to cause reduction in quality of the captured images. In addition, because it is possible to reset all of the pixels all at once, the so-called global shutter function is achievable.

FIG. 14 illustrates a conceptual diagram of the imaging device of Example 3. An imaging device 100 of Example 3 includes an imaging region 111 in which stacked imaging elements 101 are arranged in a two-dimensional array, and, as drive circuits (peripheral circuits) thereof, the vertical drive circuit 112, the column signal processing circuit 113, a horizontal drive circuit 114, an output circuit 115, a drive control circuit 116, and the like. Needless to say, these circuits may be configured of known circuits, or may be configured using other circuit configurations (e.g., various circuits used in existing CCD imaging devices or CMOS imaging devices). In FIG. 14, the representation of a reference numeral “101” for the stacked imaging elements 101 is made in only one row.

On the basis of a vertical synchronization signal, a horizontal synchronization signal, and a master clock, the drive control circuit 116 generates a clock signal and a control signal serving as a reference for operations of the vertical drive circuit 112, the column signal processing circuit 113, and the horizontal drive circuit 114. Then, the clock signal and the control signal thus generated are inputted to the vertical drive circuit 112, the column signal processing circuit 113, and the horizontal drive circuit 114.

The vertical drive circuit 112 includes, for example, a shift register, and selectively scans the stacked imaging elements 101 in the imaging region 111 sequentially in the vertical direction row by row. Then, a pixel signal (image signal) based on a current (signal) generated according to the amount of light reception at each stacked imaging element 101 is sent to the column signal processing circuit 113 via the signal line (data output line) 117 or VSL.

The column signal processing circuit 113 is disposed, for example, for each column of the stacked imaging elements 101, and performs signal processing, including noise removal and signal amplification, on the image signals outputted from one row of the stacked imaging elements 101 for each imaging element in accordance with a signal from a black reference pixel (although not illustrated, formed around the effective pixel region). At an output stage of the column signal processing circuit 113, a horizontal selection switch (not illustrated) is provided to be coupled between the output stage and a horizontal signal line 118.

The horizontal drive circuit 114 includes, for example, a shift register, and sequentially outputs horizontal scan pulses to sequentially select each one of the column signal processing circuits 113, thereby outputting a signal from each of the column signal processing circuits 113 to the horizontal signal line 118.

The output circuit 115 performs signal processing on the signals sequentially supplied from the respective column signal processing circuits 113 through the horizontal signal line 118, and outputs the processed signals.

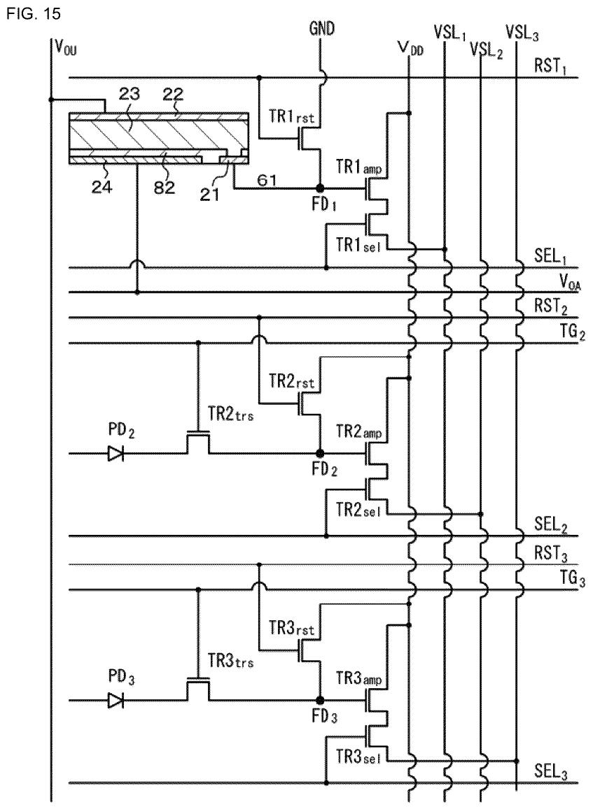

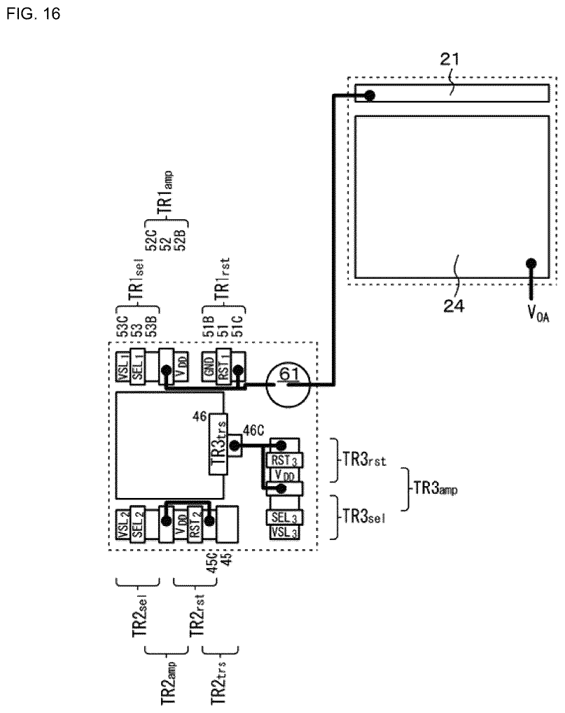

FIG. 15 illustrates an equivalent circuit diagram of a modification example of the imaging element and the stacked imaging element of Example 3, and FIG. 16 illustrates a schematic layout diagram of the first electrode, the electric charge accumulation electrode, and the transistors included in the control section. As illustrated, the other source/drain region 51B of the reset transistor TR1ᵣₛₜ may be grounded, instead of being coupled to the power supply V_{DD}.

Although not illustrated, the insulating layer 82 may have a two-layer configuration including an insulating layer or lower layer and an insulating layer or upper layer. That is, it is sufficient that the insulating layer or lower layer is formed at least over the electric charge accumulation electrode 24 and in a region between the electric charge accumulation electrode 24 and the first electrode 21 (more specifically, the insulating layer or lower layer is formed on the interlayer insulating layer 81 including the electric charge accumulation electrode 24), a planarization process is performed on the insulating layer or lower layer, and thereafter, the insulating layer or upper layer is formed over the insulating layer or lower layer and the electric charge accumulation electrode 24. This makes it possible to accomplish the planarization of the insulating layer 82 with reliability. It is then sufficient that the connection section 67 is opened in the insulating layer 82 obtained in this way.

In addition, FIG. 15 illustrates an equivalent circuit diagram of a modification example of the imaging element and the stacked imaging element of Example 3, and FIG. 15 illustrates a schematic layout diagram of the first electrode, the electric charge accumulation electrode, and the transistors included in the control section. As illustrated, the other source/drain region 51B of the reset transistor TR1ᵣₛₜ may be grounded, instead of being coupled to the power supply V_{DD}.

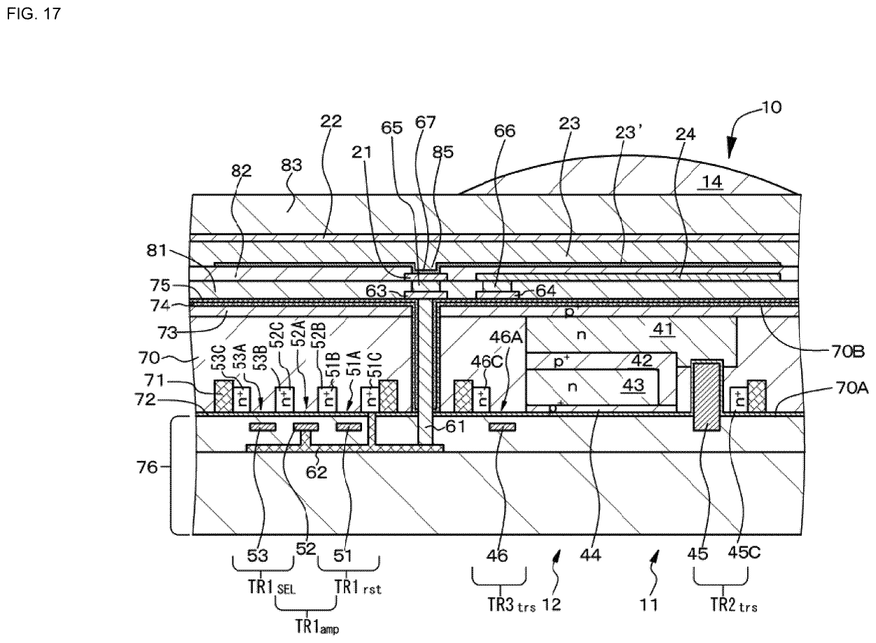

Furthermore, FIG. 17 illustrates a schematic partial cross-sectional view of another modification example of the imaging element of Example 3. As illustrated, an inorganic oxide semiconductor material layer 23′ may be formed directly below the photoelectric conversion layer 23.

Forming the inorganic oxide semiconductor material layer makes it possible to obtain a photoelectric conversion layer (including the inorganic oxide semiconductor material layer) having superior balance of characteristics such as the carrier mobility, the carrier density, the SS value, and the transparency with respect to incident light. Further, it is possible to achieve, in a well-balanced manner, optimization of the carrier density of the inorganic oxide semiconductor material layer (optimization of a degree of depletion of the inorganic oxide semiconductor material layer), high carrier mobility of the inorganic oxide semiconductor material layer, control of the minimum energy value of the conduction band of the inorganic oxide semiconductor material included in the inorganic oxide semiconductor material layer, and suppression of generation of the oxygen deficiency in the inorganic oxide semiconductor material layer. Therefore, despite the simple configuration and structure, it is possible to provide an imaging element, a stacked imaging element, and an imaging device having less loss of incident light and being superior in transfer characteristic for the electric charge accumulated in the photoelectric conversion layer. Moreover, the inorganic oxide semiconductor material layer is stable with respect to a manufacturing process of the imaging element after formation of the inorganic oxide semiconductor material layer, and it is also possible to suppress aged deterioration of the imaging element, the stacked imaging element, and the imaging device. In addition, because the photoelectric conversion section has a two-layer structure of the inorganic oxide semiconductor material layer and the photoelectric conversion layer, it is possible to prevent recombination during electric charge accumulation, and it is possible to further increase the efficiency of transfer of the electric charge accumulated in the photoelectric conversion layer to the first electrode. Further, it is possible to temporarily hold, in the inorganic oxide semiconductor material layer, the electric charge generated in the photoelectric conversion layer to thereby control the timing of transfer and the like. It is also possible to suppress the generation of a dark current.

It is possible to produce the imaging element and stacked imaging element of Example 3 by the following method, for example. That is, an SOI substrate is prepared first. A first silicon layer is then formed on the surface of the SOI substrate on the basis of an epitaxial growth method, and the p+ layer 73 and the n-type semiconductor region 41 are formed on the first silicon layer. Next, a second silicon layer is formed on the first silicon layer on the basis of an epitaxial growth method, and the element separation region 71, the oxide film 72, the p+ layer 42, the n-type semiconductor region 43, and the p+ layer 44 are formed on the second silicon layer. In addition, various transistors and the like included in the control section of the imaging element are formed on the second silicon layer, and the wiring layer 62, the interlayer insulating layer 76, and various wiring lines are further formed thereon. The interlayer insulating layer 76 and a support substrate (not illustrated) are thereafter bonded to each other. Thereafter, the SOI substrate is removed to expose the first silicon layer. The surface of the second silicon layer corresponds to the front surface 70A of the semiconductor substrate 70, and the surface of the first silicon layer corresponds to the back surface 70B of the semiconductor substrate 70. In addition, the first silicon layer and the second silicon layer are collectively expressed as the semiconductor substrate 70. Next, an opening for forming the contact hole section 61 is formed on the side of the back surface 70B of the semiconductor substrate 70, and the HfO₂ film 74, the insulating material film 75, and the contact hole section 61 are formed. Further, the pad sections 63 and 64, the interlayer insulating layer 81, the connection holes 65 and 66, the first electrode 21, the electric charge accumulation electrode 24, and the insulating layer 82 are formed. Next, the connection section 67 is opened, and the photoelectric conversion layer 23, the second electrode 22, the protection material layer 83, and the on-chip microlens 14 are formed. It is possible to obtain the imaging element and the stacked imaging element of Example 3 in the above-described manner.

### Example 4

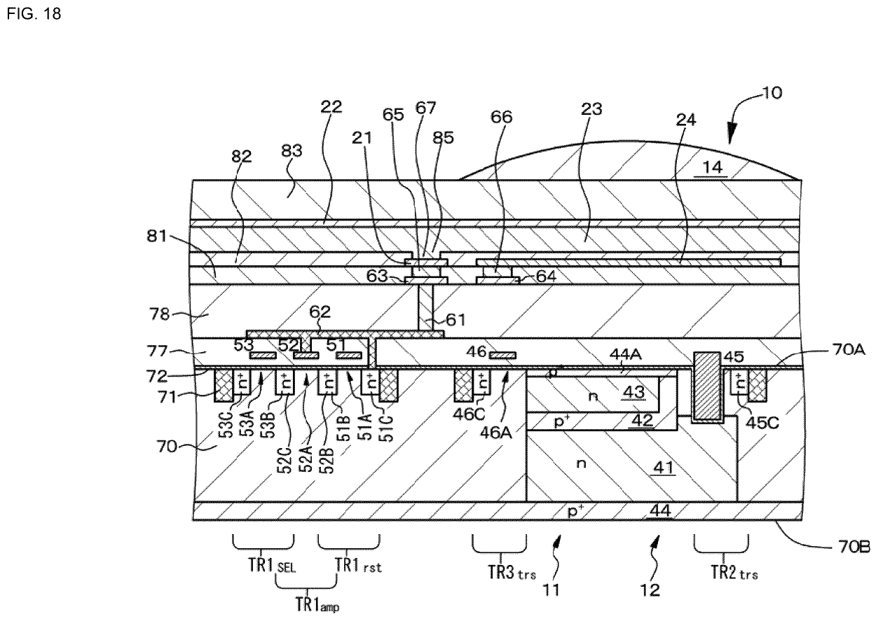

Example 4 is a modification of Example 3. FIG. 18 illustrates a schematic partial cross-sectional view of an imaging element and a stacked imaging element of Example 4. The imaging element and the stacked imaging element of Example 4 are of the front illuminated type, and have a structure in which three imaging elements are stacked, the three imaging elements being: the green light imaging element of Example 1 of the first type (first imaging element 10) having sensitivity to green light and including the green light photoelectric conversion layer of the first type for absorbing green light; the existing blue light imaging element of the second type (second imaging element 11) having sensitivity to blue light and including the blue light photoelectric conversion layer of the second type for absorbing blue light; and the existing red light imaging element of the second type (third imaging element 12) having sensitivity to red light and including the red light photoelectric conversion layer of the second type for absorbing red light. Here, the red light imaging element (third imaging element 12) and the blue light imaging element (second imaging element 11) are provided in the semiconductor substrate 70, and the second imaging element 11 is positioned closer to the light incident side than the third imaging element 12. In addition, the green light imaging element (first imaging element 10) is provided above the blue light imaging element (second imaging element 11).

As in Example 1, various transistors included in the control section are provided on side of the front surface 70A of the semiconductor substrate 70. These transistors may have configurations and structures substantially similar to those of the transistors described in Example 3. In addition, while the second imaging element 11 and the third imaging element 12 are provided in the semiconductor substrate 70, these imaging elements may also have configurations and structures substantially similar to those of the second imaging element 11 and the third imaging element 12 described in Example 3.

The interlayer insulating layer 81 is formed above the front surface 70A of the semiconductor substrate 70, and the first electrode 21, the photoelectric conversion layer 23, and the second electrode 22, and also the electric charge accumulation electrode 24 are provided above the interlayer insulating layer 81, as in the imaging element of Example 1.

In this way, it is possible for the imaging element and the stacked imaging element of Example 4 to have configurations and structures similar to the configurations and structures of the imaging element and the stacked imaging element of Example 3, except for being of the front illuminated type, and the detailed description thereof is thus omitted.

### Example 5

Example 5 is a modification of Example 3 and Example 4.

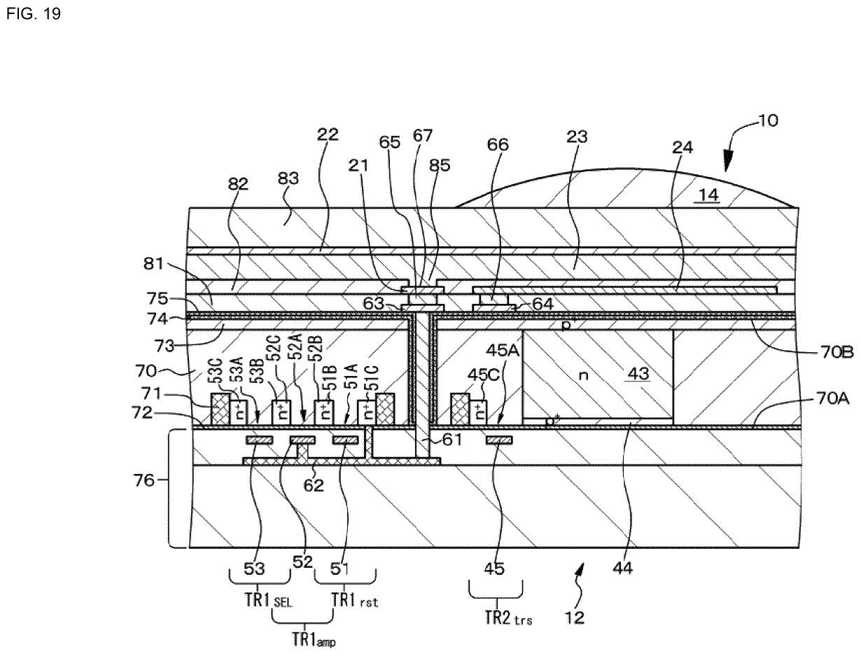

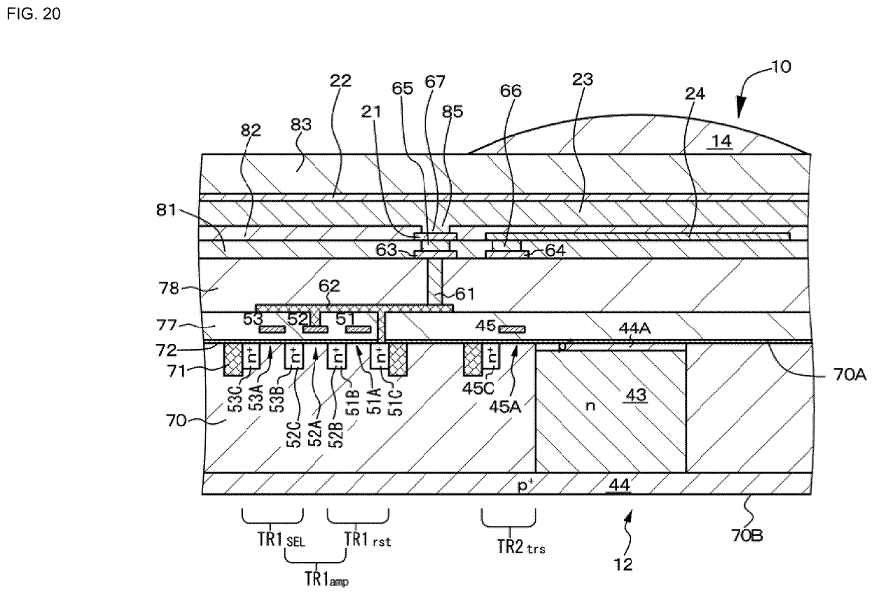

FIG. 19 illustrates a schematic partial cross-sectional view of an imaging element and a stacked imaging element of Example 5. The imaging element and the stacked imaging element of Example 5 are of the back illuminated type, and have a structure in which two imaging elements are stacked, the two imaging elements being the first imaging element 10 of Example 1 of the first type and the third imaging element 12 of the second type. In addition, FIG. 20 illustrates a schematic partial cross-sectional view of Modification Example-1 of the imaging element and the stacked imaging element of Example 5. The modification example of the imaging element and the stacked imaging element of Example 5 are of the front illuminated type, and has a structure in which two imaging elements are stacked, the two imaging elements being the first imaging element 10 of Example 1 of the first type and the third imaging element 12 of the second type. Here, the first imaging element 10 absorbs light in primary colors, and the third imaging element 12 absorbs light in complementary colors. Alternatively, the first imaging element 10 absorbs white light, and the third imaging element 12 absorbs infrared rays.

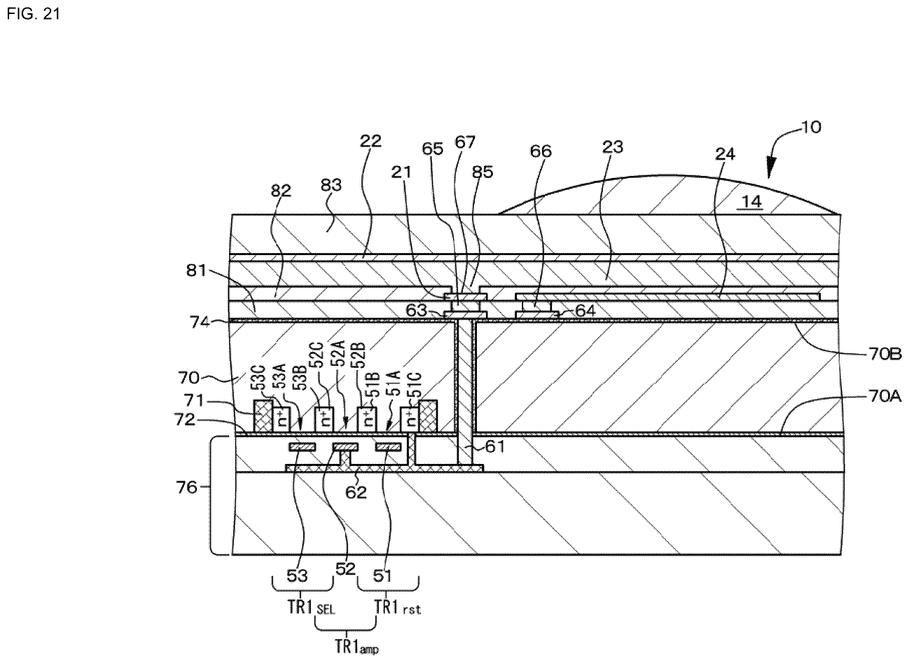

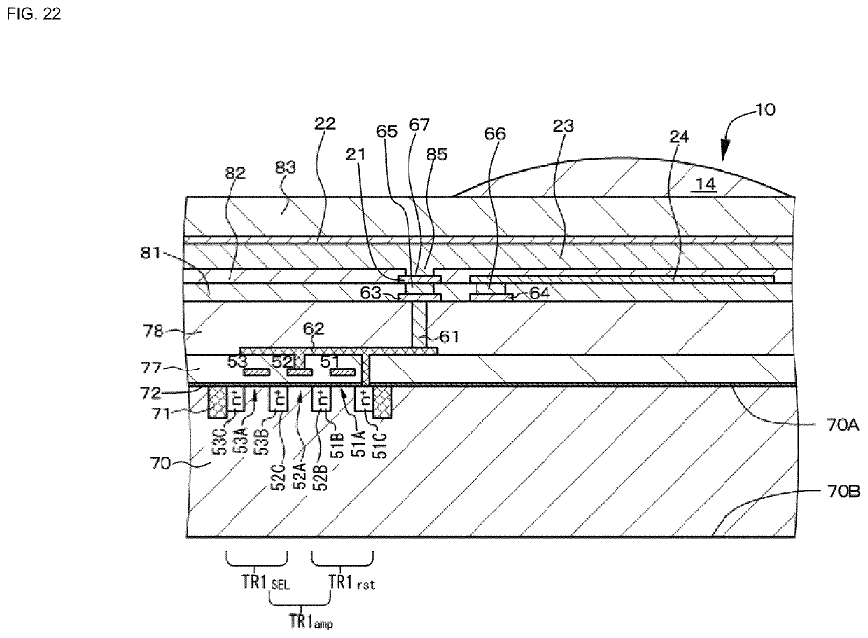

FIG. 21 illustrates a schematic partial cross-sectional view of Modification Example-2 of the imaging element of Example 5. Modification Example-2 of the imaging element of Example 5 is of the back illuminated type, and includes the first imaging element 10 of Example 1 of the first type. In addition, FIG. 22 illustrates a schematic partial sectional view of Modification Example-3 of the imaging element of Example 5. Modification Example-1 of the imaging element of Example 5 is of the front illuminated type, and includes the first imaging element 10 of Example 1 of the first type. The imaging devices illustrated in FIGS. 21 and 22 are imaging devices according to the first aspect of the present disclosure. Here, the first imaging element 10 includes three kinds of imaging elements, i.e., an imaging element that absorbs red light, an imaging element that absorbs green light, and an imaging element that absorbs blue light. Further, a plurality of ones of these imaging elements is included in the imaging device according to the first aspect of the present disclosure. Examples of arrangement of the plurality of ones of these imaging elements include a Bayer arrangement. Color filter layers for performing blue, green, and red spectral separation are disposed on the light incident side of the imaging elements as necessary.

Instead of providing one imaging element of Example 1 of the first type, two may be provided in a stacked mode (i.e., a mode in which two photoelectric conversion sections are stacked, and control sections for the two photoelectric conversion sections are provided in the semiconductor substrate), or alternatively, three may be provided in a stacked mode (i.e., a mode in which three photoelectric conversion sections may be stacked, and control sections for the three photoelectric conversion sections are provided in the semiconductor substrate). The following table illustrates examples of the stacked structures of the imaging element of the first type and the imaging element of the second type.

| | First type | Second type |
|---|---|---|
| Back illuminated | 1 | 2 |
| type and front | Green | Blue + Red |
| illuminated | 1 | 1 |
| type | Primary color | Complementary color |
| | 1 | 1 |
| | White | Infrared |
| | 1 | 0 |
| | Blue, Green, or Red | |
| | 2 | 2 |
| | Green + Infrared | Blue + Red |
| | 2 | 1 |
| | Green + Blue | Red |
| | 2 | 0 |
| | White + Infrared | |
| | 3 | 2 |
| | Green + Blue + Red | Blue-Green (Emerald) + |
| | | Infrared |
| | 3 | 1 |
| | Green + Blue + Red | Infrared |
| | 3 | 0 |
| | Blue + Green + Red | |

### Example 6

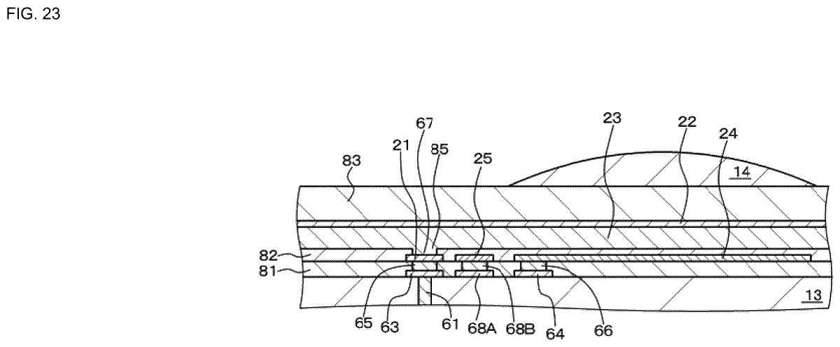

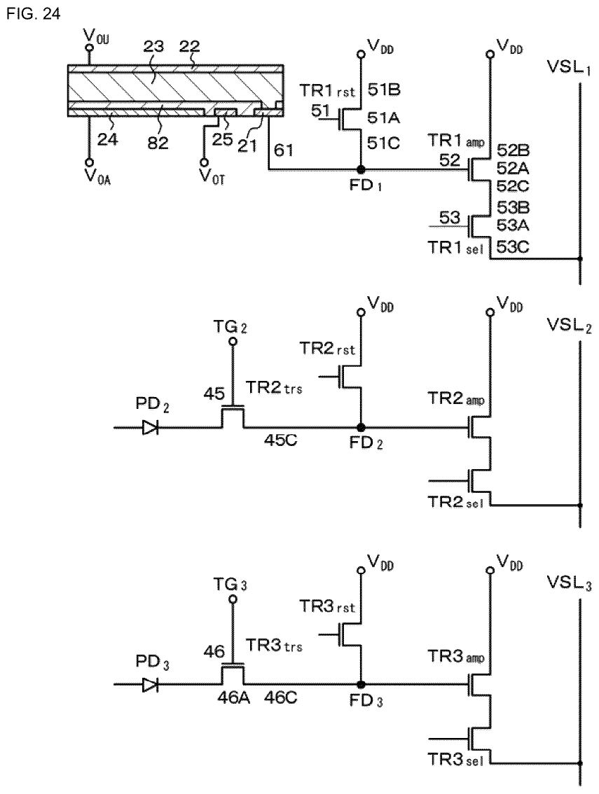

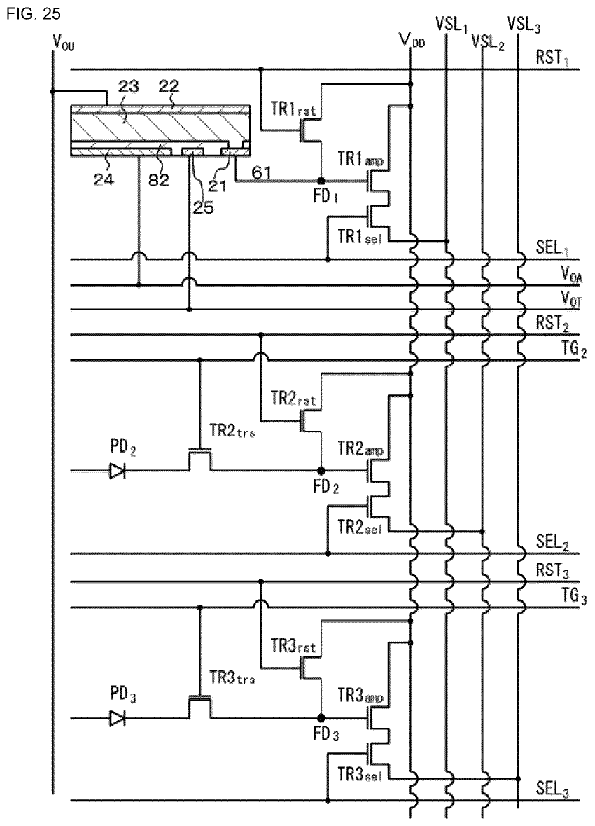

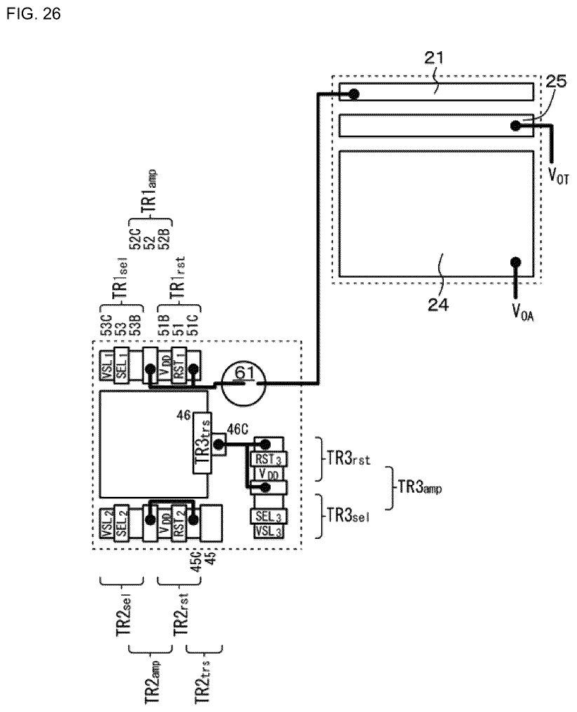

Example 6 is a modification of Examples 3 to 5, and relates to an imaging element including the transfer control electrode (electric charge transfer electrode) of the present disclosure. FIG. 23 illustrates a schematic partial cross-sectional view of a portion of an imaging element and a stacked imaging element of Example 6. FIGS. 24 and 25 illustrate equivalent circuit diagrams of the imaging element and the stacked imaging element of Example 6. FIG. 26 illustrates a schematic layout diagram of the first electrode, the transfer control electrode, and the electric charge accumulation electrode, and transistors included in the control section that are included in the imaging element of Example 6. FIGS. 27 and 28 schematically illustrate a state of potential at each part during operation of the imaging element of Example 6. FIG. 13B illustrates an equivalent circuit diagram for describing each part of the imaging element of Example 6.

It is to be noted that, in FIGS. 23, and FIGS. 30, 32, 40, 46, 49A, 49B, 50A, 50B, 65, and 66 to be described later, various constituent elements of the imaging element positioned below the interlayer insulating layer 81 are collectively denoted by Reference numeral 13 for the sake of convenience in order to simplify the drawings.

The imaging element and the stacked imaging element of Example 6 further include, between the first electrode 21 and the electric charge accumulation electrode 24, the transfer control electrode (electric charge transfer electrode) 25 disposed at a distance from the first electrode 21 and the electric charge accumulation electrode 24, and disposed to be opposed to the photoelectric conversion layer 23 with the insulating layer 82 interposed therebetween. The transfer control electrode 25 is coupled to a pixel drive circuit included in the drive circuit, via a connection hole 68B, a pad section 68A, and a wiring line V_{OT} provided in the interlayer insulating layer 81.

In the following, description is given of an operation of the imaging element (first imaging element 10) of Example 6 with reference to FIGS. 27 and 28. It is to be noted that, in FIGS. 27 and 28, the values of a potential to be applied to the electric charge accumulation electrode 24 and a potential at point P_{D} are different.

During an electric charge accumulation period, from the drive circuit, the potential V₁₁ is applied to the first electrode 21, the potential V₃₁ is applied to the electric charge accumulation electrode 24, and the potential V₅₁ is applied to the transfer control electrode 25. Light having entered the photoelectric conversion layer 23 causes photoelectric conversion in the photoelectric conversion layer 23. Holes generated by the photoelectric conversion are sent from the second electrode 22 to the drive circuit via a wiring line Vou. Meanwhile, the potential of the first electrode 21 is higher than the potential of the second electrode 22, i.e., for example, a positive potential is to be applied to the first electrode 21 and a negative potential is to be applied to the second electrode 22. Thus, V₃₁>V₅₁ (e.g., V₃₁>V₁₁>V₅₁, or V₁₁>V₃₁>V₅₁) holds true. This causes electrons generated by the photoelectric conversion to be attracted to the electric charge accumulation electrode 24, and to remain in the region of the photoelectric conversion layer 23 opposed to the electric charge accumulation electrode 24. That is, electric charge is accumulated in the photoelectric conversion layer 23. Because V₃₁>V₅₁ holds true, it is possible to prevent, with reliability, the electrons generated inside of the photoelectric conversion layer 23 from moving toward the first electrode 21. With the passage of time of photoelectric conversion, the potential in the region of the photoelectric conversion layer 23 opposed to the electric charge accumulation electrode 24 has a more negative value.

A reset operation is performed later in the electric charge accumulation period. This resets the potential of the first floating diffusion layer FD₁, and the potential of the first floating diffusion layer FD₁ shifts to the potential V_{DD} of the power supply.

After completion of the reset operation, the electric charge is read out. That is, during an electric charge transfer period, from the drive circuit, the potential V₁₂ is applied to the first electrode 21, the potential V₃₂ is applied to the electric charge accumulation electrode 24, and the potential V₅₂ is applied to the transfer control electrode 25. Here, V₃₂≤V₅₂≤V₁₂ (preferably, V₃₂<V₅₂<V₁₂) holds true. This causes the electrons remaining in the region of the photoelectric conversion layer 23 opposed to the electric charge accumulation electrode 24 to be read out to the first electrode 21, and further to the first floating diffusion layer FD₁ with reliability. That is, the electric charge accumulated in the photoelectric conversion layer 23 is read out to the control section.

This completes the series of operations including the electric charge accumulation, the reset operation, and the electric charge transfer.

The operations of the amplification transistor TR1ₐₘₚ and the selection transistor TR1ₛₑₗ after the electrons are read out to the first floating diffusion layer FD₁ are the same as the operations of existing ones of these transistors. In addition, for example, the series of operations including the electric charge accumulation, the reset operation, and the electric charge transfer of the second imaging element 11 and the third imaging element 12 are similar to the series of operations including the electric charge accumulation, the reset operation, and the electric charge transfer according to existing techniques.

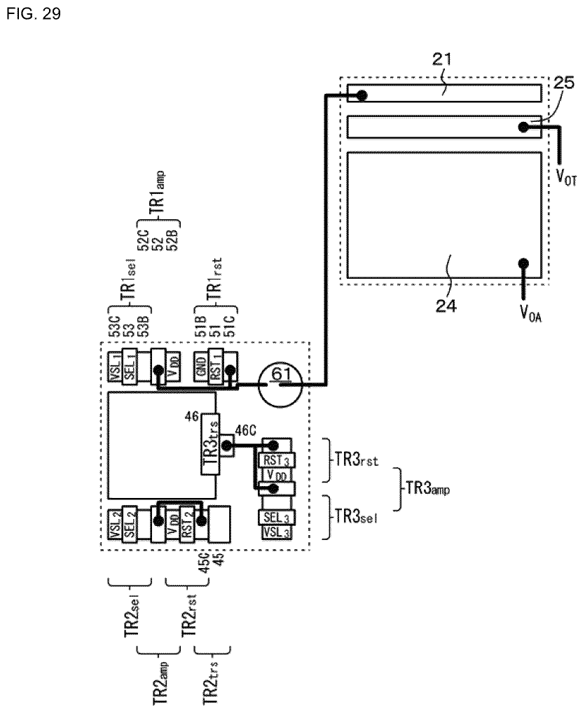

FIG. 29 illustrates a schematic layout diagram of the first electrode and the electric charge accumulation electrode, and the transistors included in the control section that are included in a modification example of the imaging element of Example 6. As illustrated, the other source/drain region 51B of the reset transistor TR1ᵣₛₜ may be grounded, instead of being coupled to the power supply V_{DD}.

### Example 7

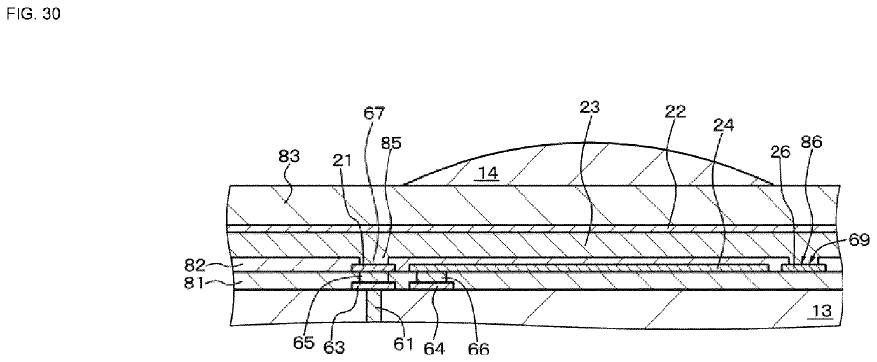

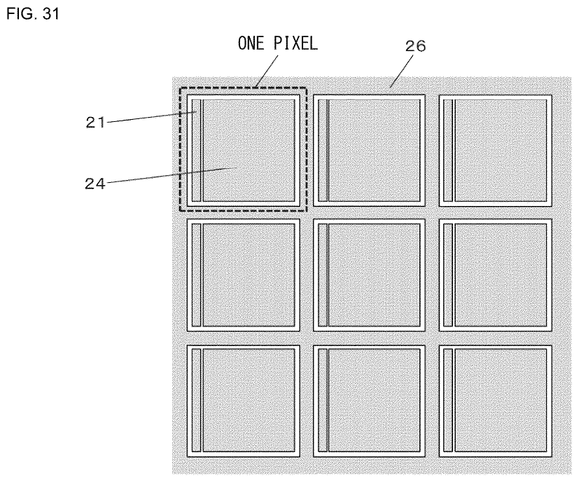

Example 7 is a modification of Examples 3 to 6, and relates to an imaging element including the electric charge drain electrode of the present disclosure. FIG. 30 illustrates a schematic partial cross-sectional view of a portion of an imaging element of Example 7. FIG. 31 illustrates a schematic layout diagram of the first electrode, the electric charge accumulation electrode, and the electric charge drain electrode included in the photoelectric conversion section including the electric charge accumulation electrode of the imaging element of Example 7.

The imaging element of Example 7 further includes an electric charge drain electrode 26 coupled to the photoelectric conversion layer 23 via a connection section 69 and disposed at a distance from the first electrode 21 and the electric charge accumulation electrode 24. Here, the electric charge drain electrode 26 is disposed to surround the first electrode 21 and the electric charge accumulation electrode 24 (i.e., in a picture frame form). The electric charge drain electrode 26 is coupled to the pixel drive circuit included in the drive circuit. The photoelectric conversion layer 23 extends in the connection section 69. That is, the photoelectric conversion layer 23 extends in a second opening 85 provided in the insulating layer 82, and the photoelectric conversion layer 23 is coupled to the electric charge drain electrode 26. The electric charge drain electrode 26 is shared by (common to) a plurality of imaging elements. A side surface of the second opening 85 may be sloped to widen the second opening 85 upward. The electric charge drain electrode 26 is usable as, for example, a floating diffusion or overflow drain of the photoelectric conversion section.

In Example 7, during an electric charge accumulation period, from the drive circuit, the potential V₁₁ is applied to the first electrode 21, the potential V₃₁ is applied to the electric charge accumulation electrode 24, the potential V₆₁ is applied to the electric charge drain electrode 26, and electric charge is accumulated in the photoelectric conversion layer 23. Light having entered the photoelectric conversion layer 23 causes photoelectric conversion in the photoelectric conversion layer 23. Holes generated by the photoelectric conversion are sent from the second electrode 22 to the drive circuit via the wiring line Vou. Meanwhile, the potential of the first electrode 21 is higher than the potential of the second electrode 22, i.e., for example, a positive potential is to be applied to the first electrode 21 and a negative potential is to be applied to the second electrode 22. Thus, V₆₁>V₁₁ (e.g., V₃₁>V₆₁>V₁₁) holds true. This causes electrons generated by the photoelectric conversion to be attracted to the electric charge accumulation electrode 24, and to remain in the region of the photoelectric conversion layer 23 opposed to the electric charge accumulation electrode 24. It is thus possible to prevent, with reliability, the electrons from moving toward the first electrode 21. However, electrons that are not sufficiently attracted by the electric charge accumulation electrode 24 or that have failed to be accumulated in the photoelectric conversion layer 23 (so-called overflowing electrons) are sent to the drive circuit via the electric charge drain electrode 26.

A reset operation is performed later in the electric charge accumulation period. This resets the potential of the first floating diffusion layer FD₁, and the potential of the first floating diffusion layer FD₁ shifts to the potential V_{DD} of the power supply.

After completion of the reset operation, the electric charge is read out. That is, during an electric charge transfer period, from the drive circuit, the potential V₁₂ is applied to the first electrode 21, the potential V₃₂ is applied to the electric charge accumulation electrode 24, and the potential V₆₂ is applied to the electric charge drain electrode 26. Here, V₆₂<V₁₂ (e.g., V₆₂<V₃₂<V₁₂) holds true. This causes the electrons remaining in the region of the photoelectric conversion layer 23 opposed to the electric charge accumulation electrode 24 to be read out to the first electrode 21, and further to the first floating diffusion layer FD₁ with reliability. That is, the electric charge accumulated in the photoelectric conversion layer 23 is read out to the control section.

This completes the series of operations including the electric charge accumulation, the reset operation, and the electric charge transfer.

The operations of the amplification transistor TR1ₐₘₚ and the selection transistor TR1ₛₑₗ after the electrons are read out to the first floating diffusion layer FD₁ are the same as the operations of existing ones of these transistors. In addition, for example, the series of operations including the electric charge accumulation, the reset operation, and the electric charge transfer of the second imaging element and the third imaging element are similar to the series of operations including the electric charge accumulation, the reset operation, and the electric charge transfer according to existing techniques.

In Example 7, because the so-called overflowing electrons are sent to the drive circuit via the electric charge drain electrode 26, it is possible to suppress leakage into a portion in which electric charge is accumulated of an adjacent pixel, and it is possible to suppress the occurrence of blooming. This makes it possible to improve the imaging performance of the imaging element.

### Example 8

Example 8 is a modification of Examples 3 to 7, and relates to an imaging element including a plurality of electric charge accumulation electrode segments of the present disclosure.

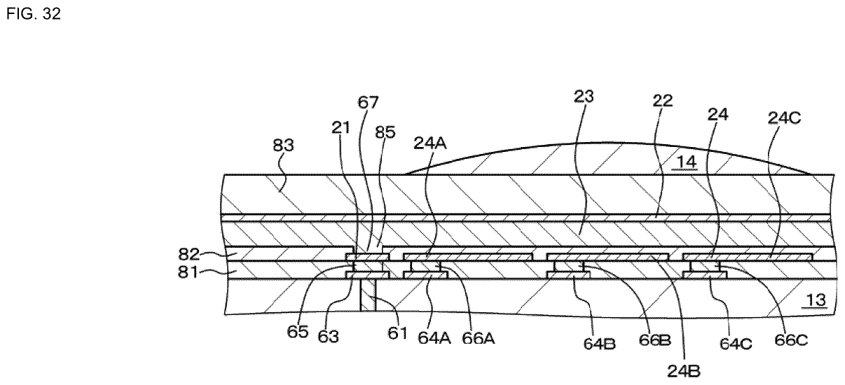

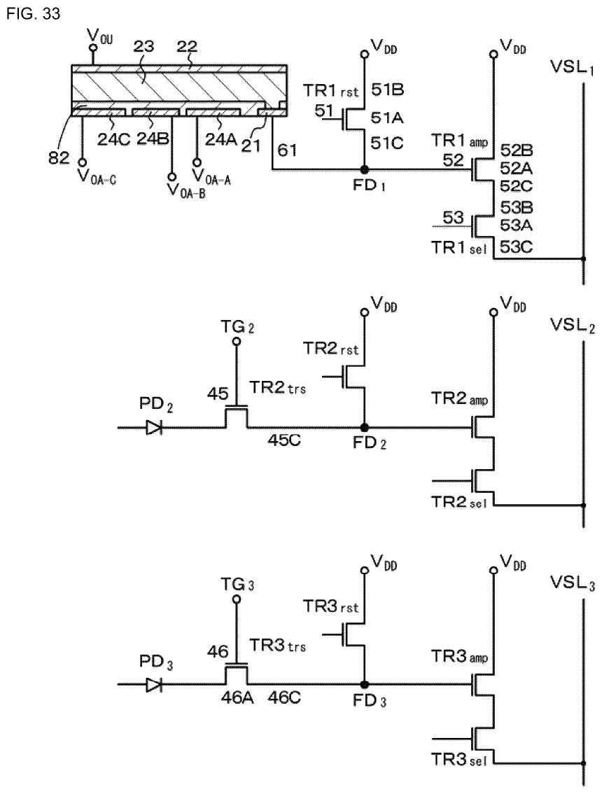

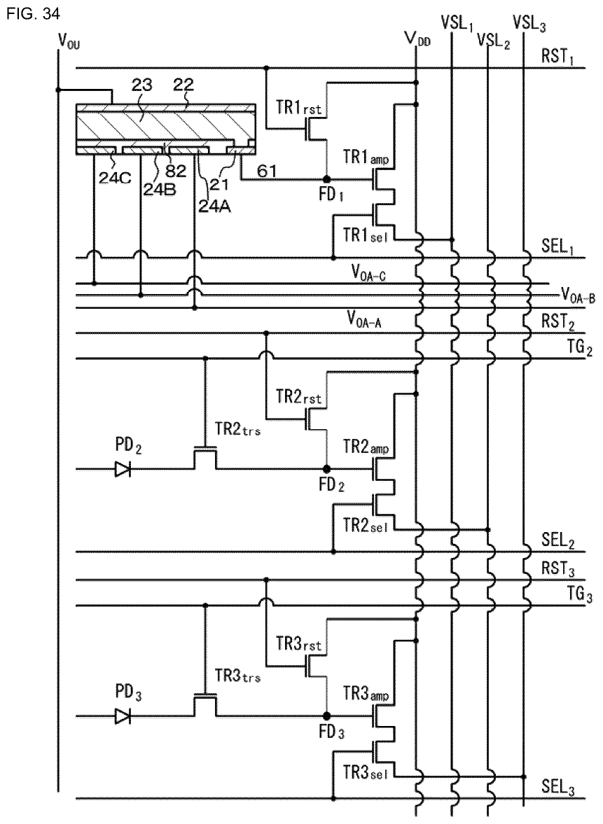

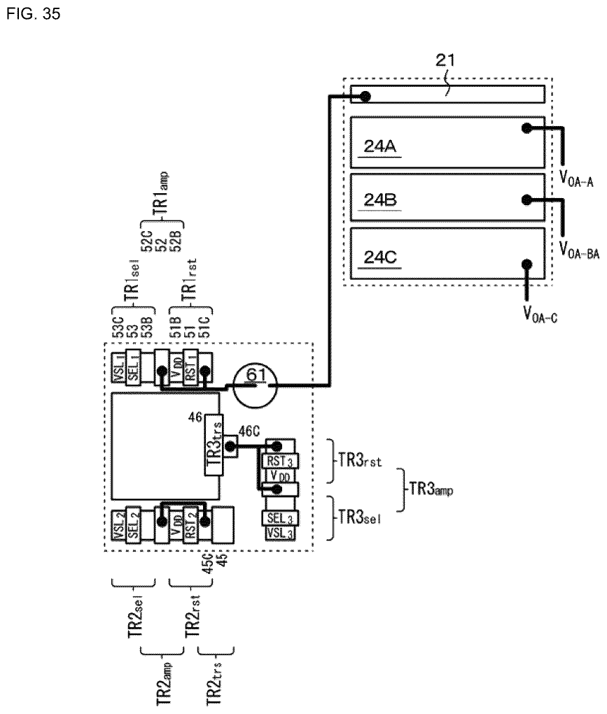

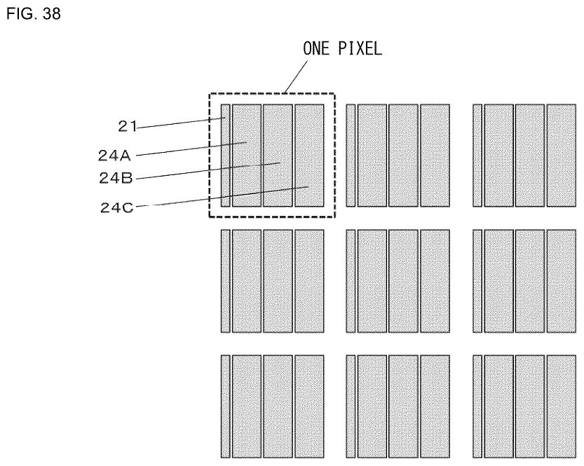

FIG. 32 illustrates a schematic partial cross-sectional view of a portion of an imaging element of Example 8. FIGS. 33 and 34 illustrate equivalent circuit diagrams of the imaging element of Example 8. FIG. 35 illustrates a schematic layout diagram of the first electrode and the electric charge accumulation electrode included in the photoelectric conversion section including the electric charge accumulation electrode, and the transistors included in the control section of the imaging element of Example 8. FIGS. 36 and 37 schematically illustrate a state of potential at each part during operation of the imaging element of Example 8. FIG. 13C illustrates an equivalent circuit diagram for describing each part of the imaging element of Example 8. In addition, FIG. 38 illustrates a schematic layout diagram of the first electrode and the electric charge accumulation electrode included in the photoelectric conversion section including the electric charge accumulation electrode of the imaging element of Example 8.

In Example 8, the electric charge accumulation electrode 24 includes a plurality of electric charge accumulation electrode segments 24A, 24B, and 24C. The number of the electric charge accumulation electrode segments only has to be two or more, and is set to “3” in Example 8. In the imaging element of Example 8, the potential of the first electrode 21 is higher than the potential of the second electrode 22, i.e., for example, a positive potential is to be applied to the first electrode 21 and a negative potential is to be applied to the second electrode 22. Thus, during the electric charge transfer period, a potential to be applied to the electric charge accumulation electrode segment 24A positioned closest to the first electrode 21 is higher than a potential to be applied to the electric charge accumulation electrode segment 24C positioned farthest from the first electrode 21. By imparting a potential gradient to the electric charge accumulation electrode 24 in such a manner, the electrons remaining in the region of the photoelectric conversion layer 23 opposed to the electric charge accumulation electrode 24 are read out to the first electrode 21, and further to the first floating diffusion layer FD₁ with higher reliability. That is, the electric charge accumulated in the photoelectric conversion layer 23 is read out to the control section.

In the example illustrated in FIG. 36, during the electric charge transfer period, the electrons remaining in the region of the photoelectric conversion layer 23 are read out to the first floating diffusion layer FD₁ all at once by satisfying: the potential of the electric charge accumulation electrode segment 24C<the potential of the electric charge accumulation electrode segment 24B<the potential of the electric charge accumulation electrode segment 24A. Meanwhile, in the example illustrated in FIG. 37, during the electric charge transfer period, the potential of the electric charge accumulation electrode segment 24C, the potential of the electric charge accumulation electrode segment 24B, and the potential of the electric charge accumulation electrode segment 24A are changed gradually (i.e., changed stepwise or in a slope-like manner). The electrons remaining in a region of the photoelectric conversion layer 23 opposed to the electric charge accumulation electrode segment 24C are thereby moved to a region of the photoelectric conversion layer 23 opposed to the electric charge accumulation electrode segment 24B, and subsequently, the electrons remaining in the region of the photoelectric conversion layer 23 opposed to the electric charge accumulation electrode segment 24B are moved to a region of the photoelectric conversion layer 23 opposed to the electric charge accumulation electrode segment 24A. Subsequently, the electrons remaining in the region of the photoelectric conversion layer 23 opposed to the electric charge accumulation electrode segment 24A are read out to the first floating diffusion layer FD₁ with reliability.

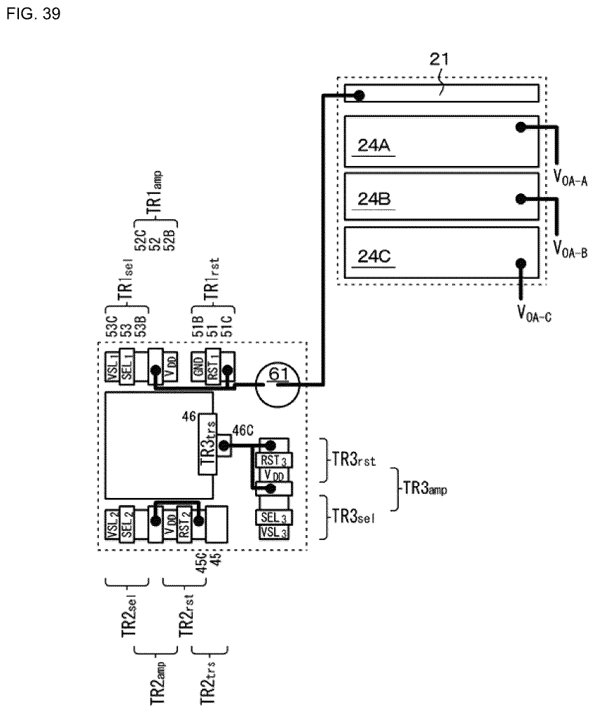

FIG. 39 illustrates a schematic layout diagram of the first electrode and the electric charge accumulation electrode, and the transistors included in the control section that are included in a modification example of the imaging element of Example 8. As illustrated, the other source/drain region 51B of the reset transistor TR1ᵣₛₜ may be grounded, instead of being coupled to the power supply V_{DD}.

### Example 9

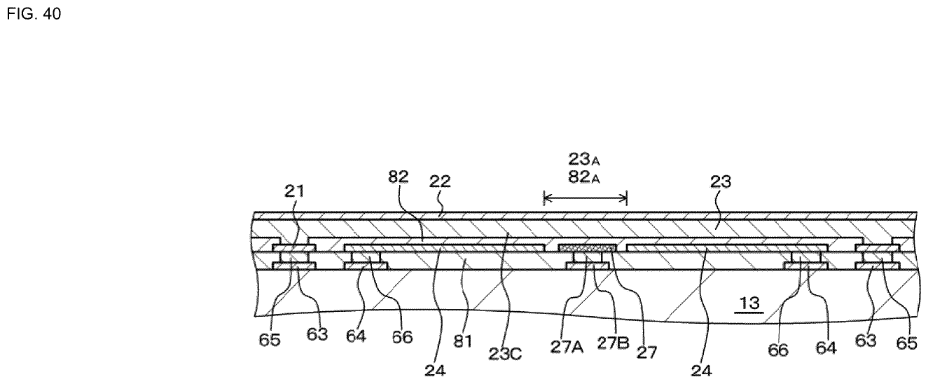

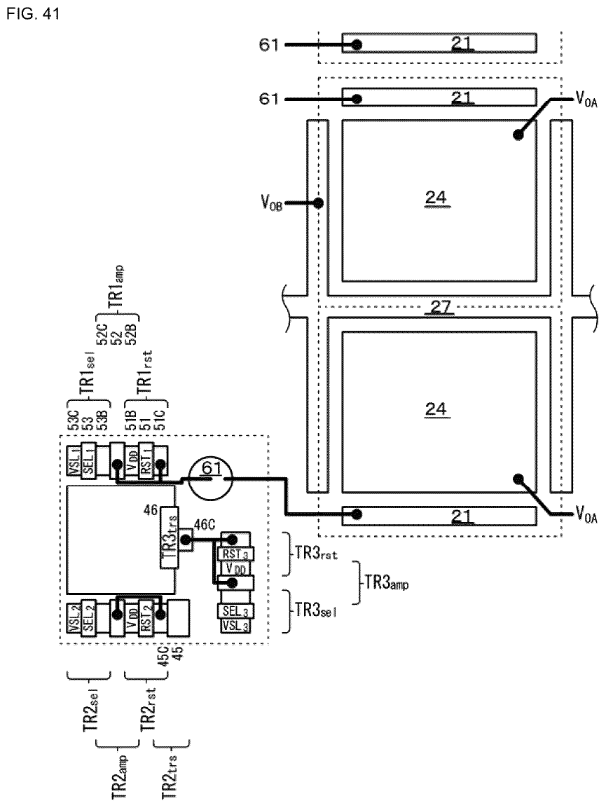

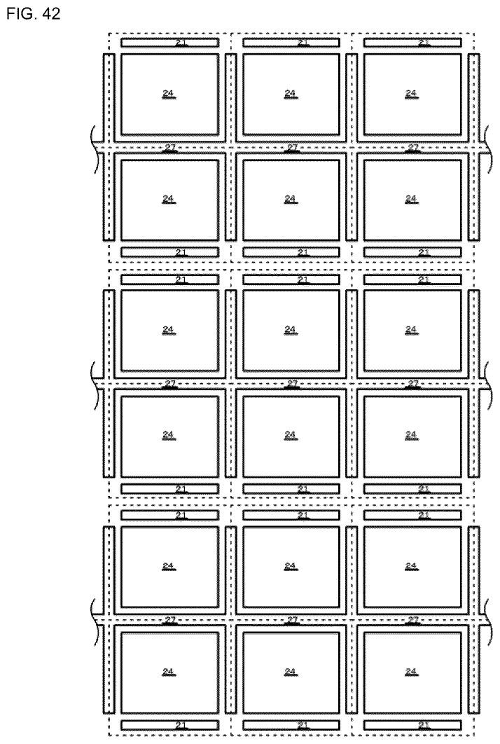

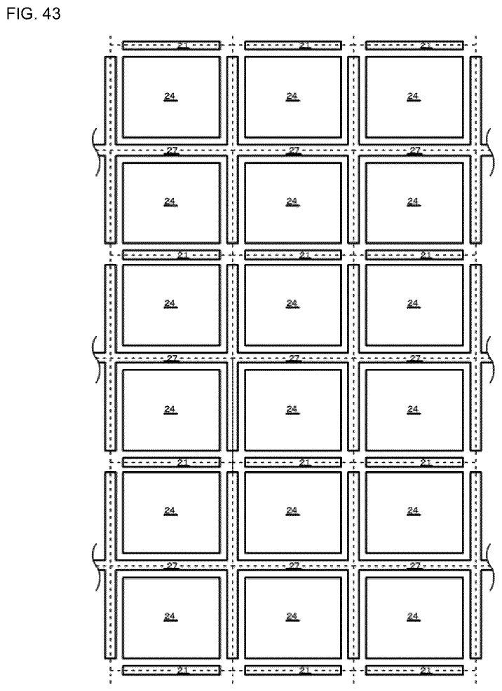

Example 9 is a modification of Examples 3 to 8, and relates to an imaging element including the electric charge movement control electrode of the present disclosure, specifically, an imaging element including the lower electric charge movement control electrode (lower side/electric charge movement control electrode) of the present disclosure. FIG. 40 illustrates a schematic partial cross-sectional view of a portion of an imaging element of Example 9. FIG. 41 is a schematic layout diagram of the first electrode, the electric charge accumulation electrode and the like, and the transistors included in the control section that are included in the imaging element of Example 9. FIGS. 42 and 43 illustrate schematic layout diagrams of the first electrode, the electric charge accumulation electrode, and the lower electric charge movement control electrode included in the photoelectric conversion section including the electric charge accumulation electrode of the imaging element of Example 9.

In the imaging element of Example 9, a lower electric charge movement control electrode 27 is formed in a region opposed to a region (region-A of the photoelectric conversion layer) 23_{A} of the photoelectric conversion layer 23 positioned between adjacent imaging elements, with the insulating layer 82 interposed therebetween. In other words, the lower electric charge movement control electrode 27 is formed below a portion 82_{A} of the insulating layer 82 (region-A of the insulating layer 82) in a region (region-a) sandwiched between the electric charge accumulation electrode 24 and the electric charge accumulation electrode 24 that are included in respective adjacent imaging elements. The lower electric charge movement control electrode 27 is provided at a distance from the electric charge accumulation electrodes 24. Or in other words, the lower electric charge movement control electrode 27 surrounds the electric charge accumulation electrodes 24 and is provided at a distance from the electric charge accumulation electrodes 24, and the lower electric charge movement control electrode 27 is disposed to be opposed to the region-A (23_{A}) of the photoelectric conversion layer with the insulating layer 82 interposed therebetween. The lower electric charge movement control electrode 27 is shared by the imaging elements. In addition, the lower electric charge movement control electrode 27 is also coupled to the drive circuit. Specifically, the lower electric charge movement control electrode 27 is coupled to the vertical drive circuit 112 included in the drive circuit, via a connection hole 27A, a pad section 27B, and a wiring line VOB provided in the interlayer insulating layer 81. The lower electric charge movement control electrode 27 may be formed at the same level as the first electrode 21 or the electric charge accumulation electrode 24, or may be formed at a different level (specifically, a level below the first electrode 21 or the electric charge accumulation electrode 24). In the former case, it is possible to shorten the distance between the electric charge movement control electrode 27 and the photoelectric conversion layer 23, and this makes it easy to control the potential. In contrast, in the latter case, it is possible to shorten the distance between the electric charge movement control electrode 27 and the electric charge accumulation electrode 24, and this is advantageous in achieving miniaturization.

In the imaging element of Example 9, when light enters the photoelectric conversion layer 23 to cause photoelectric conversion in the photoelectric conversion layer 23, the absolute value of the potential applied to a portion of the photoelectric conversion layer 23 opposed to the electric charge accumulation electrode 24 is larger than the absolute value of the potential applied to the region-A of the photoelectric conversion layer 23, and therefore, electric charge generated by the photoelectric conversion is strongly attracted to a region of the photoelectric conversion layer 23 opposed to the electric charge accumulation electrode 24. As a result, it is possible to hinder the electric charge generated by the photoelectric conversion from flowing into an adjacent imaging element. Therefore, no quality degradation occurs in a captured picture (image). Alternatively, owing to the lower electric charge movement control electrode 27 formed in a region opposed to the region-A of the photoelectric conversion layer 23 with the insulating layer interposed therebetween, it is possible to control an electric field or potential in the region-A of the photoelectric conversion layer 23 positioned above the lower electric charge movement control electrode 27. As a result, the lower electric charge movement control electrode 27 makes it possible to hinder the electric charge generated by the photoelectric conversion from flowing into the adjacent imaging element. Therefore, no quality degradation occurs in a captured picture (image).

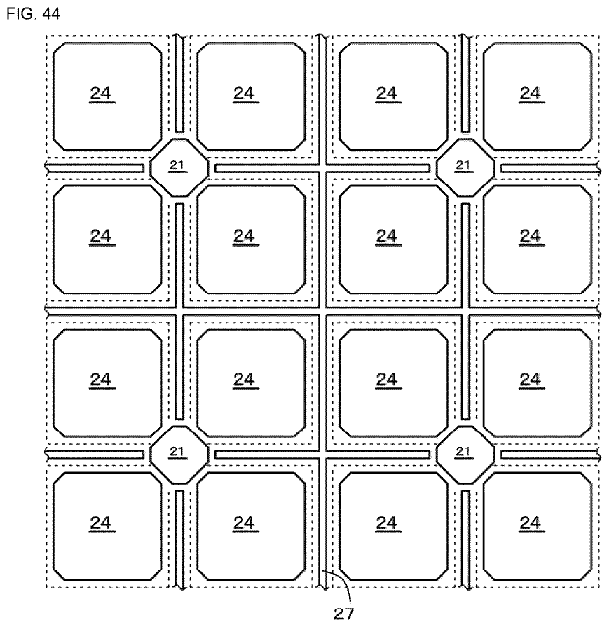

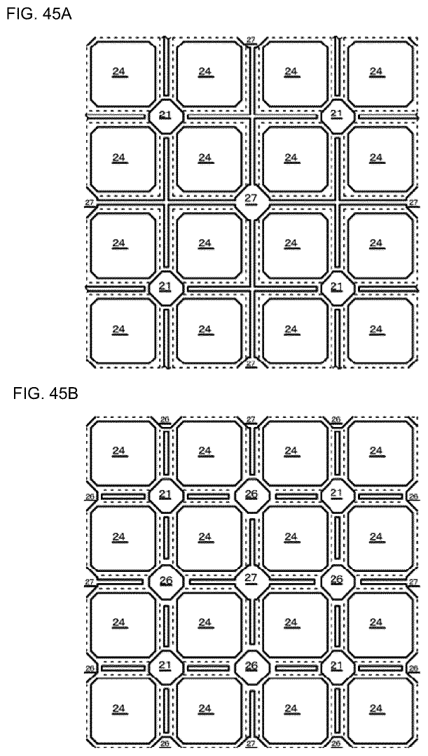

In the examples illustrated in FIGS. 42 and 43, the lower electric charge movement control electrode 27 is formed below the portion 82_{A} of the insulating layer 82 in the region (region-a) sandwiched between the electric charge accumulation electrode 24 and the electric charge accumulation electrode 24. Meanwhile, in the examples illustrated in FIGS. 44, 45A and 45B, the lower electric charge movement control electrode 27 is formed below a portion of the insulating layer 82 in a region surrounded by four electric charge accumulation electrodes 24. It is to be noted that the examples illustrated in FIGS. 44, 45A, and 45B are also the imaging devices of the first and second configurations. In four imaging elements, one common first electrode 21 is provided to correspond to the four electric charge accumulation electrodes 24.

In the example illustrated in FIG. 45B, in the four imaging elements, the one common first electrode 21 is provided to correspond to the four electric charge accumulation electrodes 24, and the lower electric charge movement control electrode 27 is formed below a portion of the insulating layer 82 in the region surrounded by the four electric charge accumulation electrodes 24. Further, the electric charge drain electrode 26 is formed below the portion of the insulating layer 82 in the region surrounded by the four electric charge accumulation electrodes 24. As described above, the electric charge drain electrode 26 is usable as a floating diffusion or overflow drain of the photoelectric conversion section, for example.

### Example 10

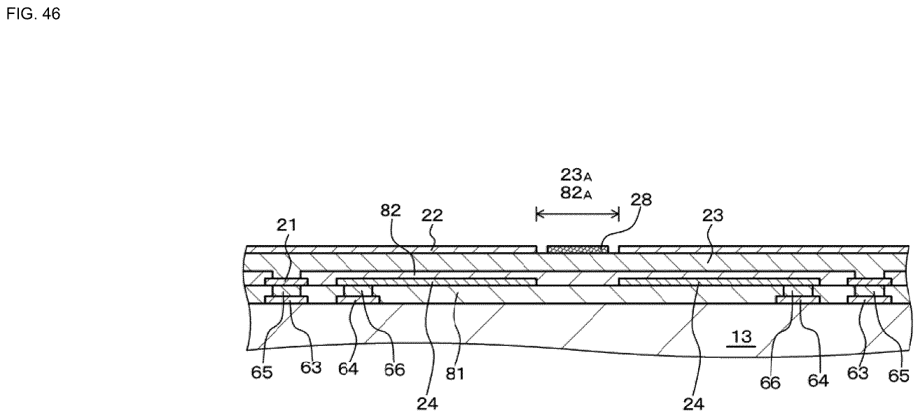

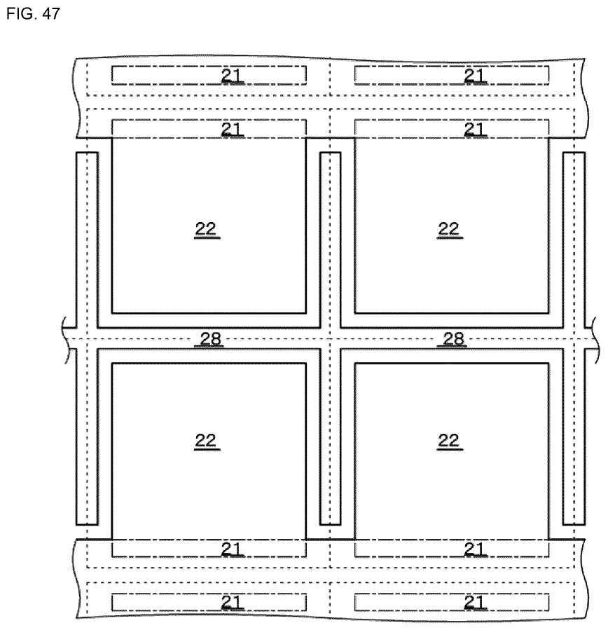

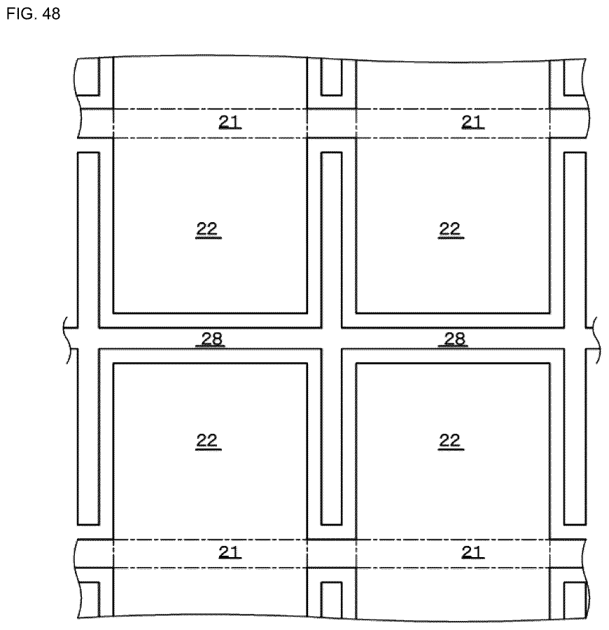

Example 10 is a modification of Example 9, and relates to an imaging element including the upper electric charge movement control electrode (upper side/electric charge movement control electrode) of the present disclosure. FIG. 46 illustrates a schematic cross-sectional view of a portion of an imaging element of Example 10 (two imaging elements arranged side by side). FIGS. 47 and 48 are schematic plan views of a portion of the imaging element of Example 10 (2×2 imaging elements arranged side by side). In the imaging element of Example 10, an upper electric charge movement control electrode 28 is formed, instead of the second electrode 22, on a region 23_{A} of the photoelectric conversion stack 23 positioned between adjacent imaging elements. The upper electric charge movement control electrode 28 is provided at a distance from the second electrode 22. In other words, the second electrode 22 is provided for each imaging element, and the upper electric charge movement control electrode 28 surrounds at least a portion of the second electrode 22 and is provided, at a distance from the second electrode 22, on the region-A of the photoelectric conversion layer 23. The upper electric charge movement control electrode 28 is formed at the same level as the second electrode 22.

It is to be noted that, in the example illustrated in FIG. 47, in one imaging element, one electric charge accumulation electrode 24 is provided to correspond to one first electrode 21. Meanwhile, in a modification example illustrated in FIG. 48, in two imaging elements, one common first electrode 21 is provided to correspond to two electric charge accumulation electrodes 24. The schematic cross-sectional view of the portion of the imaging element of Example 10 (two imaging elements arranged side by side) illustrated in FIG. 46 corresponds to FIG. 48.

In addition, FIG. 49A illustrates a schematic cross-sectional view of a portion of the imaging element of Example 10 (two imaging elements arranged side by side). As illustrated, the second electrode 22 may be divided into a plurality of ones, and different potentials may be applied to the divided individual second electrodes 22. Further, as illustrated in FIG. 49B, the upper electric charge movement control electrode 28 may be provided between the second electrode 22 and the second electrode 22 thus divided.

In Example 10, the second electrode 22 positioned on the light incident side is shared by the imaging elements arranged in the lateral direction on the sheet of FIG. 47, and shared by a pair of imaging elements arranged in the up-and-down direction on the sheet of FIG. 47. In addition, the upper electric charge movement control electrode 28 is also shared by the imaging elements arranged in the lateral direction on the sheet of FIG. 47, and shared by a pair of imaging elements arranged in the up-and-down direction on the sheet of FIG. 47. The second electrode 22 and the upper electric charge movement control electrode 28 are obtainable by forming a material layer to configure the second electrode 22 and the upper electric charge movement control electrode 28 on the photoelectric conversion layer 23 and thereafter patterning the material layer. The second electrode 22 and the upper electric charge movement control electrode 28 are coupled to respective wiring lines (not illustrated) independently of each other, and these wiring lines are coupled to the drive circuit. The wiring line coupled to the second electrode 22 is shared by a plurality of imaging elements. The wiring line coupled to the upper electric charge movement control electrode 28 is also shared by a plurality of imaging elements.

In the imaging element of Example 10, during an electric charge accumulation period, from the drive circuit, the potential V₂₁ is applied to the second electrode 22, the potential V₄₁ is applied to the upper electric charge movement control electrode 28, and electric charge is accumulated in the photoelectric conversion layer 23. During an electric charge transfer period, from the drive circuit, the potential V₂₂ is applied to the second electrode 22, the potential V₄₂ is applied to the upper electric charge movement control electrode 28, and the electric charge accumulated in the photoelectric conversion stack 23 is read out to the control section via the first electrode 21. Here, the potential of the first electrode 21 is higher than the potential of the second electrode 22, and therefore,
V₂₁≥V₄₁ and V₂₂≥V₄₂
hold true.

As described above, in the imaging element of Example 10, the electric charge movement control electrode is formed, instead of the second electrode, on the region of the photoelectric conversion layer positioned between adjacent imaging elements. The electric charge movement control electrode thus makes it possible to hinder the electric charge generated by photoelectric conversion from flowing into the adjacent imaging element, and therefore no quality degradation occurs in a captured picture (image).

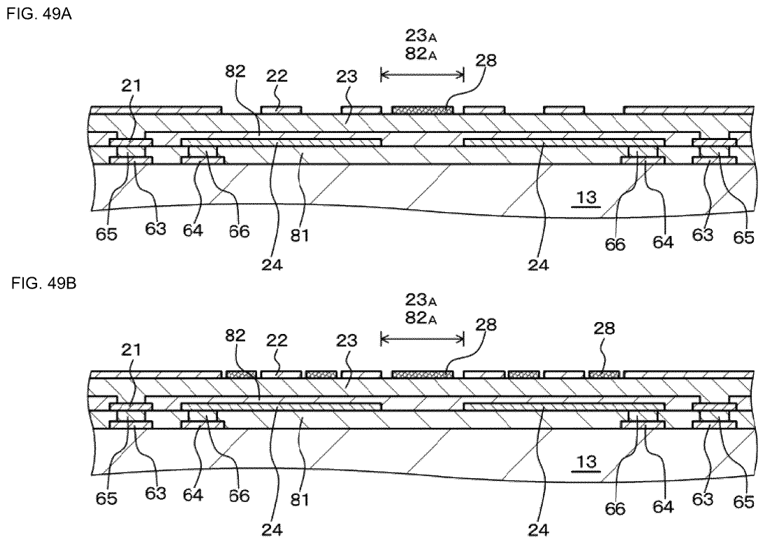

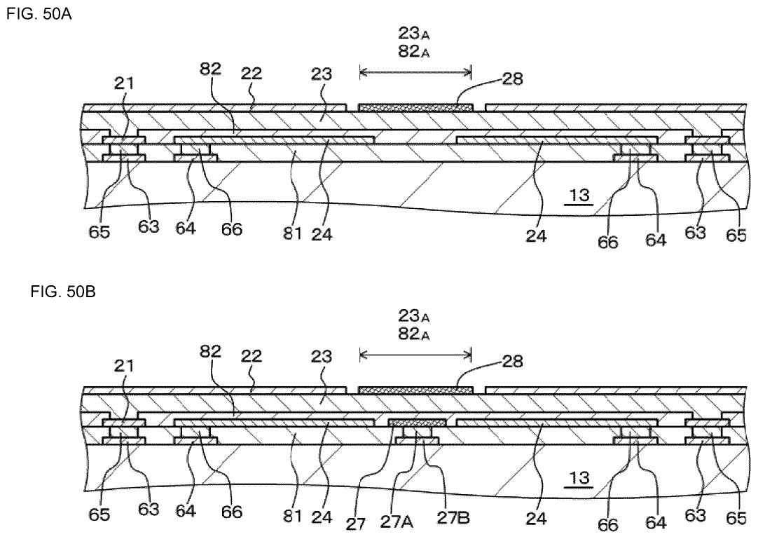

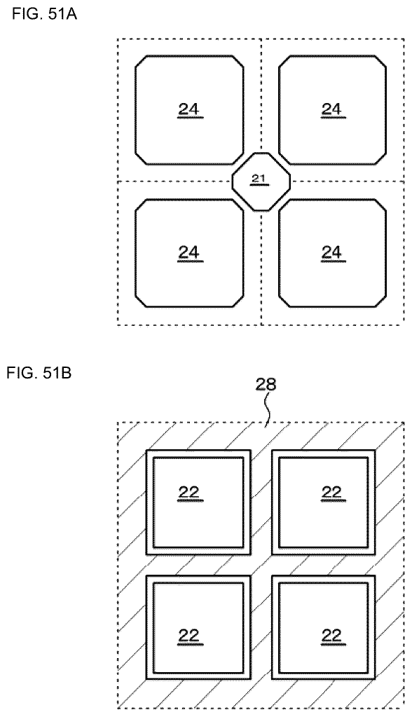

FIG. 50A illustrates a schematic cross-sectional view of a portion of a modification example of the imaging element of Example 10 (two imaging elements arranged side by side), and FIGS. 51A and 51B are schematic plan views of the portion. In this modification example, the second electrode 22 is provided for each imaging element, the upper electric charge movement control electrode 28 surrounds at least a portion of the second electrode 22 and is provided at a distance from the second electrode 22, and a portion of the electric charge accumulation electrode 24 is present below the upper electric charge movement control electrode 28. The second electrode 22 is provided, above the electric charge accumulation electrode 24, in a size smaller than that of the electric charge accumulation electrode 24.

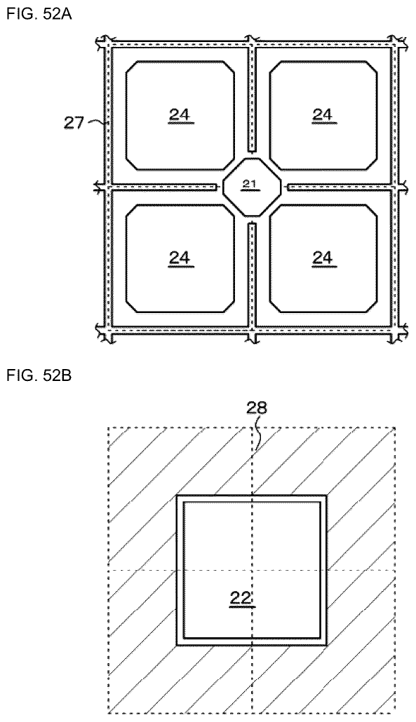

FIG. 50B illustrates a schematic cross-sectional view of a portion of a modification example of the imaging element of Example 10 (two imaging elements arranged side by side), and FIGS. 52A and 52B illustrate schematic plan views of the portion. In this modification example, the second electrode 22 is provided for each imaging element, the upper electric charge movement control electrode 28 surrounds at least a portion of the second electrode 22 and is provided at a distance from the second electrode 22, a portion of the electric charge accumulation electrode 24 is present below the upper electric charge movement control electrode 28, and furthermore, the lower electric charge movement control electrode (lower side/electric charge movement control electrode) 27 is provided below the upper electric charge movement control electrode (upper side/electric charge movement control electrode) 28. The size of the second electrode 22 is smaller than that in the modification example illustrated in FIG. 50A. That is, the region of the second electrode 22 opposed to the upper electric charge movement control electrode 28 is positioned closer to the first electrode 21 than the region of the second electrode 22 opposed to the upper electric charge movement control electrode 28 in the modification example illustrated in FIG. 50A. The electric charge accumulation electrode 24 is surrounded by the lower electric charge movement control electrode 27.

### Example 11

Example 11 is a modification of Examples 3 to 10, and relates to a first electrode sharing imaging device.

An imaging device of Example 11 includes
a photoelectric conversion section including the first electrode 21, the photoelectric conversion layer 23, and the second electrode 22 that are stacked, in which
the photoelectric conversion section further includes a plurality of imaging elements each including the electric charge accumulation electrode 24 disposed at a distance from the first electrode 21 and disposed to be opposed to the photoelectric conversion layer 23 with the insulating layer 82 interposed therebetween,
the plurality of imaging elements constitute an imaging element block, and
the first electrode 21 is shared by the plurality of imaging elements constituting the imaging element block.

Alternatively, the imaging element of Example 11 includes a plurality of imaging elements described in Examples 3 to 10.

In Example 11, one floating diffusion layer is provided for the plurality of imaging elements. Then, appropriately controlling the timing of the electric charge transfer period makes it possible for the plurality of imaging elements to share the one floating diffusion layer. Then, in this case, it is possible for the plurality of imaging elements to share one contact hole section.

It is to be noted that the imaging device of Example 11 has a configuration and a structure substantially similar to those of the imaging devices described in Examples 3 to 10, except that the first electrode 21 is shared by the plurality of imaging elements constituting the imaging element block.

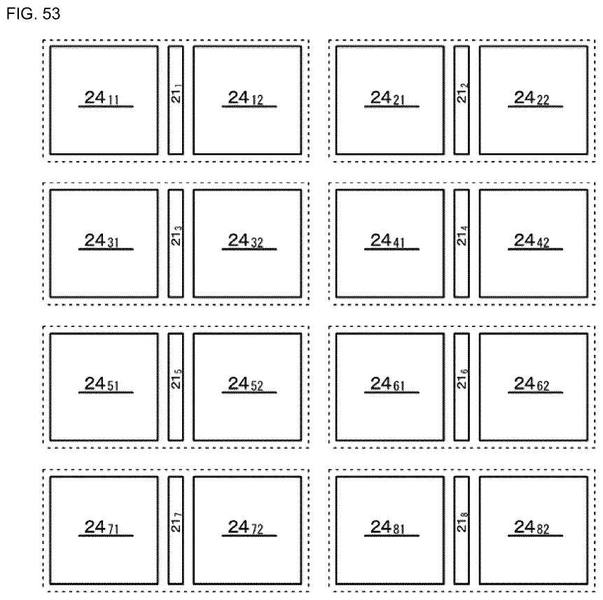

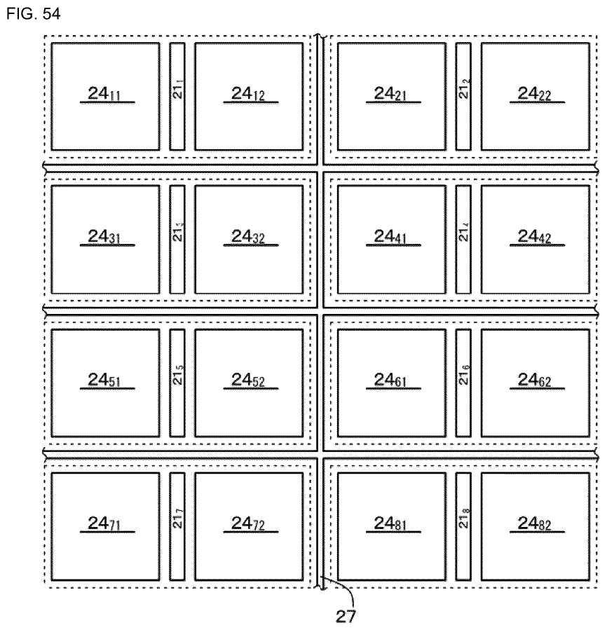

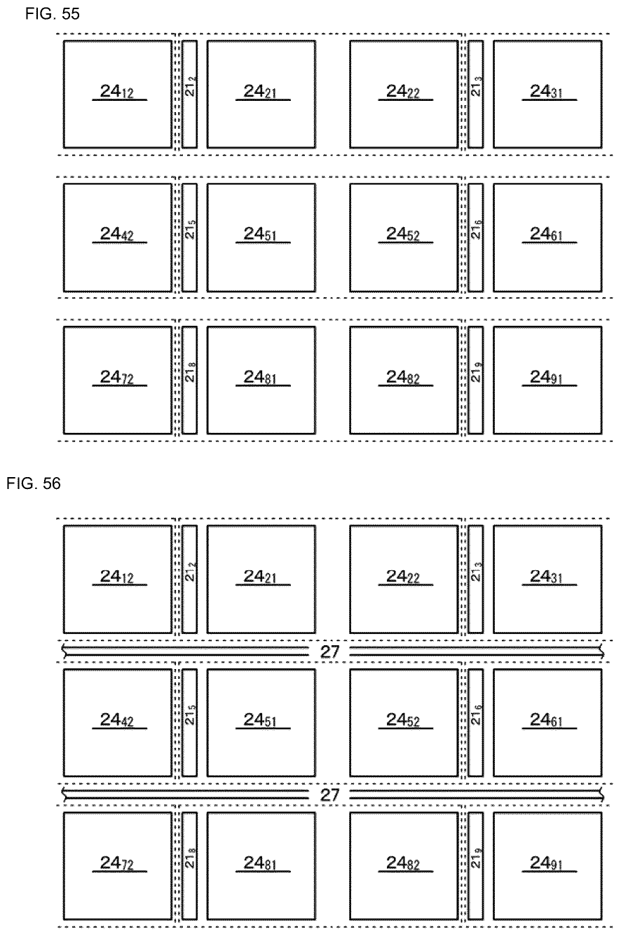

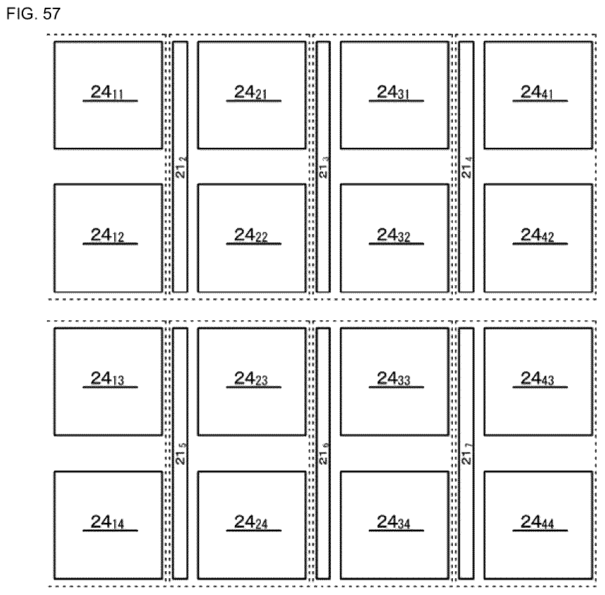

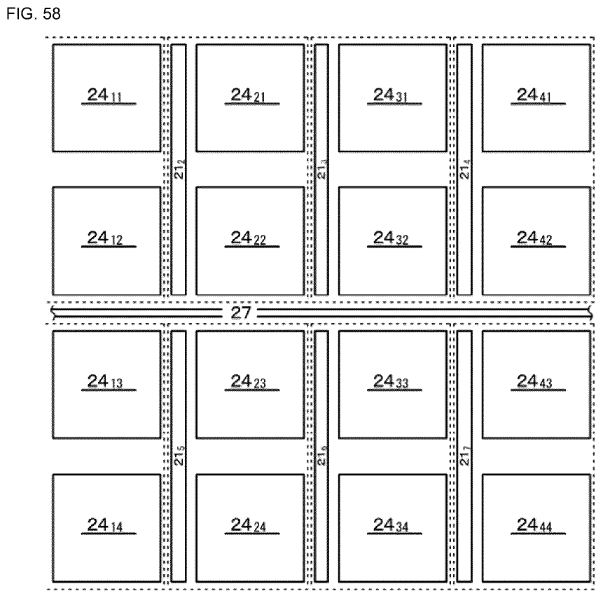

The states of arrangement of the first electrode 21 and the electric charge accumulation electrode 24 in the imaging device of Example 11 are schematically illustrated in FIG. 53 (Example 11), FIG. 54 (a first modification example of Example 11), FIG. 55 (a second modification example of Example 11), FIG. 56 (a third modification example of Example 11), and FIG. 57 (a fourth modification example of Example 11). FIGS. 53, 54, 57, and 58 illustrate sixteen imaging elements, and FIGS. 55 and 56 illustrate twelve imaging elements. Then, the imaging element block is constituted of two imaging elements. The imaging element block is indicated by enclosing with dotted lines. Subscripts attached to the first electrodes 21 and the electric charge accumulation electrodes 24 are for distinguishing individual first electrodes 21 and individual electric charge accumulation electrodes 24. The same applies also to the following description. In addition, one on-chip microlens (not illustrated in FIGS. 53 to 60) is disposed above one imaging element. Then, in one imaging element block, two electric charge accumulation electrodes 24 are disposed with the first electrode 21 interposed therebetween (see FIGS. 53 and 54). Alternatively, one first electrode 21 is disposed to be opposed to two electric charge accumulation electrodes 24 arranged side by side (see FIGS. 57 and 58). That is, the first electrode is disposed to be adjacent to the electric charge accumulation electrode of each imaging element. Alternatively, the first electrode is disposed to be adjacent to some of the electric charge accumulation electrodes of the plurality of imaging elements and not disposed to be adjacent to the rest of the electric charge accumulation electrodes of the plurality of imaging elements (see FIGS. 55 and 56), in which case the movement of electric charge from the rest of the plurality of imaging elements to the first electrode is a movement via some of the plurality of imaging elements. To ensure movement of electric charge from each imaging element to the first electrode, it is preferred that a distance A between an electric charge accumulation electrode included in an imaging element and an electric charge accumulation electrode included in an imaging element be longer than a distance B between the first electrode and the electric charge accumulation electrode in an imaging element adjacent to the first electrode. In addition, it is preferred that the value of the distance A be larger for the imaging element positioned farther from the first electrode. In addition, in the examples illustrated in FIGS. 54, 56, and 58, the electric charge movement control electrode 27 is disposed between a plurality of imaging elements constituting the imaging element block. By disposing the electric charge movement control electrode 27, it is possible to suppress, with reliability, the movement of electric charge in the imaging element blocks positioned with the electric charge movement control electrode 27 interposed therebetween. It is to be noted that it is sufficient that V₃₁>V17 holds true, where V17 denotes a potential to be applied to the electric charge movement control electrode 27.

The electric charge movement control electrode 27 may be formed at the same level as the first electrode 21 or the electric charge accumulation electrode 24, or may be formed at a different level (specifically, a level below the first electrode 21 or the electric charge accumulation electrode 24). In the former case, it is possible to shorten the distance between the electric charge movement control electrode 27 and the photoelectric conversion layer, and this makes it easy to control the potential. In contrast, in the latter case, it is possible to shorten the distance between the electric charge movement control electrode 27 and the electric charge accumulation electrode 24, and this is advantageous in achieving miniaturization.

In the following, description is given of an operation of the imaging element block including a first electrode 21₂ and two electric charge accumulation electrodes 24₂₁ and 24₂₂.

During an electric charge accumulation period, from the drive circuit, the potential V₁₁ is applied to the first electrode 21₂ and the potential V₃₁ is applied to the electric charge accumulation electrodes 24₂₁ and 24₂₂. Light having entered the photoelectric conversion layer 23 causes photoelectric conversion in the photoelectric conversion layer 23. Holes generated by the photoelectric conversion are sent from the second electrode 22 to the drive circuit via the wiring line Vou. Meanwhile, the potential V₁₁ of the first electrode 21₂ is higher than the potential V₂₁ of the second electrode 22, i.e., for example, a positive potential is to be applied to the first electrode 21₂ and a negative potential is to be applied to the second electrode 22. Thus, V₃₁≥V₁₁ holds true, and preferably, V₃₁>V₁₁ holds true. This causes electrons generated by the photoelectric conversion to be attracted to the electric charge accumulation electrodes 2421 and 2422, and to remain in regions of the photoelectric conversion layer 23 opposed to the electric charge accumulation electrodes 24₂₁ and 24₂₂. That is, electric charge is accumulated in the photoelectric conversion layer 23. Because V₃₁≥V₁₁ holds true, the electrons generated inside of the photoelectric conversion layer 23 would not move toward the first electrode 21₂. With the passage of time of photoelectric conversion, the potentials in regions of the photoelectric conversion layer 23 opposed to the electric charge accumulation electrodes 24₂₁ and 24₂₂ have more negative values.

A reset operation is performed later in the electric charge accumulation period. This resets the potential of the first floating diffusion layer, and the potential of the first floating diffusion layer shifts to the potential V_{DD} of the power supply.

After completion of the reset operation, the electric charge is read out. That is, during an electric charge transfer period, from the drive circuit, the potential V₂₁ is applied to the first electrode 21₂, a potential V_{32-A} is applied to the electric charge accumulation electrode 24₂₁, and a potential V_{32-B} is applied to the electric charge accumulation electrode 24₂₂. Here, V_{32-A}<V₂₁<V_{32-B} holds true. This causes the electrons remaining in the region of the photoelectric conversion layer 23 opposed to the electric charge accumulation electrode 24₂₁ to be read out to the first electrode 21₂, and further to the first floating diffusion layer. That is, the electric charge accumulated in the region of the photoelectric conversion layer 23 opposed to the electric charge accumulation electrode 24₂₁ is read out to the control section. Once the reading has been completed, V_{32-B}<V_{32-A}<V₂₁ holds true. It is to be noted that, in the examples illustrated in FIGS. 57 and 58, V_{32-B}<V₂₁<V_{32-A} may hold true. This causes the electrons remaining in the region of the photoelectric conversion layer 23 opposed to the electric charge accumulation electrode 24₂₂ to be read out to the first electrode 21₂, and further to the first floating diffusion layer. In addition, in the examples illustrated in FIGS. 55 and 56, the electrons remaining in the region of the photoelectric conversion layer 23 opposed to the electric charge accumulation electrode 24₂₂ may be read out to the first floating diffusion layer via a first electrode 213 to which the electric charge accumulation electrode 24₂₂ is adjacent. In this way, the electric charge accumulated in the region of the photoelectric conversion layer 23 opposed to the electric charge accumulation electrode 24₂₂ is read out to the control section. It is to be noted that, once the reading of the electric charge accumulated in the region of the photoelectric conversion layer 23 opposed to the electric charge accumulation electrode 24₂₁ to the control section has been completed, the potential of the first floating diffusion layer may be reset.

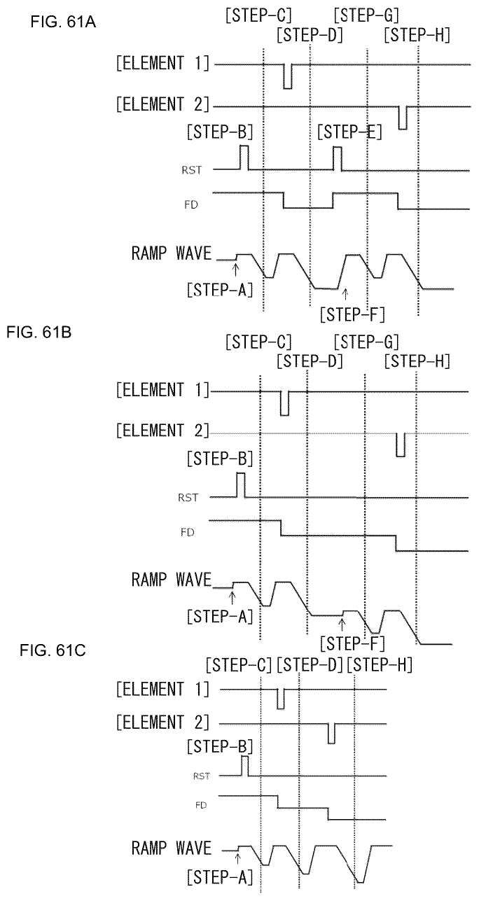

FIG. 61A illustrates an example of reading and driving in the imaging element block of Example 11.

### [Step-A]

Inputting auto zero signal to comparator

### [Step-B]

Reset operation of one shared floating diffusion layer

### [Step-C]

P-phase reading in imaging element corresponding to electric charge accumulation electrode 24₂₁ and movement of electric charge to first electrode 21₂

### [Step-D]

D-phase reading in imaging element corresponding to electric charge accumulation electrode 24₂₁ and movement of electric charge to first electrode 21₂

### [Step-E]

Reset operation of one shared floating diffusion layer

### [Step-F]

Inputting auto zero signal to comparator

### [Step-G]

P-phase reading in imaging element corresponding to electric charge accumulation electrode 24₂₂ and movement of electric charge to first electrode 21₂

### [Step-H]

D-phase reading in imaging element corresponding to electric charge accumulation electrode 24₂₂ and movement of electric charge to first electrode 21₂

In accordance with the above flow, signals from two imaging elements corresponding to the electric charge accumulation electrode 24₂₁ and the electric charge accumulation electrode 24₂₂ are read out. On the basis of a correlated double sampling (CDS) process, a difference between the P-phase reading in [Step-C] and the D-phase reading in [Step-D] is a signal from the imaging element corresponding to the electric charge accumulation electrode 24₂₁, and a difference between the P-phase reading in [Step-G] and the D-phase reading in [Step-H] is a signal from the imaging element corresponding to the electric charge accumulation electrode 24₂₂.

It is to be noted that the operation of [Step-E] may be omitted (see FIG. 61B). In addition, the operation of [Step-F] may be omitted, and in this case, it is possible to further omit [Step-G] (see FIG. 61C); then, a difference between the P-phase reading in [Step-C] and the D-phase reading in [Step-D] is a signal from the imaging element corresponding to the electric charge accumulation electrode 24₂₁, and a difference between the D-phase reading in [Step-D] and the D-phase reading in [Step-H] is a signal from the imaging element corresponding to the electric charge accumulation electrode 24₂₂.

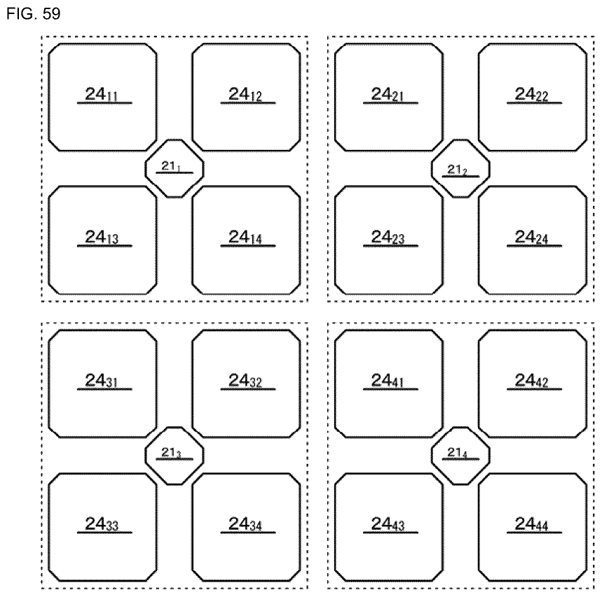

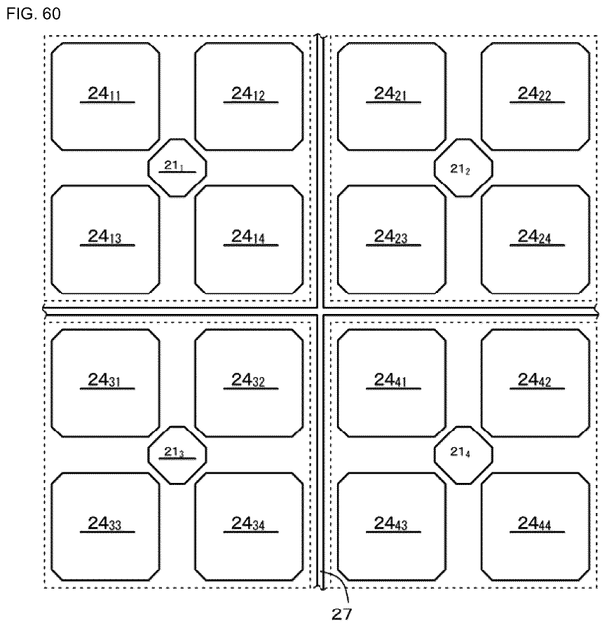

The states of arrangement of the first electrode 21 and the electric charge accumulation electrode 24 in modification examples are schematically illustrated in FIG. 59 (a sixth modification example of Example 11) and FIG. 60 (a seventh modification example of Example 11). In these modification examples, four imaging elements constitute an imaging element block. Operations of these imaging devices may be substantially similar to the operations of the imaging devices illustrated in FIGS. 53 to 58.

In the imaging device of Example 11, the first electrode is shared by a plurality of imaging elements constituting the imaging element block. It is thus possible to simplify and miniaturize the configuration and structure in the pixel region in which a plurality of imaging elements are arranged. It is to be noted that a plurality of imaging elements provided for one floating diffusion layer may be constituted of a plurality of imaging elements of the first type, or may be constituted of at least one imaging element of the first type and one or two or more imaging elements of the second type.

While the description has been given above of the present disclosure on the basis of preferred examples, the present disclosure is not limited to these examples. The structures and configurations, manufacturing conditions, manufacturing methods, and materials used of the imaging elements, the stacked imaging elements, and the imaging devices described in the examples are merely illustrative, and may be modified as appropriate. The imaging elements of the examples may be combined as appropriate. The configuration and structure of the imaging element of the present disclosure are applicable to light emitting elements, e.g., organic EL elements, or channel formation regions of thin-film transistors.

Depending on the case, the floating diffusion layers FD₁, FD₂, FD₃, 51C, 45C, and 46C may also be shared, as has been described.

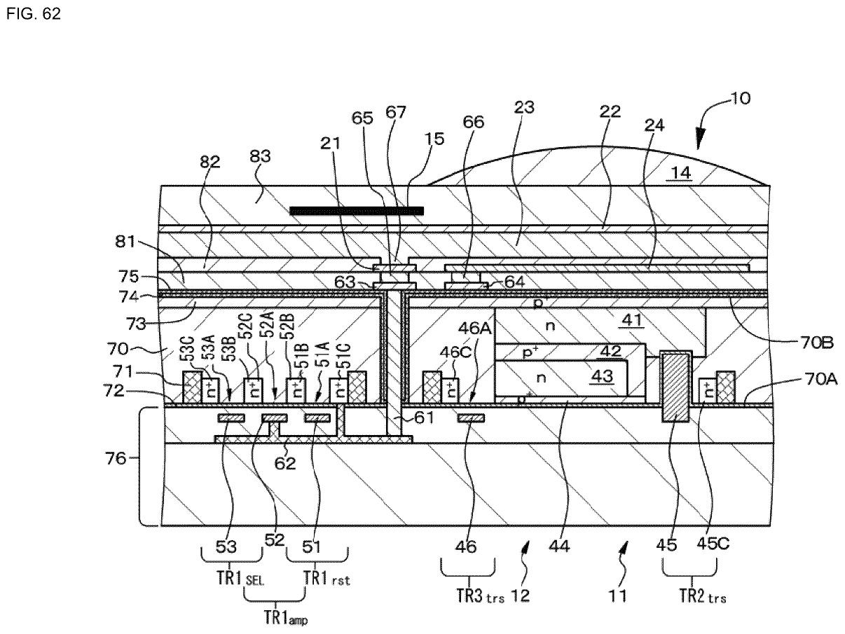

In addition, FIG. 62 illustrates a modification example of the imaging element and the stacked imaging element described in Example 3. As illustrated, for example, a configuration may be adopted in which light enters from side of the second electrode 22 and a light-blocking layer 15 is formed on the light incident side near the second electrode 22. It is to be noted that various wiring lines provided closer to the light incident side than the photoelectric conversion layer may also serve as a light-blocking layer.

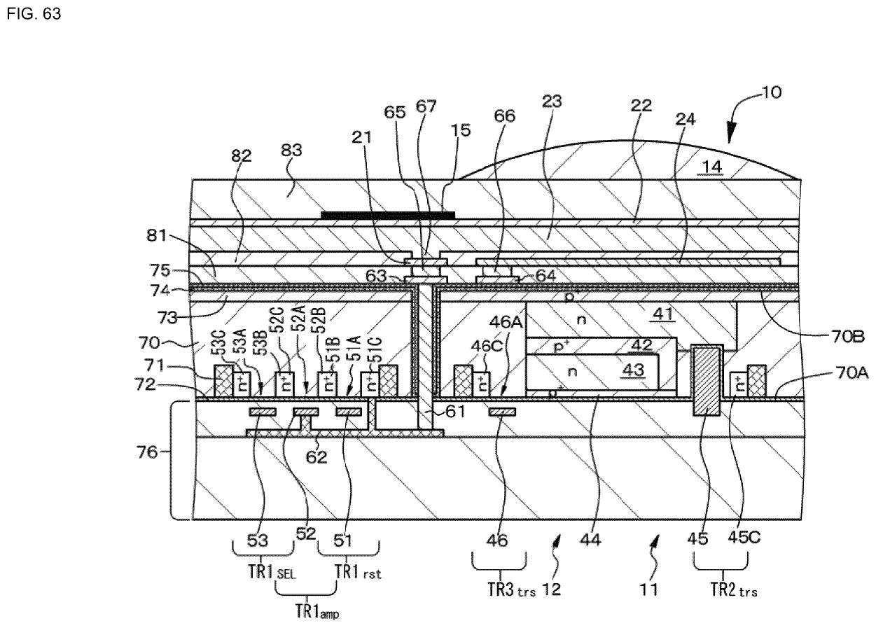

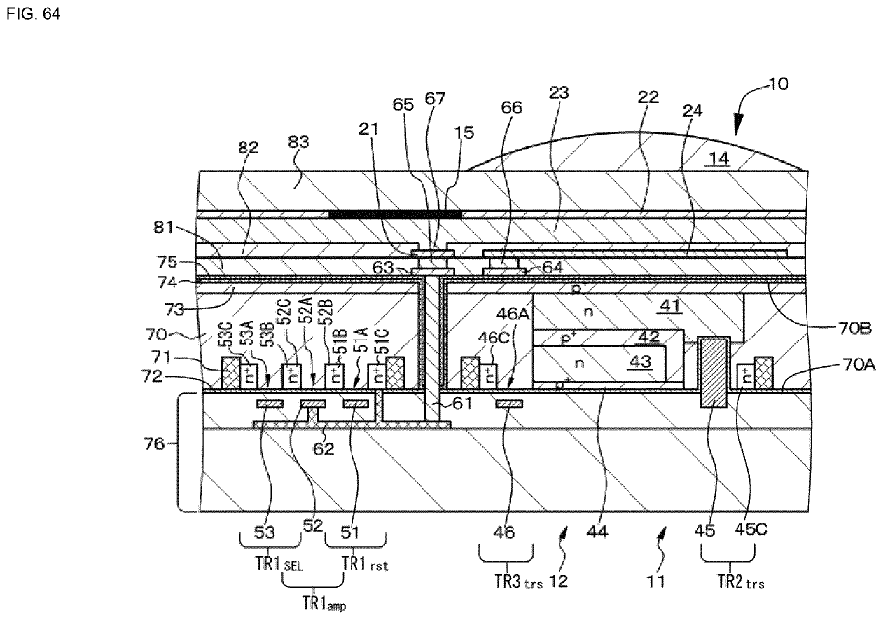

It is to be noted that, in the example illustrated in FIG. 62, the light-blocking layer 15 is formed above the second electrode 22, i.e., the light-blocking layer 15 is formed on the light incident side near the second electrode 22 and above the first electrode 21; however, as illustrated in FIG. 63, the light-blocking layer 15 may be disposed on a surface of the second electrode 22 on the light incident side. In addition, as illustrated in FIG. 64, the second electrode 22 may be provided with the light-blocking layer 15, depending on the case.

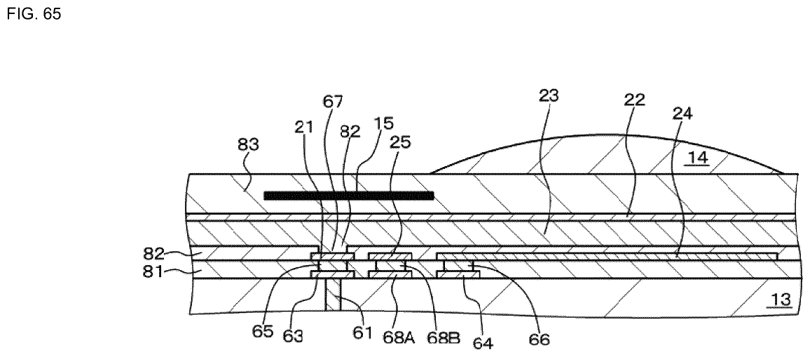

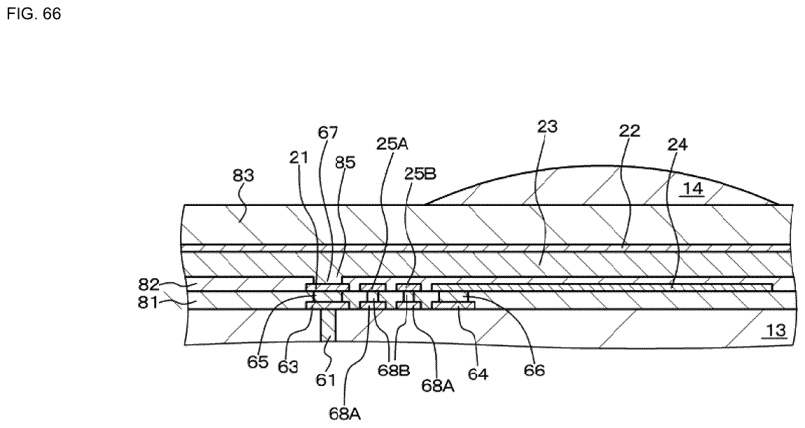

Alternatively, a structure may be adopted in which light enters from the side of the second electrode 22 and no light enters the first electrode 21. Specifically, as illustrated in FIG. 62, the light-blocking layer 15 is formed on the light incident side near the second electrode 22 and above the first electrode 21. Alternatively, a structure may be adopted in which, as illustrated in FIG. 66, the on-chip microlens 14 is provided above the electric charge accumulation electrode 24 and the second electrode 22, and light entering the on-chip microlens 14 is condensed onto the electric charge accumulation electrode 24 and does not reach the first electrode 21. It is to be noted that, as described in Example 6, in the case where the transfer control electrode 25 is provided, a mode may be adopted in which light enters neither of the first electrode 21 and the transfer control electrode 25. Specifically, a structure may be adopted in which, as illustrated in FIG. 65, the light-blocking layer 15 is formed above the first electrode 21 and the transfer control electrode 25. Alternatively, a structure may be adopted in which the light entering the on-chip microlens 14 does not reach the first electrode 21, or reaches neither of the first electrode 21 and the transfer control electrode 25.

By employing these configurations and structures, or by providing the light-blocking layer 15 to allow light to enter only a portion of the photoelectric conversion section positioned above the electric charge accumulation electrode 24, or by designing the on-chip microlens 14, the portion of the photoelectric conversion section positioned above the first electrode 21 (or above the first electrode 21 and the transfer control electrode 25) becomes unable to contribute to photoelectric conversion, and it is thus possible to reset all the pixels all at once with higher reliability, and to achieve the global shutter function more easily. Thus, in a method of driving an imaging device including a plurality of imaging elements having these configurations and structures, the following steps are repeated:
draining, in all of the imaging elements, electric charge in the first electrodes 21 out of the system all at once while accumulating electric charge in the photoelectric conversion layer 23, and thereafter
transferring, in all of the imaging elements, the electric charge accumulated in the photoelectric conversion layer 23 to the first electrodes 21 all at once, and after completion of the transfer, reading out the electric charge transferred to the first electrodes 21 in the respective imaging elements sequentially.

In such a method of driving the imaging device, each imaging element has a structure in which light having entered from the side of the second electrode does not enter the first electrode and, in all of the imaging elements, the electric charge in the first electrodes is drained out of the system all at once while accumulating electric charge in the photoelectric conversion layer. This makes it possible to perform resetting of the first electrodes in all of the imaging elements simultaneously with reliability. Thereafter, in all of the imaging elements, the electric charge accumulated in the photoelectric conversion layer is transferred all at once to the first electrodes, and after completion of the transfer, the electric charge transferred to the first electrodes is read out in the imaging elements sequentially. It is thus possible to easily achieve the so-called global shutter function.

In a case where one inorganic oxide semiconductor material layer shared by a plurality of imaging elements is formed, it is desirable that an end part of the inorganic oxide semiconductor material layer be covered with at least the photoelectric conversion layer 23, from the viewpoint of protection of the end part of the inorganic oxide semiconductor material layer.

In addition, as a modification example of Example 6, as illustrated in FIG. 66, a plurality of transfer control electrodes may be provided from a position closest to the first electrode 21 toward the electric charge accumulation electrode 24. It is to be noted that FIG. 66 illustrates an example in which two transfer control electrodes 25A and 25B are provided. Then, a structure may be adopted in which the on-chip microlens 14 is provided above the electric charge accumulation electrode 24 and the second electrode 22, so that light entering the on-chip microlens 14 is condensed onto the electric charge accumulation electrode 24 and reaches none of the first electrode 21 and the transfer control electrodes 25A and 25B.

The first electrode 21 may be configured to extend in the opening 84 provided in the insulating layer 82 and to be coupled to the photoelectric conversion layer 23.

In addition, in the examples, description has been given with reference to, as an example, a case of application to a CMOS type imaging device in which unit pixels are arranged in matrix for sensing signal electric charge responsive to the amount of incident light as a physical quantity; however, the application to the CMOS type imaging device is not limitative, and application to a CCD type imaging device is also possible. In the latter case, the signal electric charge is transferred in the vertical direction by a vertical transfer register of a CCD type structure, transferred in the horizontal direction by a horizontal transfer register, and then amplified to thereby cause a pixel signal (image signal) to be outputted. In addition, possible applications are not limited to column-system imaging devices in general in which pixels are formed in a two-dimensional matrix pattern and a column signal processing circuit is disposed for each pixel column. Further, depending on the case, the selection transistor may be omitted.

Further, the imaging element and the stacked imaging element of the present disclosure are applicable not only to an imaging device that senses the distribution of incident amount of visible light to capture an image of the distribution, but also to an imaging device that captures an image of the distribution of incident amount of infrared rays, X-rays, particles, or the like. In addition, in a broad sense, the imaging element and the stacked imaging element of the present disclosure are generally applicable to an imaging device (physical quantity distribution sensing device) that senses the distribution of other physical quantities, including pressure and capacitance, to capture an image of the distribution, such as a fingerprint detection sensor.

Further, possible applications are not limited to an imaging device that sequentially scans unit pixels in an imaging region row by row and reads out pixel signals from the unit pixels. Application to an X-Y address type imaging device is also possible that selects any pixel on a per-pixel basis and reads out a pixel signal from the selected pixel on a per-pixel basis. The imaging device may be formed in a one-chip form or may be in a modular form with an imaging function in which the imaging region and the drive circuit or the optical system are packaged together.

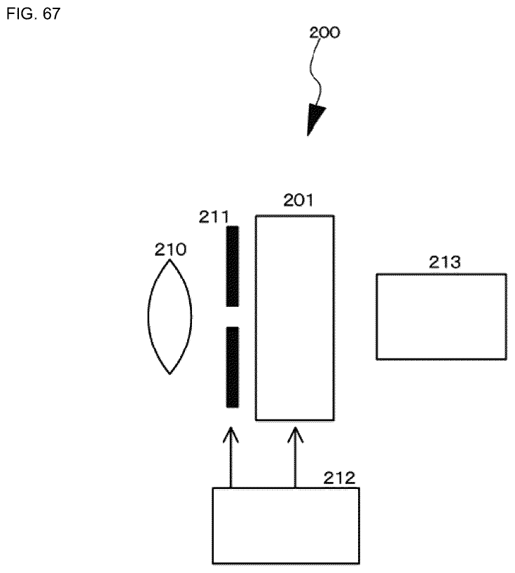

FIG. 67 illustrates, as a conceptual diagram, an example of using an imaging device 201 including the imaging element and the stacked imaging element of the present disclosure in an electronic apparatus (camera) 200. The electronic apparatus 200 includes the imaging device 201, an optical lens 210, a shutter device 211, a drive circuit 212, and a signal processing circuit 213. The optical lens 210 focuses image light (incident light) from a subject to form an image on an imaging plane of the imaging device 201. This causes signal electric charge to be accumulated in the imaging device 201 for a predetermined period of time. The shutter device 211 controls a period during which the imaging device 201 is to be irradiated with light and a period during which the light is to be blocked. The drive circuit 212 supplies drive signals for controlling a transfer operation, etc. of the imaging device 201 and a shutter operation of the shutter device 211. Signal transfer in the imaging device 201 is performed in accordance with the drive signals (timing signals) supplied from the drive circuit 212. The signal processing circuit 213 performs various kinds of signal processing. An image signal having undergone the signal processing is stored in a storage medium such as a memory, or is outputted to a monitor. In such an electronic apparatus 200, the imaging device 201 is able to achieve miniaturization of pixel size and improvement in transfer efficiency, thus making it possible to provide the electronic apparatus 200 with improved pixel characteristics. Examples of the electronic apparatus 200 to which the imaging device 201 is applicable are not limited to a camera, but includes a digital still camera, a camera module for a mobile apparatus such as a mobile phone, and other imaging devices.

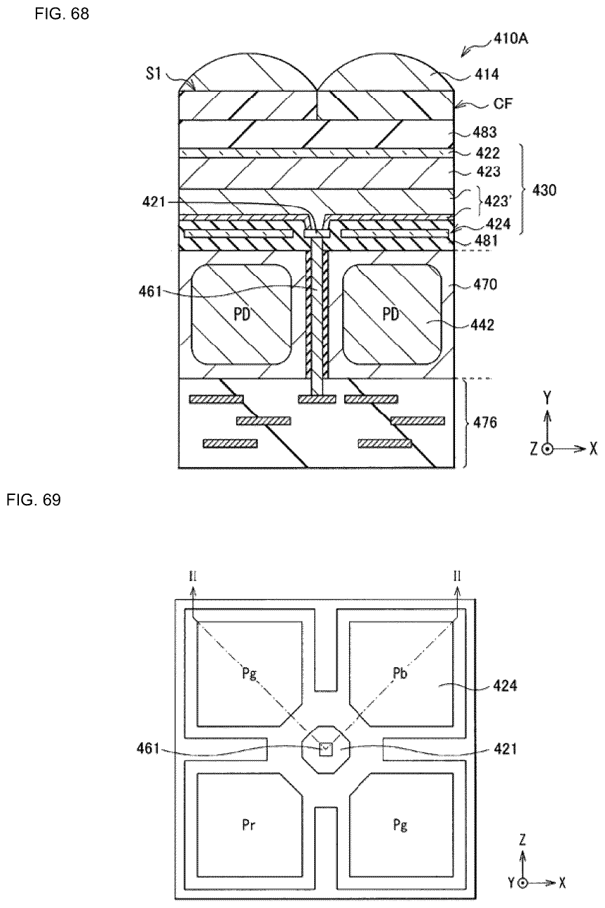

FIG. 68 illustrates a schematic partial cross-sectional view of a modification example (imaging element 410A) of the imaging element of the present disclosure. In addition, FIG. 69 schematically illustrates an example of a planar configuration of the imaging element 410A illustrated in FIG. 68. It is to be noted that FIG. 68 illustrates a cross section taken along a line II-II illustrated in FIG. 69. The imaging element 410A is, for example, a stacked imaging element in which an inorganic photoelectric conversion section 442 and an organic photoelectric conversion section 430 are stacked. In a pixel section of an imaging device including this imaging element 410A, as illustrated in FIG. 69, a pixel unit including four pixels arranged in two rows by two columns is a repetition unit, and the pixel units are repeatedly arranged in an array in a row direction and a column direction.

In the imaging element 410A, a color filter layer CF that selectively transmits red light (R), green light (G), or blue light (B) is provided for each of unit pixels Pᵣ, P_{g}, and P_{b} above the organic photoelectric conversion section 430 (light incident side S1). Specifically, in the pixel unit including four pixels arranged in two rows by two columns, two color filter layers CF that selectively transmit the green light (G) are provided on a diagonal line, and one color filter layer CF that selectively transmits the red light (R) and one color filter layer CF that selectively transmits the blue light (B) are provided on a diagonal line orthogonal to the diagonal line. In each of the unit pixels (Pᵣ, P_{g}, and P_{b}) each provided with the color filter layer CF, for example, light of a corresponding color is detected in the organic photoelectric conversion section 430. That is, in the pixel section, pixels (Pᵣ, P_{g}, and P_{b}) that respectively detect the red light (R) the green light (G), and the blue light (B) are arranged in a Bayer arrangement.

The organic photoelectric conversion section 430 includes, for example, a first electrode 421, an insulating layer 481, an inorganic oxide semiconductor material layer 423′, a photoelectric conversion layer 423, a second electrode 422, and an electric charge accumulation electrode 424. The first electrode 421, the insulating layer 481, the inorganic oxide semiconductor material layer 423′, the photoelectric conversion layer 423, the second electrode 422, and the electric charge accumulation electrode 424 each have a configuration similar to that in the photoelectric conversion section described above. The inorganic photoelectric conversion section 442 detects light in a wavelength range different from that of the organic photoelectric conversion section 430. It is to be noted that reference numeral 414 denotes an on-chip microlens (OCL): reference numeral 483 denotes a protection material layer; reference numeral 461 denotes a contact hole section; reference numeral 470 denotes a semiconductor substrate; and reference numeral 476 denotes an interlayer insulating layer.

In the imaging element 410A, of light having transmitted through the color filter layers CF, light in a visible light region [the red light (R), the green light (G), and the blue light (B)] is absorbed by the organic photoelectric conversion sections 430 of the unit pixels (Pᵣ, P_{g}, and P_{b}) provided with the respective color filter layers CF, and light other than the light in the visible light region, for example, light in an infrared light region (e.g., from 700 nm to 1000 nm both inclusive) [infrared light (IR)] transmits through the organic photoelectric conversion section 430. This infrared light (IR) having transmitted through the organic photoelectric conversion section 430 is detected by the inorganic photoelectric conversion section 442 of each of the unit pixels Pᵣ, P_{g}, and P_{b}, and each of the unit pixels Pᵣ, P_{g}, and Pb generates signal electric charge corresponding to the infrared light (IR). That is, in the imaging device including the imaging element 410A, it is possible to generate both a visible light image and an infrared light image simultaneously.

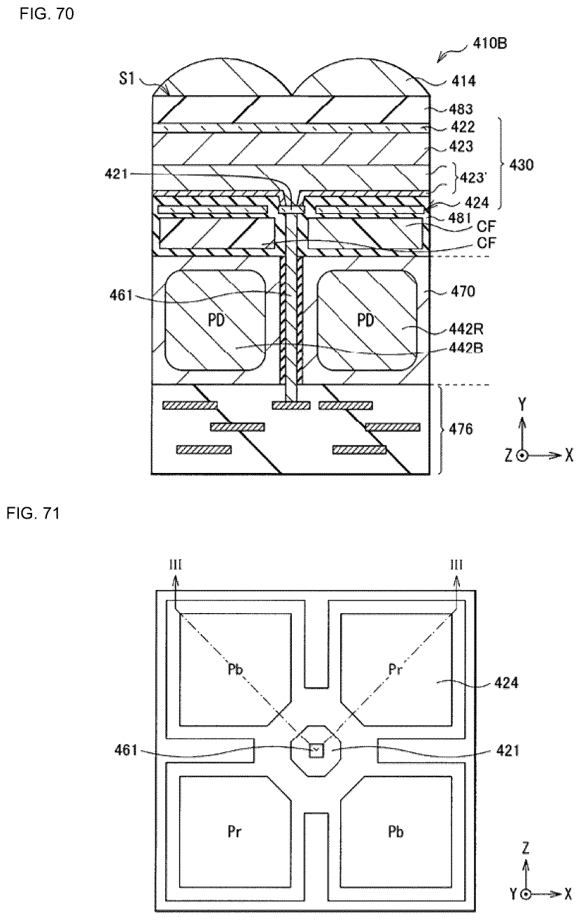

FIG. 70 illustrates a schematic partial cross-sectional view of another modification example (imaging element 410B) of the imaging element of the present disclosure. In addition, FIG. 71 schematically illustrates an example of a planar configuration of the imaging element 410B illustrated in FIG. 70. It is to be noted that FIG. 70 illustrates a cross section taken along a line III-III illustrated in FIG. 71. In the imaging element 410A illustrated in FIG. 68, the color filter layers CF that selectively transmit the red light (R), the green light (G), and the blue light (B) are provided above the organic photoelectric conversion section 430 (light incident side S1); however, in an example illustrated in FIG. 70, the color filter layers CF are provided, for example, between the inorganic photoelectric conversion sections 442R and 442B, and the organic photoelectric conversion section 430.

In the imaging element 410B, for example, the color filter layers CF have a configuration in which the color filter layer CL that selectively transmits at least the red light (R) and the color filter layer CF that selectively transmits at least the blue light (B) are disposed diagonally to each other in the pixel unit. The organic photoelectric conversion section 430 (photoelectric conversion layer 423) is configured to selectively absorb, for example, a wavelength corresponding to green light. This makes it possible to obtain signals corresponding to green light, red light, and blue light in the organic photoelectric conversion section 430, and inorganic photoelectric conversion sections 442R and 442B disposed below the respective color filter layers CF. In the imaging element 410B, it is possible to increase the area of each photoelectric conversion section of the imaging element more than an imaging element having a typical Bayer arrangement, which makes it possible to improve an S/N ratio.

The technology according to the present disclosure (the present technology) is applicable to various products. For example, the technology according to the present disclosure may be implemented as a device to be mounted on any type of mobile body such as an automobile, an electric vehicle, a hybrid electric vehicle, a motorcycle, a bicycle, a personal mobility, an airplane, a drone, a vessel, or a robot.

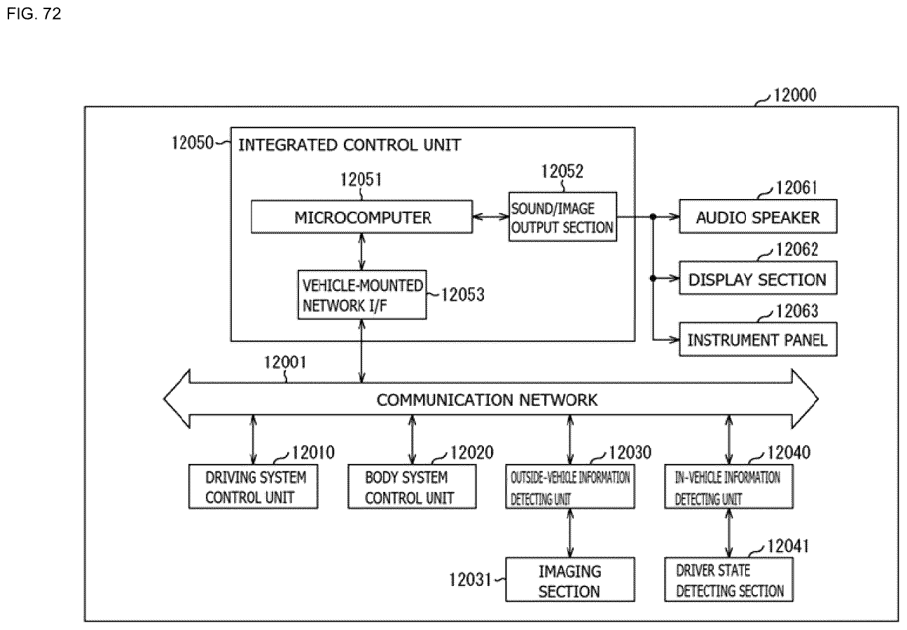

FIG. 72 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 72, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 72, an audio speaker 12061, a display section 12062, and an instrument panel 12063 are illustrated as the output device. The display section 12062 may, for example, include at least one of an on-board display and a head-up display.

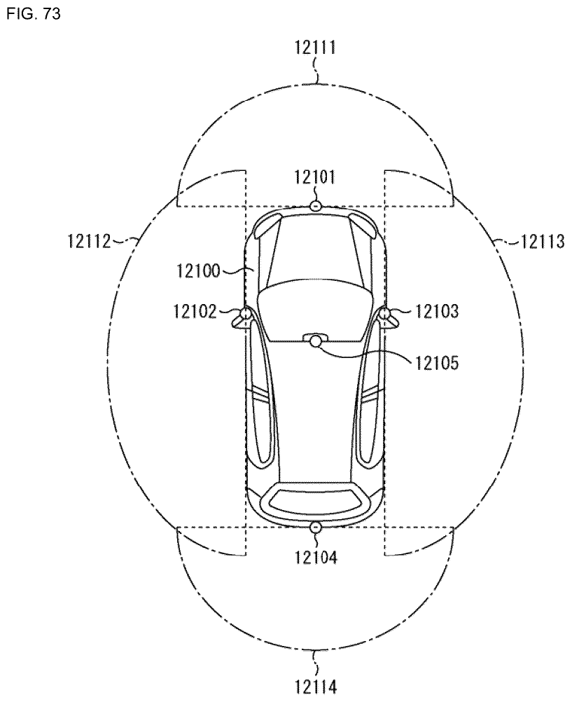

FIG. 73 is a diagram depicting an example of the installation position of the imaging section 12031.

In FIG. 73, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 73 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In addition, for example, the technology according to the present disclosure may be applied to an endoscopic surgery system.

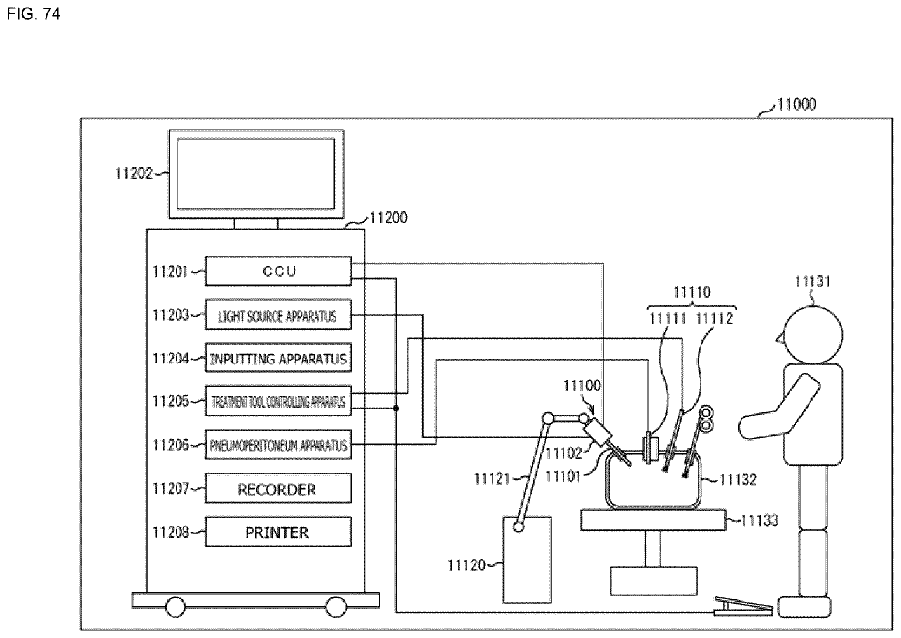

FIG. 74 is a view depicting an example of a schematic configuration of an endoscopic surgery system to which the technology according to an embodiment of the present disclosure (present technology) can be applied.

In FIG. 74, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

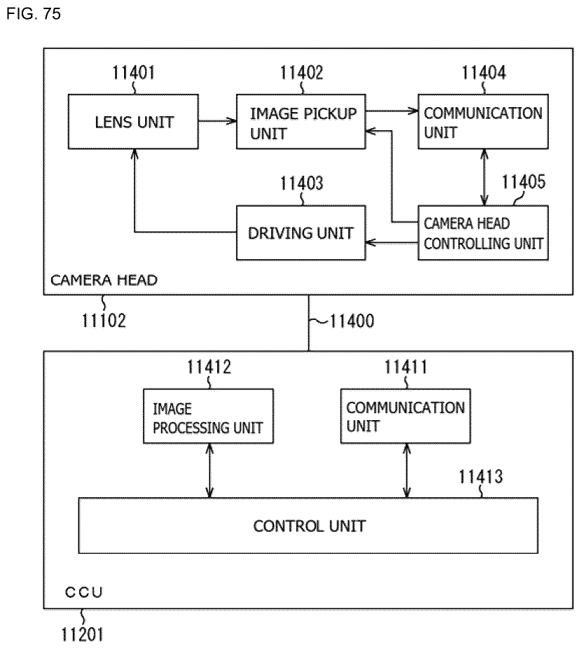

FIG. 75 is a block diagram depicting an example of a functional configuration of the camera head 11102 and the CCU 11201 depicted in FIG. 74.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

It is to be noted that while the description has been given here of the endoscopic surgery system as one example, the technology according to the present disclosure may also be applied to, for example, a micrographic surgery system and the like.

It is to be noted that the present disclosure may also have the following configurations.

### [A01]<<Imaging Element>>

An imaging element including a photoelectric conversion layer including an organic photoelectric conversion material, a hole transporting material, and an electron transporting material, in which the electron transporting material includes a fullerene compound monomer and a fullerene compound dimer.

### [A02]

The imaging element according to [A01], in which mass % of (the fullerene compound monomer+the fullerene compound dimer) in the photoelectric conversion layer is greater than or equal to 13 mass % and less than or equal to 33 mass %.

### [A03]

The imaging element according to [A02], in which a mass ratio of the electron transporting material, and the fullerene compound dimer per unit mass is greater than 0 and less than or equal to 0.4.

### [A04]

The imaging element according to [A03], in which the mass ratio of the electron transporting material, and the fullerene compound dimer per unit mass is greater than or equal to 0.08 and less than 0.30.

### [A05]

The imaging element according to any one of [A02] to [A04], in which a mass ratio of the electron transporting material, and a fullerene compound trimer or a higher-order fullerene compound multimer per unit mass is less than or equal to 0.12.

### [A06]

The imaging element according to any one of [A02] to [A05], in which M_{Di-1}/M_{Di-0}≤100 is satisfied, where M_{Di-0} denotes mass % of the fullerene compound dimer in the photoelectric conversion layer, and M_{Di-1} denotes mass % of the fullerene compound dimer in the photoelectric conversion layer after the photoelectric conversion layer is irradiated with light of a wavelength of 560 nm having an energy of 3.2 mW/cm² for 24 hours.

### [A07]

The imaging element according to any one of [A01] to [A06], in which mass % of the hole transporting material in the photoelectric conversion layer is greater than or equal to 15 mass % and less than or equal to 50 mass %.

### [A08]

The imaging element according to any one of [A01] to [A07], in which
the fullerene compound monomer includes at least one kind of material selected from a group including a C60 monomer, a C60 monomer oxide, a C60 monomer derivative, a C60 monomer derivative oxide, a C70 monomer, a C70 monomer oxide, a C70 monomer derivative, a C70 monomer derivative oxide, a C74 monomer, a C74 monomer oxide, a C74 monomer derivative, and a C74 monomer derivative oxide, and
the fullerene compound dimer includes at least one kind of material selected from a group including a C60 dimer, a C60 dimer oxide, a C60 dimer derivative, a C60 dimer derivative oxide, a C70 dimer, a C70 dimer oxide, a C70 dimer derivative, a C70 dimer derivative oxide, a C74 dimer, a C74 dimer oxide, a C74 dimer derivative, and a C74 dimer derivative oxide.

### [A09]

The imaging element according to [A08], in which
the fullerene compound monomer includes the C60 monomer, and
the fullerene compound dimer includes the C60 dimer.

### [A10]

The imaging element according to any one of [A01] to [A09], further including a first electrode, and a second electrode where light enters, in which
the photoelectric conversion layer is sandwiched between the first electrode and the second electrode.

### [B01] <<Stacked Imaging Element>>

A stacked imaging element including at least one imaging element according to any one of [A01] to [A10] stacked.

### [C01] <<Imaging Device: First Mode>>

An imaging device including a plurality of the imaging elements according to any one of [A01] to [A10].

### [C02] <<Imaging Device: Second Mode>>

An imaging device including a plurality of the stacked imaging elements according to [A11S].

This application claims the priority on the basis of Japanese Patent Application No. 2020-204687 filed on Dec. 10, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. An imaging element comprising a photoelectric conversion layer including an organic photoelectric conversion material, a hole transporting material, and an electron transporting material, wherein
the electron transporting material includes a fullerene compound monomer and a fullerene compound dimer.

2. The imaging element according to claim 1, wherein mass % of (the fullerene compound monomer+the fullerene compound dimer) in the photoelectric conversion layer is greater than or equal to 13 mass % and less than or equal to 33 mass %.

3. The imaging element according to claim 2, wherein a mass ratio of the electron transporting material, and the fullerene compound dimer per unit mass is greater than 0 and less than or equal to 0.4.

4. The imaging element according to claim 3, wherein the mass ratio of the electron transporting material, and the fullerene compound dimer per unit mass is greater than or equal to 0.08 and less than 0.30.

5. The imaging element according to claim 2, wherein a mass ratio of the electron transporting material, and a fullerene compound trimer or a higher-order fullerene compound multimer per unit mass is less than or equal to 0.12.

6. The imaging element according to claim 2, wherein M_{Di-1}/M_{Di-0}≤100 is satisfied, where M_{Di-0} denotes mass % of the fullerene compound dimer in the photoelectric conversion layer, and M_{Di-1} denotes mass % of the fullerene compound dimer in the photoelectric conversion layer after the photoelectric conversion layer is irradiated with light of a wavelength of 560 nm having an energy of 3.2 mW/cm² for 24 hours.

7. The imaging element according to claim 1, wherein mass % of the hole transporting material in the photoelectric conversion layer is greater than or equal to 15 mass % and less than or equal to 50 mass %.

8. The imaging element according to claim 1, wherein
the fullerene compound monomer includes at least one kind of material selected from a group including a C60 monomer, a C60 monomer oxide, a C60 monomer derivative, a C60 monomer derivative oxide, a C70 monomer, a C70 monomer oxide, a C70 monomer derivative, a C70 monomer derivative oxide, a C74 monomer, a C74 monomer oxide, a C74 monomer derivative, and a C74 monomer derivative oxide, and
the fullerene compound dimer includes at least one kind of material selected from a group including a C60 dimer, a C60 dimer oxide, a C60 dimer derivative, a C60 dimer derivative oxide, a C70 dimer, a C70 dimer oxide, a C70 dimer derivative, a C70 dimer derivative oxide, a C74 dimer, a C74 dimer oxide, a C74 dimer derivative, and a C74 dimer derivative oxide.

9. The imaging element according to claim 8, wherein
the fullerene compound monomer includes the C60 monomer, and
the fullerene compound dimer includes the C60 dimer.

10. The imaging element according to claim 1, further comprising a first electrode, and a second electrode where light enters, wherein
the photoelectric conversion layer is sandwiched between the first electrode and the second electrode.

11. A stacked imaging element comprising at least one imaging element according to claim 1 stacked.

12. An imaging device comprising a plurality of the imaging elements according to claim 1.

13. An imaging device comprising a plurality of the stacked imaging elements according to claim 11.
